(19) United States
(12) Patent Application Publication
(10) Pub. No.: US 2023/0045448 A1
(43) Pub. Date: Feb. 9, 2023

(54) QUANTUM DOT, AND INK COMPOSITION, LIGHT-EMITTING DEVICE, OPTICAL MEMBER, AND APPARATUS, EACH INCLUDING THE SAME

(71) Applicants: Samsung Display Co., Ltd., Yongin-si (KR); Hannam University Institute for Industry-Academia Cooperation, Daejeon (KR)

(72) Inventors: Yunhyuk Ko, Yongin-si (KR); Dongryeol Whang, Seoul (KR); Changhee Lee, Yongin-si (KR); Kwangsup Lee, Daejeon (KR); Prem PRABHAKARAN, Daejeon (KR); Daeho Hwang, Daejeon (KR)

(21) Appl. No.: 17/853,872

(22) Filed: Jun. 29, 2022

(30) Foreign Application Priority Data
Jul. 2, 2021 (KR) 10-2021-0087393

(51) Int. Cl. H01L 51/50; C09K 11/88; C09K 11/74; C09K 11/70; C09K 11/66; C09K 11/62; C09K 11/56; C09D 11/033; C09D 11/03

(52) U.S. Cl. CPC H01L 51/502; C09K 11/883; C09K 11/7492; C09K 11/885; C09K 11/70; C09K 11/661; C09K 11/666; C09K 11/66; C09K 11/621; C09K 11/62; C09K 11/565; C09D 11/033; C09D 11/03; B82Y 30/00

(57) ABSTRACT

A quantum dot, and an ink composition, a light-emitting device, an optical member, and an apparatus, each including the quantum dot. The quantum dot includes: a nanoparticle; and at least one ligand on a surface of the nanoparticle, wherein the nanoparticle does not include mercury and cadmium, and the at least one ligand includes at least two thiol groups and at least one hydrophilic group.

### CROSS-REFERENCE TO RELATED APPLICATION

This application claims priority to and the benefit of Korean Patent Application No. 10-2021-0087393, filed on Jul. 2, 2021, in the Korean Intellectual Property Office, the disclosure of which is incorporated by reference herein in its entirety.

### BACKGROUND

### 1. Field

One or more embodiments relate to a quantum dot, and an ink composition, a light-emitting device, an optical member, and an apparatus, each including the quantum dot.

### 2. Description of the Related Art

Quantum dots are semiconductor nanocrystals that exhibit a quantum confinement effect. When quantum dots receive light from an excitation source and reach an excited energy state, they emit energy autonomously according to a corresponding energy band gap. Here, even in the same material, quantum dots emit light with a wavelength that varies depending on a particle size. Thus, by adjusting the quantum dot size, light having a desired wavelength region may be obtained, and excellent or suitable color purity and high luminescence efficiency may be also exhibited. Accordingly, quantum dots are applicable to various suitable devices.

In addition, quantum dots may be utilized as materials that perform various suitable optical functions (for example, an optical conversion function) in an optical member. Quantum dots, as nano-sized semiconductor nanocrystals, may have different energy band gaps by adjusting the size and composition of the nanocrystals, and accordingly, light of various suitable emission wavelengths may be emitted.

An optical member including such quantum dots may be in the form of a thin film, for example, in the form of a thin film patterned for each subpixel. Such an optical member may be utilized as a color conversion member of an apparatus including various suitable light sources.

### SUMMARY

Aspects according to one or more embodiments are directed toward a quantum dot, and an ink composition, a light-emitting device, an optical member, and an apparatus, each including the quantum dot, the quantum dot having excellent or suitable solubility in a hydrophilic solvent (for example, an alcohol-based solvent), excellent or suitable charge injection ability, and a narrow (e.g., small) distance between quantum dots.

Additional aspects will be set forth in part in the description, which follows and, in part, will be apparent from the description, or may be learned by practice of the presented embodiments of the disclosure.

According to one or more embodiments, a quantum dot includes a nanoparticle and at least one ligand on a surface of the nanoparticle, wherein the nanoparticle does not include mercury (Hg) and cadmium (Cd), and the at least one ligand includes at least two thiol groups and at least one hydrophilic group.

According to one or more embodiments, an ink composition includes the quantum dot and a solvent.

According to one or more embodiments, a light-emitting device includes a first electrode, a second electrode facing the first electrode, and an emission layer between the first electrode and the second electrode, wherein the emission layer includes the quantum dot.

According to one or more embodiments, an optical member includes the quantum dot.

According to one or more embodiments, an apparatus includes the quantum dot.

### BRIEF DESCRIPTION OF THE DRAWINGS

The above and other aspects, features, and enhancements of certain embodiments of the disclosure will be more apparent from the following description taken in conjunction with the accompanying drawings, in which:

FIG. 1 is a schematic view of a quantum dot according to an embodiment;

FIG. 2 is a schematic cross-sectional view of a light-emitting device according to an embodiment;

FIG. 3 is a schematic cross-sectional view of a light-emitting apparatus according to an embodiment;

FIG. 4 is a schematic cross-sectional view of a light-emitting apparatus according to an embodiment;

FIG. 5A is an image showing a photoluminescence state of a quantum dot dispersion solution for Quantum dot 1, according to Evaluation Example 1;

FIG. 5B is an image showing a photoluminescence state of a quantum dot dispersion solution for Quantum dot A, according to Evaluation Example 1; and

FIG. 6 is a graph showing photoluminescence (PL) spectra of Ink compositions 1-1 to 1-3.

### DETAILED DESCRIPTION

Reference will now be made in more detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. As used herein, expressions such as “at least one of”, “one of”, and “selected from”, when preceding a list of elements, modify the entire list of elements and do not modify the individual elements of the list. For example, “at least one of a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

Because the present disclosure may have diverse modified embodiments, embodiments are illustrated in the drawings and are described in the detailed description. An effect and a characteristic of the disclosure, and a method of accomplishing these will be apparent when referring to embodiments described with reference to the drawings. The present disclosure may, however, be embodied in many different forms and should not be construed as limited to the embodiments set forth herein.

Hereinafter, embodiments of the present disclosure will be described in more detail with reference to the accompanying drawings. The same or corresponding components will be denoted by the same reference numerals, and thus redundant description thereof will be omitted.

It will be understood that although the terms “first,” “second,” etc. may be used herein to describe various components, these components should not be limited by these terms. These components are only used to distinguish one component from another.

An expression used in the singular encompasses the expression of the plural, unless it has a clearly different meaning in the context.

It will be further understood that the terms “comprises” and/or “comprising” as used herein specify the presence of stated features or elements, but do not preclude the presence or addition of one or more other features or elements.

In the following embodiments, when various components such as layers, films, regions, plates, and the like are said to be “on” another component, this may include not only a case in which the other component is “immediately on” the layers, films, regions, or plates (e.g., without any intervening elements therebetween), but also a case in which other intermediate component(s) may be placed therebetween. Sizes of elements in the drawings may be exaggerated for convenience of explanation. In other words, because sizes and thicknesses of components in the drawings are arbitrarily illustrated for convenience of explanation, the following embodiments are not limited thereto.

### Quantum Dot

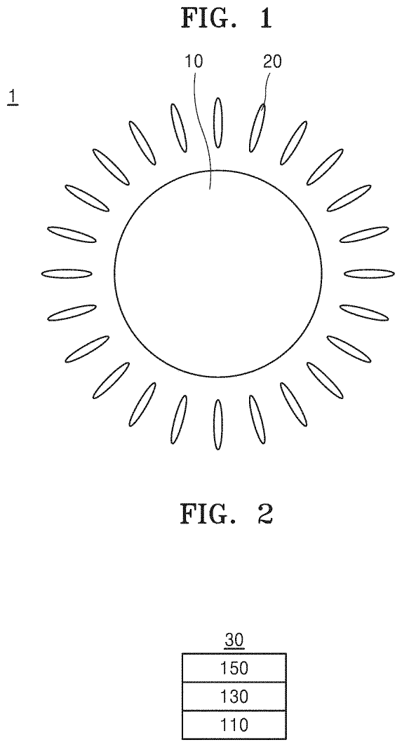

FIG. 1 is a schematic view of a structure of a quantum dot according to an embodiment.

Referring to FIG. 1, a quantum dot 1 may include: a nanoparticle 10; and at least one ligand 20 represented by Formula 1 and arranged on a surface of the nanoparticle 10.

In an embodiment, the quantum dot 1 may include: the nanoparticle 10; and at least one ligand 20 arranged on the surface of the nanoparticle 10, wherein

the nanoparticle may not include mercury (Hg) and cadmium (Cd), and

the at least one ligand may each independently include two or more thiol groups and at least one hydrophilic group. For example, the at least one ligand may each include two or more thiol groups and one hydrophilic group.

In an embodiment, the ligand 20 may be represented by Formula 1:

A₁-(L₁)ₙ₁-T₁ Formula 1

wherein, in Formula 1,

A₁ may be a moiety including at least two thiol groups.

In an embodiment, the at least two thiol groups of A₁ may be bidentate or tridentate thiol groups.

In one or more embodiments, A₁ may be an anchoring group bonded to the surface of the nanoparticle 10. Here, the anchoring group is a binding group that allows the at least one ligand 20 to be adsorbed onto the nanoparticle 10 when arranged on the nanoparticle 10.

In one or more embodiments, A₁ may be a group represented by one of Formulae A-1 to A-4:

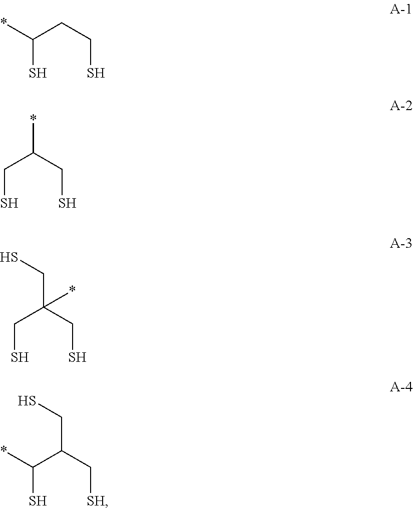

wherein * in Formulae A-1 to A-4 indicates a binding site to a neighboring atom.

In Formula 1, L₁ may be a single bond, *—O—*′, *—S—*′, or *—C(R₁)(R₂)—*′.

In Formula 1, n1 may be an integer from 1 to 10.

For example, n1 may be an integer from 1 to 5.

When n1 is within the ranges above, charge injection into the quantum dot 1 may be facilitated. Accordingly, as a distance between the quantum dots is kept small (e.g., narrow), a light-emitting device including the quantum dots 1 including the at least one ligand 20 may have improved efficiency.

In an embodiment, R₁ and R₂ in Formula 1 may each independently be hydrogen, deuterium, —F, —Cl, —Br, —I, a hydroxyl group, a cyano group, a carboxyl group, a C₁-C₂₀ alkyl group, a C₁-C₂₀ alkoxy group, —NCO, —NCS, —OCN, —SCN, —C(═O)N(Q₁)₂, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂).

In one or more embodiments, R₁ and R₂ in Formula 1 may each independently be hydrogen, deuterium, —F, —Cl, —Br, —I, a hydroxyl group, a cyano group, a C₁-C₂₀ alkyl group, or a C₁-C₂₀ alkoxy group.

In Formula 1, T₁ may be a hydrophilic group.

In an embodiment, the hydrophilic group may be a hydroxyl group, a carboxyl group, an amine group, a sulfonyl group, a phosphate group, an ammonium group, or a phosphonium group.

In one or more embodiments, the hydrophilic group may be a hydroxyl group, a carboxyl group, or an amine group. Thus, the ligand 20 may include at least two thiol groups and at least one hydroxyl group.

In Formula 1, Q₁ to Q₃ may each independently be hydrogen, a C₁-C₂₀ alkyl group, a C₁-C₂₀ alkoxy group, a phenyl group, a biphenyl group, a terphenyl group, a naphthyl group, or a pyridinyl group, and * and *′ each indicate a binding site to a neighboring atom.

In an embodiment, the amine group may be represented by —N(Q₄)(Q₅), wherein Q₄ and Q₅ may each independently be the same as described in connection with Q₁.

In an embodiment, the nanoparticle 10 may have a core-shell structure in which a core includes a first semiconductor material and a shell includes a second semiconductor material.

In an embodiment, the first semiconductor material and the second semiconductor material may not include mercury (Hg) and cadmium (Cd). That is, each of the first semiconductor material and the second semiconductor material may be free of mercury (Hg) and cadmium (Cd).

In an embodiment, the shell may include two different kinds (e.g., types) of the second semiconductor material.

In an embodiment, the first semiconductor material and the second semiconductor material may each independently include:

ZnS, ZnSe, ZnTe, ZnO, MgSe, MgS, ZnSeS, ZnSeTe, ZnSTe, MgZnSe, MgZnS, or CdZnSeS;

GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InGaN, InGaP, InNP, InAlP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, InGaZnP, or InAlZnP;

TiO, GaO, GaS, GaSe, Ga₂Se₃, GaTe, InS, InSe, In₂S₃, In₂Se₃, or InTe;

InGaS₃ or InGaSe₃;

AgInS, AgInS₂, CulnS, CuInS₂, CuGaO₂, AgGaO₂, AgAlO₂, or AgInZnS;

SrSe, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, or SnPbSTe;

Si, Ge, SiC, or SiGe; or

any combination thereof.

In one or more embodiments, the first semiconductor material may include InP, InZnP, InGaP, ZnS, ZnSe, ZnTe, ZnSeS, ZnSeTe, PbSe, PbS, PbTe, AgInZnS, GaN, GaP, GaAs, InGaN, InAs, ZnO, or any combination thereof, and

the second semiconductor material may include ZnS, ZnSe, ZnTe, ZnSeS, ZnSeTe, ZnO, InP, InS, GaP, GaN, GaO, ZnSeTe, InZnP, InGaP, InGaN, PbS, TiO, SrSe, or any combination thereof.

In one or more embodiments, the first semiconductor material may include ZnSeS, ZnSeTe, or any combination thereof, and

the second semiconductor material may include ZnS, ZnSe, ZnSeS, ZnSeTe, or any combination thereof.

Each element included in a multi-element compound including a binary compound such as ZnS and ZnSe, a ternary compound, such as ZnSeS and ZnSeTe and/or a quaternary compound such as AgInZnS may exist at a uniform or non-uniform concentration in a quantum dot particle.

In an embodiment, the shell may include: a first region (e.g., around the core); a second region covering (e.g., around) the first region; and a third region covering (e.g., around) the second region, wherein

the first region may include a third semiconductor material,

the second region may include a fourth semiconductor material, and

the third region may include a fifth semiconductor material.

Here, the third semiconductor material, the fourth semiconductor material, and the fifth semiconductor material may respectively be the same as described in connection with the second semiconductor material.

In an embodiment, the third semiconductor material, the fourth semiconductor material, and the fifth semiconductor material may be different from each other.

In an embodiment, the third semiconductor material included in the first region may exist at a uniform concentration or a non-uniform concentration.

In an embodiment, the fourth semiconductor material included in the second region may exist at a uniform concentration or a non-uniform concentration.

In an embodiment, the fifth semiconductor material included in the third region may exist at a uniform concentration or a non-uniform concentration.

In an embodiment, the nanoparticle 10 may be surface-modified with the ligand 20.

For example, the ligand 20 may include at least one selected from Ligands 1 to 3:

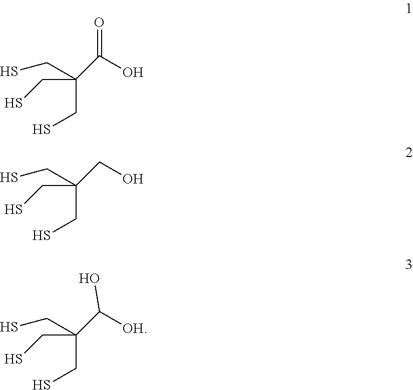

When the quantum dot 1 has a structure in which at least one ligand 20 including at least two thiol groups and at least one hydrophilic group is arranged on the surface of the nanoparticle 10 that does not include Hg and Cd, the injection of holes and electrons may be significantly facilitated (e.g., improved).

Because the nanoparticle 10 does not include Hg and Cd, excellent or suitable bandgap characteristics may be exhibited while alleviating problems such as environmental pollution and heavy metal poisoning caused by a quantum dot including Hg and Cd.

In addition, because the ligand 20 includes at least two thiol groups, the ligand 20 may be easily introduced to the surface of the nanoparticle 10, and holes and electrons may also be easily injected between the nanoparticle 10 and the ligand 20.

In addition, because the ligand 20 includes at least one hydrophilic group, the quantum dot 1 may have excellent or suitable solubility in a hydrophilic solvent, for example, an alcohol-based solvent, thereby preventing or substantially preventing (protecting from) invasion of common organic layers (e.g., deterioration of ligand of related art). Accordingly, a light-emitting device, an optical member, and an electronic device, each including the quantum dot 1 may exhibit improved luminescence efficiency, show improvements in solubility and compatibility in a hydrophilic solvent, and also have improved workability due to omission of additional processes such as cross-linking among common layers (e.g., due to the elimination of additional processes such as cross-linking necessary when utilizing ligand of related art).

Furthermore, as the ligand 20 is arranged on the surface of the nanoparticle 10 in the quantum dot 1, the length of the ligand 20 on the surface of the quantum dot 1 decreases (e.g., compared to free unbound ligands) and the amount of non-conductive organic materials are reduced such that, as compared to a quantum dot in which a ligand and a nanoparticle are simply mixed, a light-emitting device including the quantum dot 1 may exhibit improvement in efficiency.

### Ink Composition

Another aspect of the present disclosure provides an ink composition including the quantum dot and a solvent.

In the ink composition, an amount of the quantum dot may be from about 1.0 wt % or more to about 10 wt % or less, for example, from about 2 wt % or more to about 5 wt % or less, based on the total weight of the ink composition. However, the amount of the quantum dot is not limited thereto. Within these ranges, the ink composition may be suitable for usage in manufacturing a light-emitting device having sufficient luminescence efficiency in a soluble process (e.g., solution process).

A light-emitting device including a quantum dot-containing emission layer may provide improved film uniformity, improved charge injection balance, an improvement in quantum dot efficiency affected by a transport layer, and/or sufficient improvements in luminescence efficiency and/or lifespan upon blocking of a direct contact between an electron transport layer and a hole transport layer due to quantum dots.

For usage as the solvent, kinds (e.g., types) of the solvent are not limited as long as the solvent properly disperses the quantum dot.

In an embodiment, the solvent may be a hydrophilic solvent.

In one or more embodiments, the solvent may be an alcohol-based solvent, but embodiments of the present disclosure are not limited thereto.

The term “alcohol-based solvent” as used herein refers to a solvent including a compound including an alcohol group (—OH). For example, the term “alcohol-based solvent” as used herein may refer to an alcohol group (—OH) containing solvent.

In one or more embodiments, the solvent may include aliphatic alcohol, aromatic alcohol, polyhydric alcohol, ethylene glycol monoalkyl ether, or any combination thereof, but embodiments of the present disclosure are not limited thereto.

In one or more embodiments, the solvent may include methanol, ethanol, phenol, benzenediol, ethylene glycol, glycerol, diethylene glycol, triethylene glycol, ethylene glycol monoethyl ether, ethylene glycol monobutyl ether, or any combination thereof, but embodiments of the present disclosure are not limited thereto.

In the ink composition, an amount of the solvent may be from about 80 wt % or more to about 99.9 wt % or less, for example, from about 90 wt % or more to about 99.8 wt % or less, based on the total weight of the ink composition, but embodiments of the present disclosure are not limited thereto. Within these ranges, the quantum dot may be properly dispersed in the ink composition, and a solid content concentration suitable for a soluble process (e.g., solution process) may be obtained.

In an embodiment, the ink composition may further include a polymerization initiator. The polymerization initiator may include a thermal polymerization initiator and/or a photopolymerization initiator.

For usage as the thermal polymerization initiator, any compound capable of forming radicals by heat may be utilized without limitation, and examples of the thermal polymerization initiator may include: a persulfate-containing acid salt compound, such as sodium persulfate (Na₂S₂O₈), potassium persulfate (K₂S₂O₈), and/or ammonium persulfate ((NH₄)₂S₂O₈); an azo-based compound, such as 2,2-azobis(2-amidinopropane) dihydrochloride, 2,2-azobis-(N,N-dimethylene)isobutyramidine dihydrochloride, 2-(carbamoylazo)isobutylonitril, 2,2-azobis[2-(2-imidazolin-2-yl)propane]dihydrochloride, and/or 4,4-azobis(4-cyanovaleric acid); peroxide; or any combination thereof.

When the thermal polymerization initiator is utilized, an amount thereof may be from about 0.01 parts by weight to about 15 parts by weight based on the total weight of the ink composition.

For usage as the photopolymerization initiator, any compound capable of forming radicals by ultraviolet light having a maximum emission wavelength in a range of about 200 nm to about 400 nm may be utilized without limitation, and the photopolymerization initiator may be a compound or an organosilane compound, each including a combination of any one of cations including arylsulfonium, aryldiazonium, or arylammonium and any one of anions including AsF₆₋, SbF₆₋, PF₆₋, or tetrakis(pentafluorophenyl)borate.

When the photopolymerization initiator is utilized, an amount thereof may be from about 0.01 parts by weight to about 15 parts by weight based on the total weight of the ink composition.

In an embodiment, the ink composition may further include various suitable additives to improve ejection properties and coating properties of the ink composition in a range that does not affect physical properties of the quantum dot, and to improve the optical properties of a thin film cured therefrom.

For example, the ink composition may further include a suitable (e.g., known) dispersing agent, a viscosity modifier, and/or the like to improve ejection properties and coating properties, and a suitable (e.g., known) surfactant, a scattering agent, an anti-foaming agent, a UV stabilizer, a moisture absorbent, an antioxidant, and/or the like to improve optical properties of the cured thin film. Here, the additive may be utilized in an amount in a range that does not affect physical properties of the quantum dot.

The ink composition may further include a hole-transporting compound or an electron-transporting compound.

The hole-transporting compound may be the same as to be described later in connection with a compound included in a hole transport region.

The electron-transporting compound may be the same as to be described later in connection with a compound included in an electron transport region.

In the ink composition, an amount of the hole-transporting compound or the electron-transporting compound may be from about 0.5 wt % or more to about 20 wt % or less, or from about 0.5 wt % or more to about 15 wt % or less based on the total weight of the composition. However, embodiments of the present disclosure are not limited thereto.

The ink composition may have a viscosity in a range of about 1 cP to about 10 cP. The ink composition that satisfies this viscosity range may be suitable for forming a quantum dot-containing emission layer of a light-emitting device by a soluble process (e.g., solution process).

The ink composition may have a surface tension in a range from about 10 dynes/cm to about 40 dynes/cm. The ink composition that satisfies this surface tension range may be suitable for forming a quantum dot-containing emission layer of a light-emitting device by a soluble process (e.g., solution process).

### Light-Emitting Device

FIG. 2 is a schematic cross-sectional view of a light-emitting device 30 according to an embodiment. The light-emitting device 30 includes a first electrode 110, an interlayer 130, and a second electrode 150.

Hereinafter, the structure of the light-emitting device 30 according to an embodiment and a method of manufacturing the light-emitting device 30 will be described in connection with FIG. 2.

### First Electrode 110

In FIG. 2, a substrate may be additionally arranged under the first electrode 110 or above the second electrode 150. In an embodiment, the substrate may be a glass substrate or a plastic substrate. In one or more embodiments, the substrate may be a flexible substrate, and for example, may include plastics with excellent heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, depositing or sputtering a material for forming the first electrode 110 on the substrate. When the first electrode 110 is an anode, a material for forming the first electrode 110 may be a high-work function material that facilitates injection of holes.

The first electrode 110 may be a reflective electrode, a semi-transmissive electrode, or a transmissive electrode. In an embodiment, when the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In one or more embodiments, when the first electrode 110 is a semi-transmissive electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a single-layered structure consisting of a single layer or a multi-layered structure including a plurality of layers. For example, the first electrode 110 may have a three-layered structure of ITO/Ag/ITO.

### Interlayer 130

The interlayer 130 is on the first electrode 110. The interlayer 130 may include an emission layer.

The interlayer 130 may further include a hole transport region between the first electrode 110 and the emission layer and an electron transport region between the emission layer and the second electrode 150.

In an embodiment, the interlayer 130 may further include, in addition to various suitable organic materials, a metal-containing compound such as an organometallic compound, an inorganic material such as a quantum dot, and/or the like.

In one or more embodiments, the interlayer 130 may include the quantum dot 1. The quantum dot 1 may be the same as described above.

In one or more embodiments, the interlayer 130 may further include: i) two or more emitting units sequentially stacked between the first electrode 110 and the second electrode 150; and ii) a charge generation layer between the two or more emitting units. When the interlayer 130 includes the two or more emitting units and the charge generation layer, the light-emitting device 30 may be a tandem light-emitting device.

### Hole Transport Region in Interlayer 130

The hole transport region may have i) a single-layered structure consisting of a single layer consisting of a single material, ii) a single-layered structure consisting of a single layer including (e.g., consisting of) a plurality of different materials, or iii) a multi-layered structure including a plurality of layers including different materials.

The hole transport region may include a hole injection layer, a hole transport layer, an emission auxiliary layer, an electron blocking layer, or any combination thereof.

For example, the hole transport region may have a multi-layered structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron-blocking layer structure, wherein layers of each structure are sequentially stacked from the first electrode 110 in the respective stated order.

The hole transport region may include a compound represented by Formula 201, a compound represented by Formula 202, or any combination thereof:

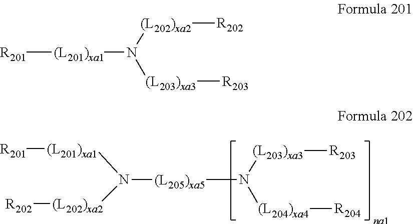

wherein, in Formulae 201 and 202,

L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,

xa1 to xa4 may each independently be an integer from 0 to 5,

xa5 may be an integer from 1 to 10,

R₂₀₁ to R₂₀₄ and 0201 may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ to form a C₈-C₆₀ polycyclic group (for example, a carbazole group and/or the like) unsubstituted or substituted with at least one R₁₀ₐ (for example, Compound HT16),

R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ to form a C₈-C₆₀ polycyclic group unsubstituted or substituted with at least one R₁₀ₐ, and

na1 may be an integer from 1 to 4.

For example, each of Formulae 201 and 202 may include at least one of the groups represented by Formulae CY201 to CY217:

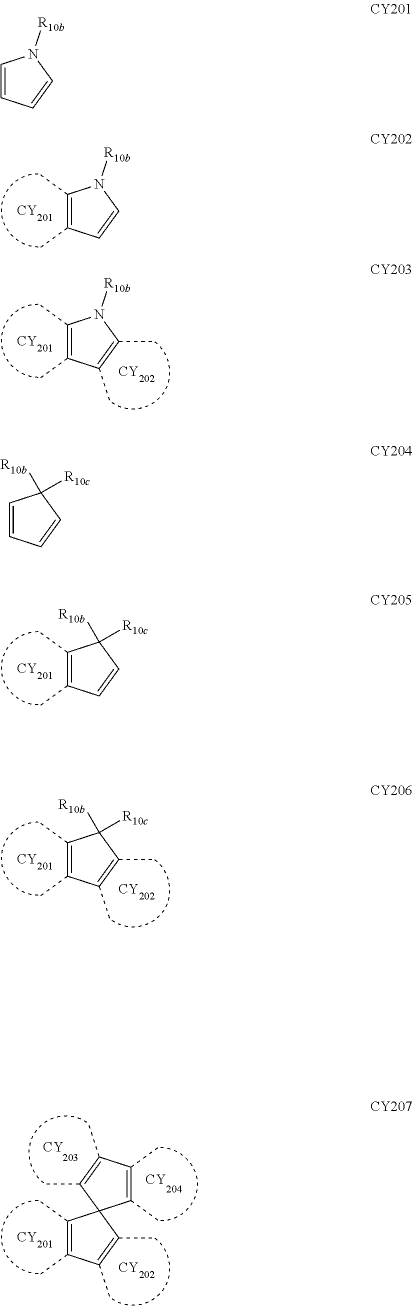

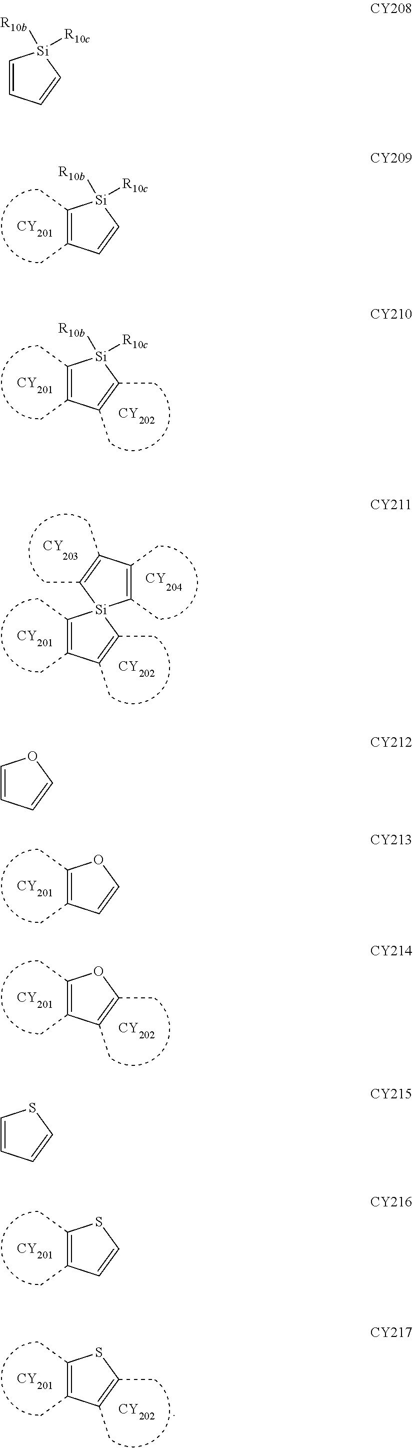

In Formulae CY201 to CY217, R_{10b} and R_{10c} may respectively be the same as described in connection with R₁₀ₐ, ring CY201 to ring CY204 may each independently be a C₃-C₂₀ carbocyclic group or a C₁-C₂₀ heterocyclic group, and at least one hydrogen in each of Formulae CY201 to CY217 may be unsubstituted or substituted with R₁₀ₐ.

In an embodiment, in Formulae CY201 to CY217, ring CY201 to ring CY204 may each independently be a benzene group, a naphthalene group, a phenanthrene group, or an anthracene group.

In one or more embodiments, each of Formulae 201 and 202 may include at least one of the groups represented by Formulae CY201 to CY203.

In one or more embodiments, Formula 201 may include at least one of the groups represented by Formulae CY201 to CY203 and at least one of the groups represented by Formulae CY204 to CY217.

In one or more embodiments, in Formula 201, xa1 may be 1, R₂₀₁ may be a group represented by one of Formulae CY201 to CY203, xa2 may be 0, and R₂₀₂ may be a group represented by one of Formulae CY204 to CY207.

In one or more embodiments, each of Formulae 201 and 202 may not include any of the groups represented by Formulae CY201 to CY203.

In one or more embodiments, each of Formulae 201 and 202 may not include any of the groups represented by Formulae CY201 to CY203, and may include at least one of the groups represented by Formulae CY204 to CY217.

In one or more embodiments, each of Formulae 201 and 202 may not include any of the groups represented by Formulae CY201 to CY217.

For example, the hole transport region may include one of Compounds HT1 to HT46, m-MTDATA, TDATA, 2-TNATA, NPB(NPD), β-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), poly[(9,9-dioctylfluorenyl-2,7-diyl)-co-(4,4′-(N-(4-sec-butylphenyl)diphenylamine)] (TFB), polyaniline/camphor sulfonic acid (PANI/CSA), polyaniline/poly(4-styrenesulfonate) (PANI/PSS), or any combination thereof:

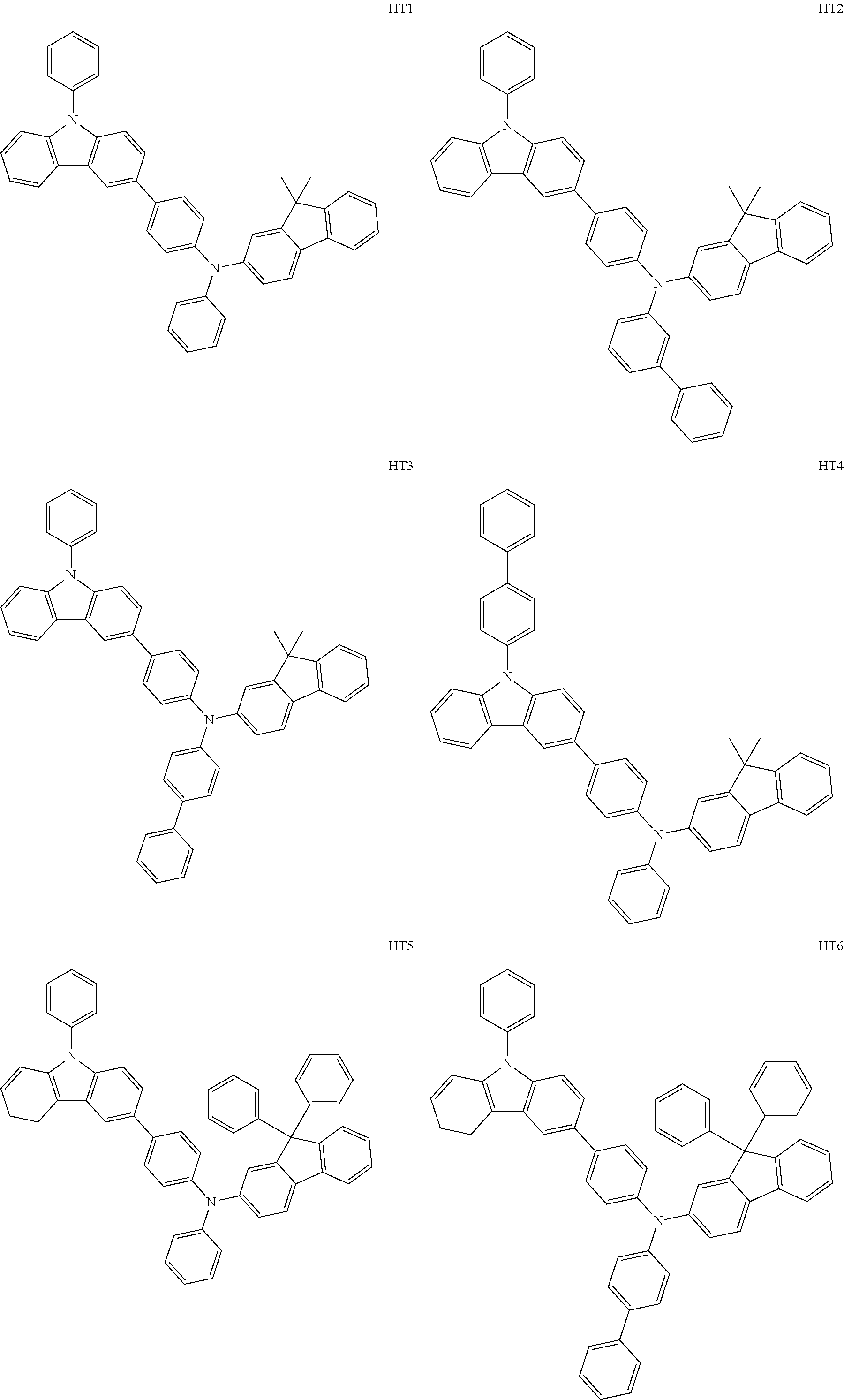

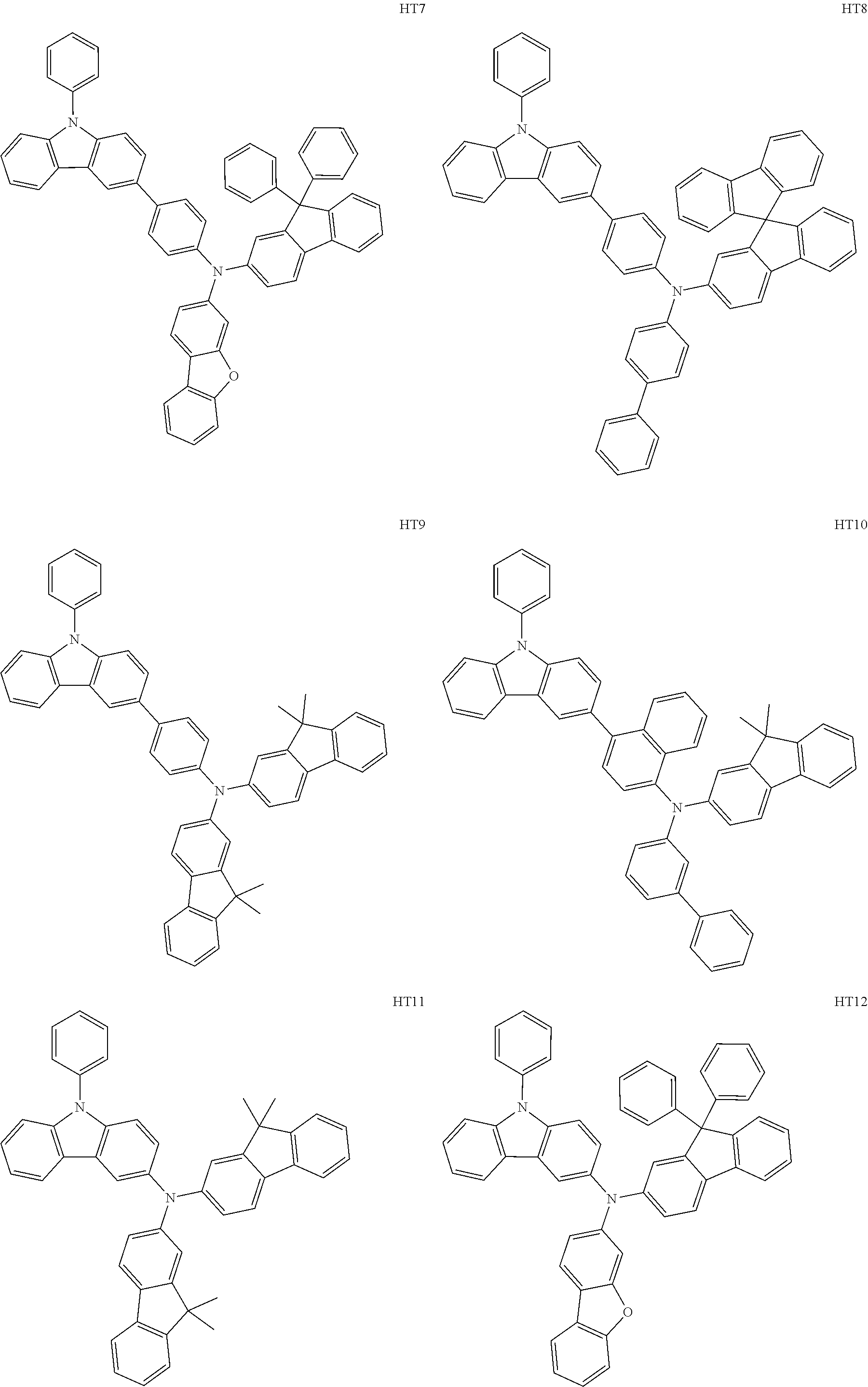

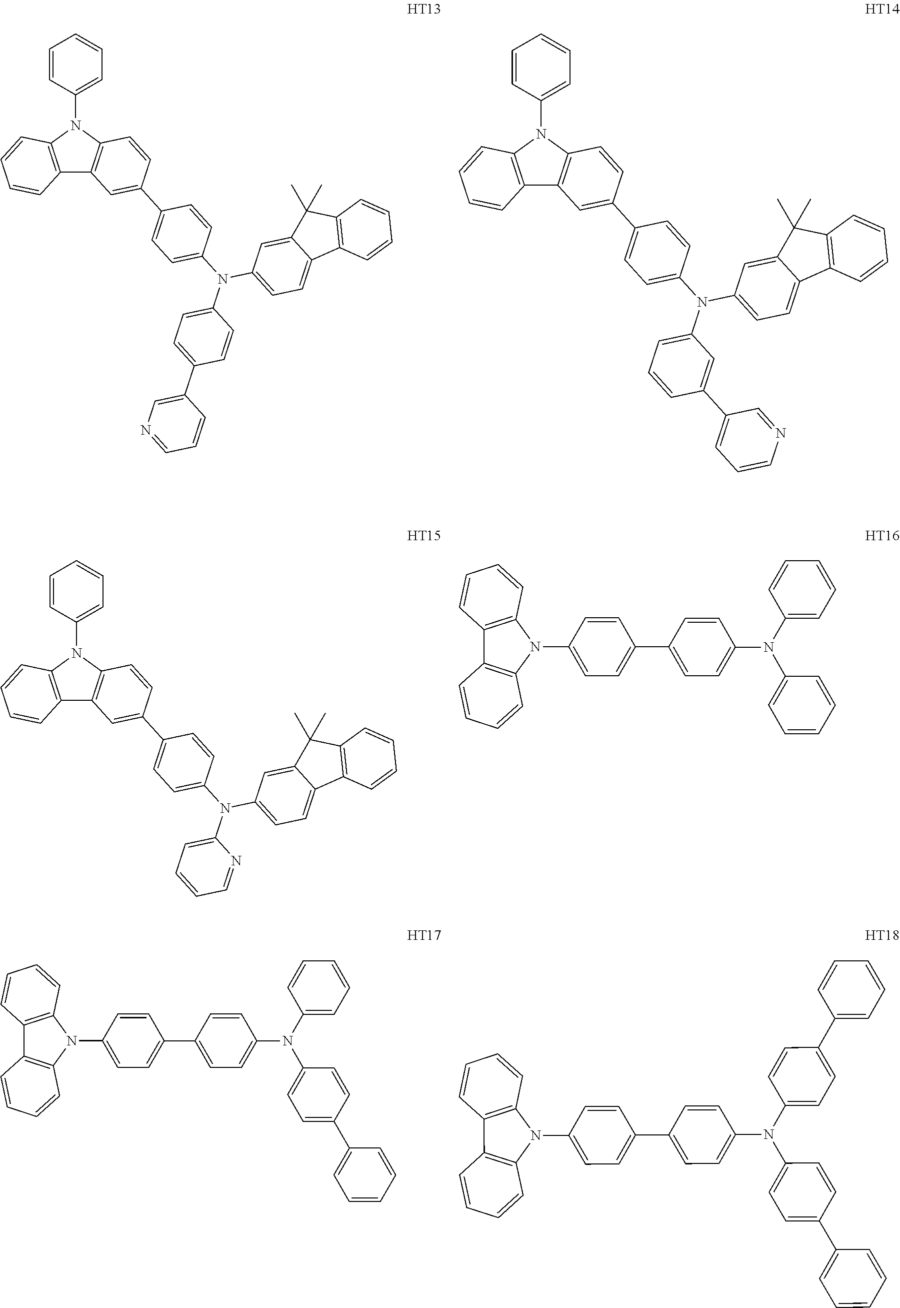 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

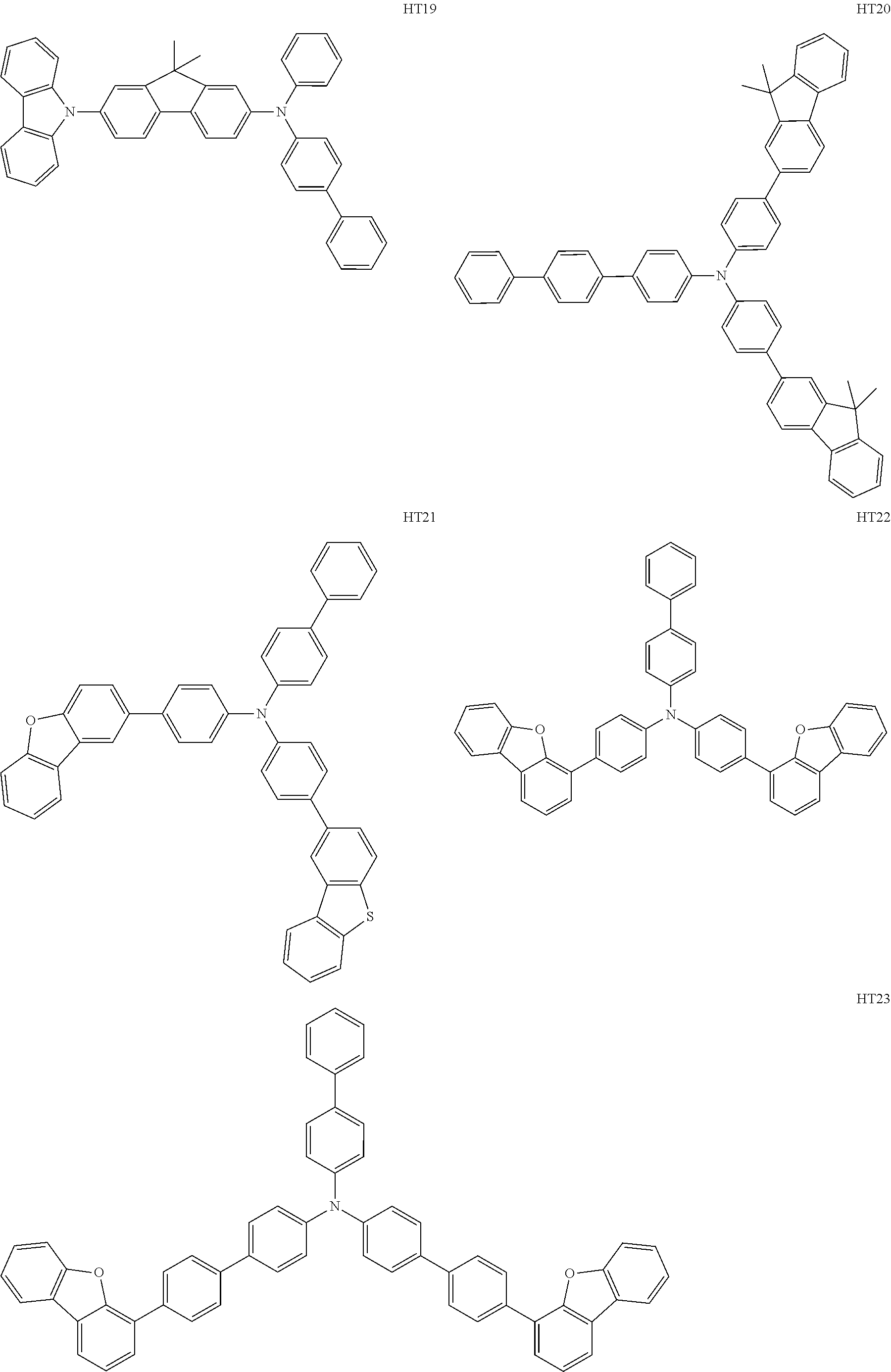

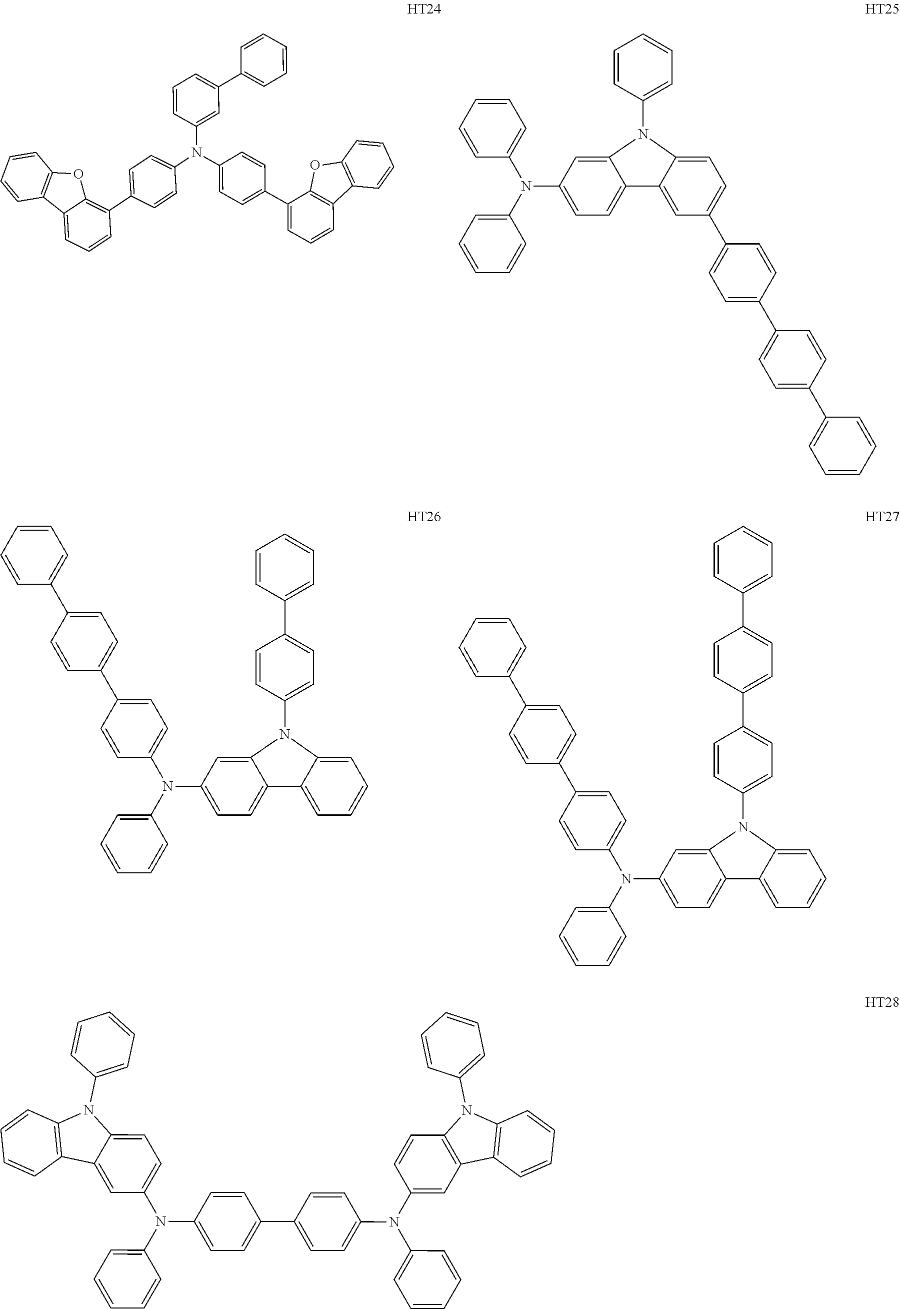 [SMILES: c1ccc(-c2cccc(N(c3ccc(-c4cccc5c4oc4ccccc45)cc3)c3ccc(-c4cccc5c4oc4ccccc45)cc3)c2)cc1 ; c1ccc(-c2ccc(-c3ccc(-c4ccc5c(c4)c4ccc(N(c6ccccc6)c6ccccc6)cc4n5-c4ccccc4)cc3)cc2)cc1 ; c1ccc(-c2ccc(-c3ccc(N(c4ccccc4)c4ccc5c6ccccc6n(-c6ccc(-c7ccccc7)cc6)c5c4)cc3)cc2)cc1 ; c1ccc(-c2ccc(-c3ccc(N(c4ccccc4)c4ccc5c6ccccc6n(-c6ccc(-c7ccc(-c8ccccc8)cc7)cc6)c5c4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

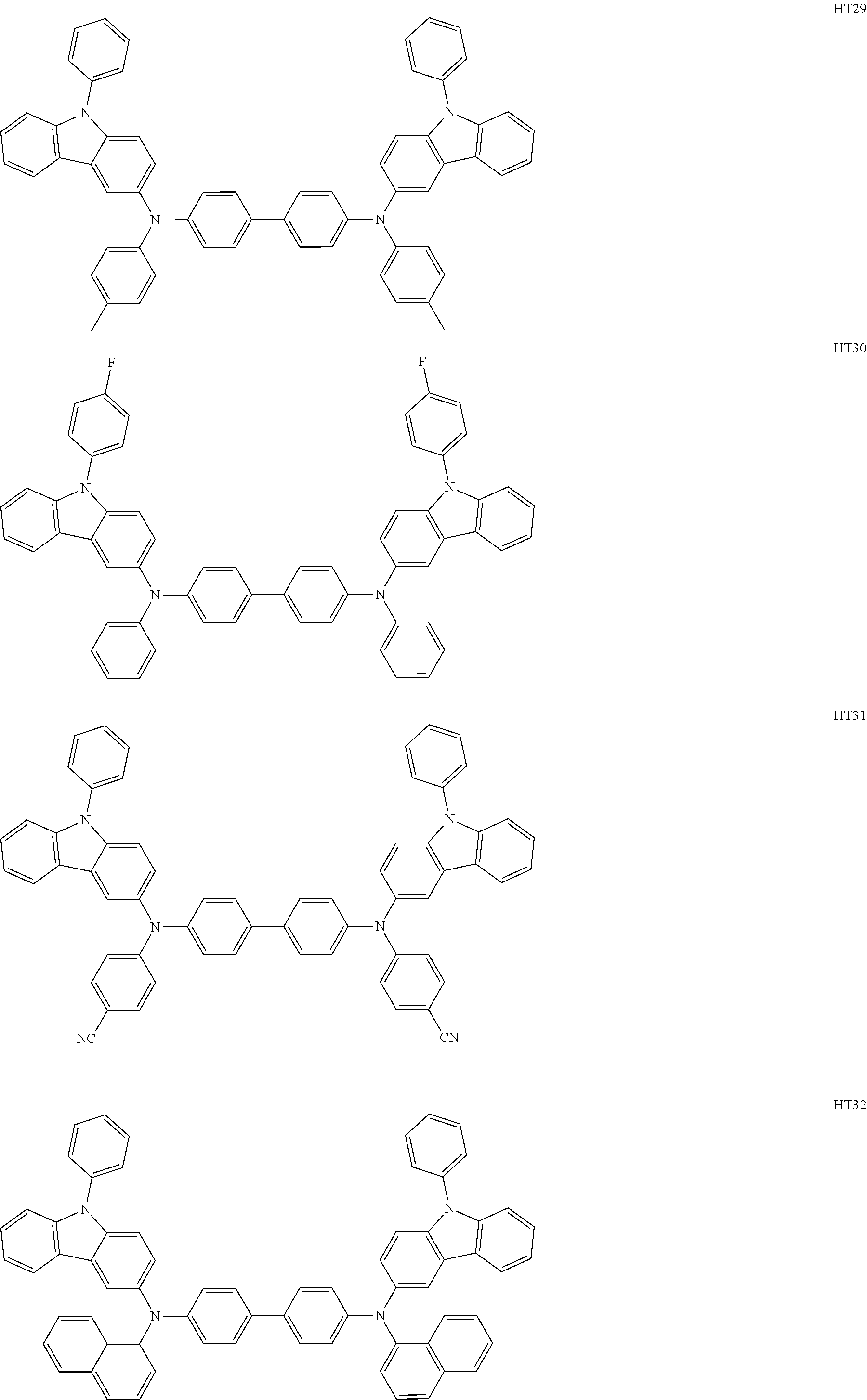

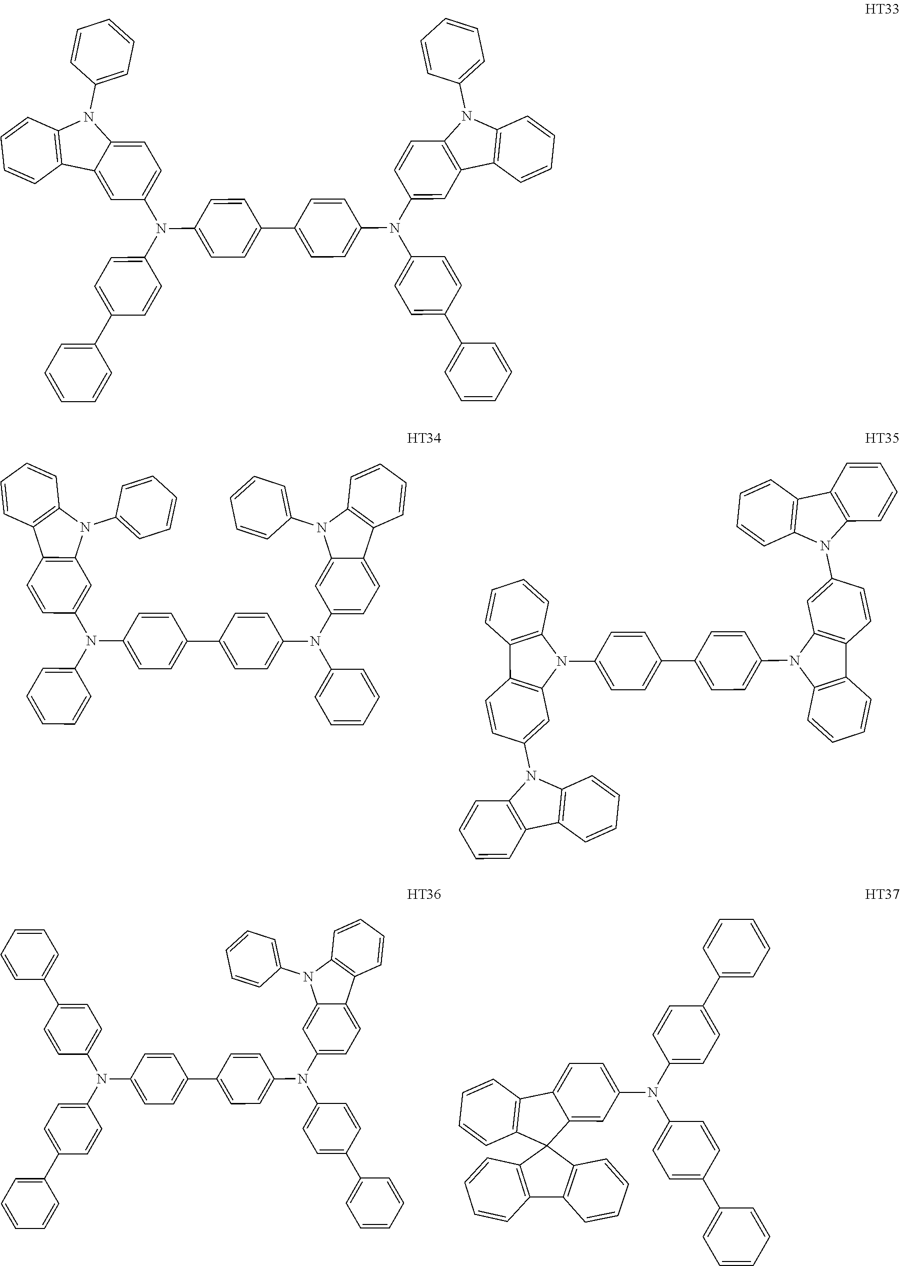

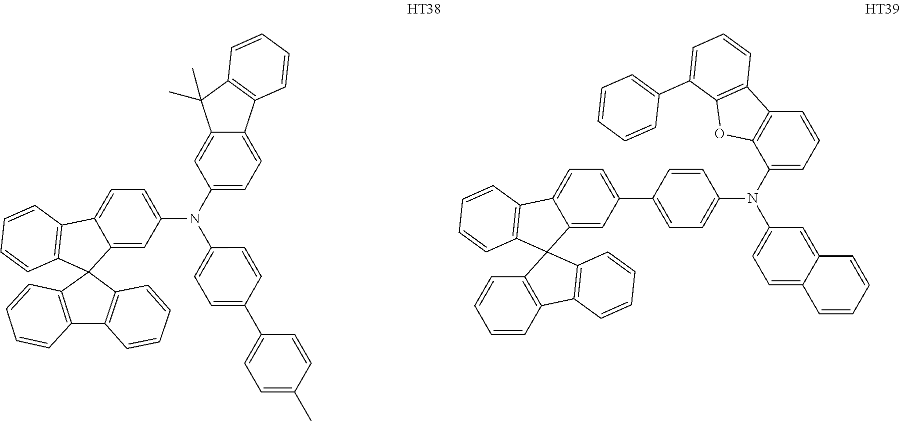 [SMILES: Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1]

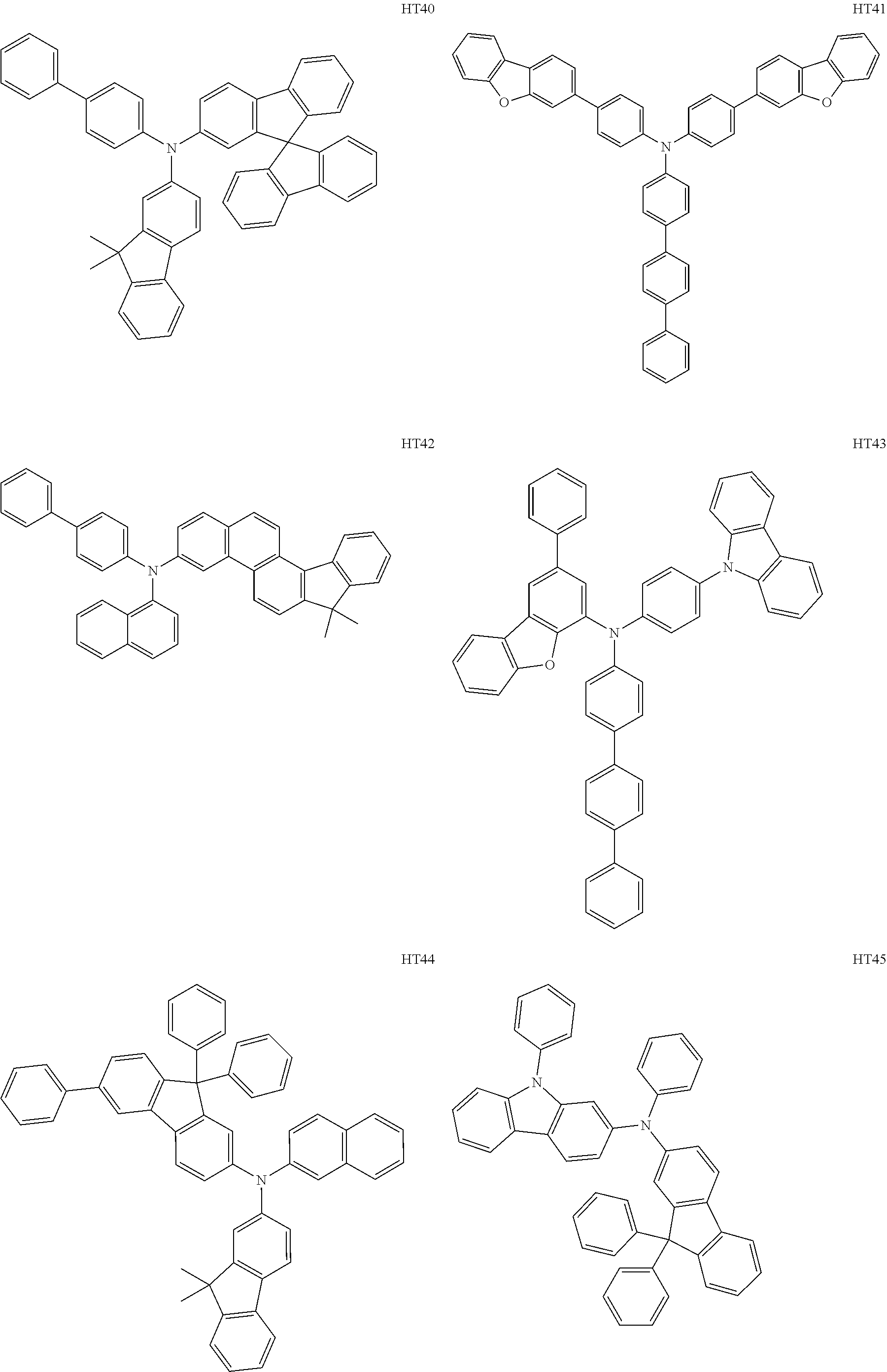

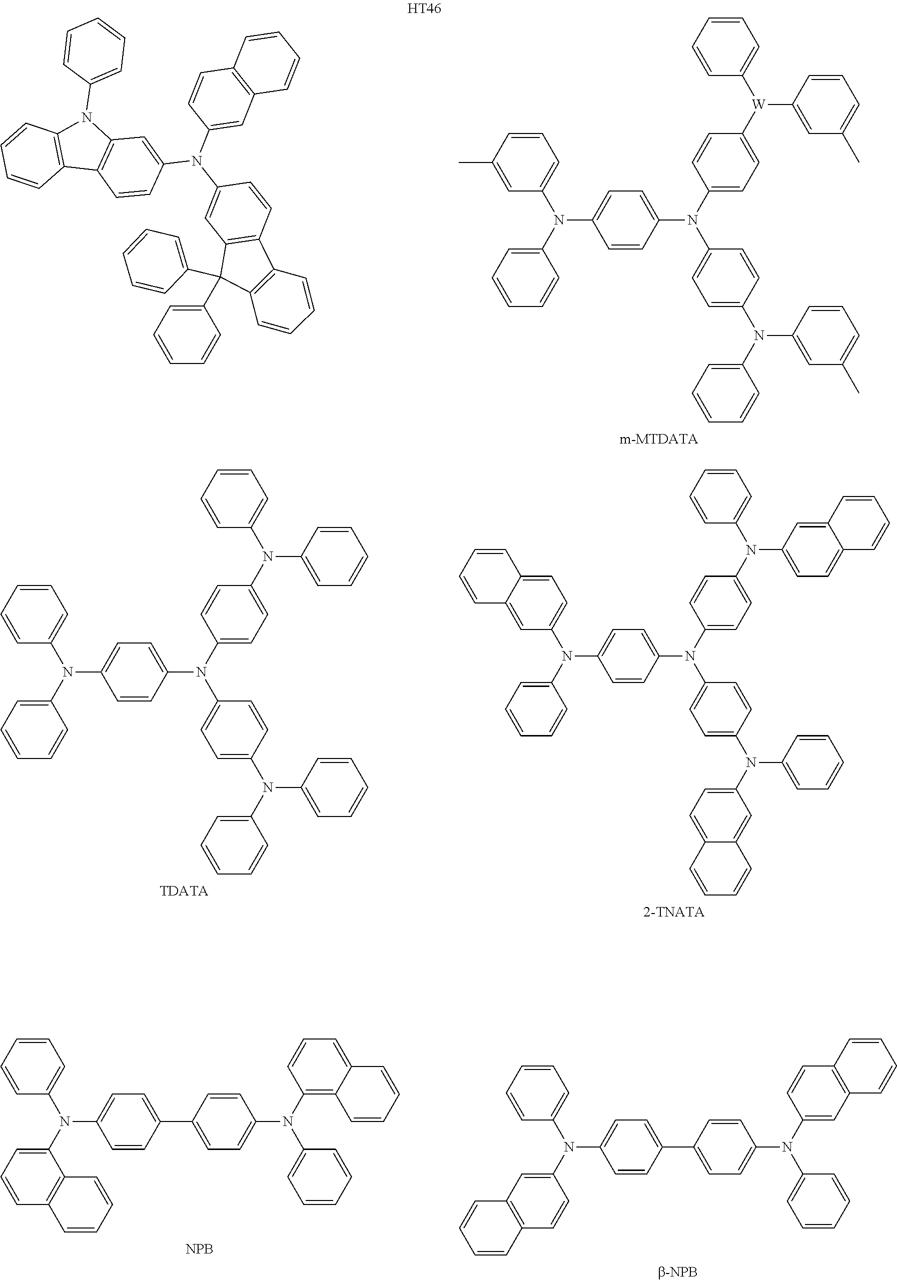

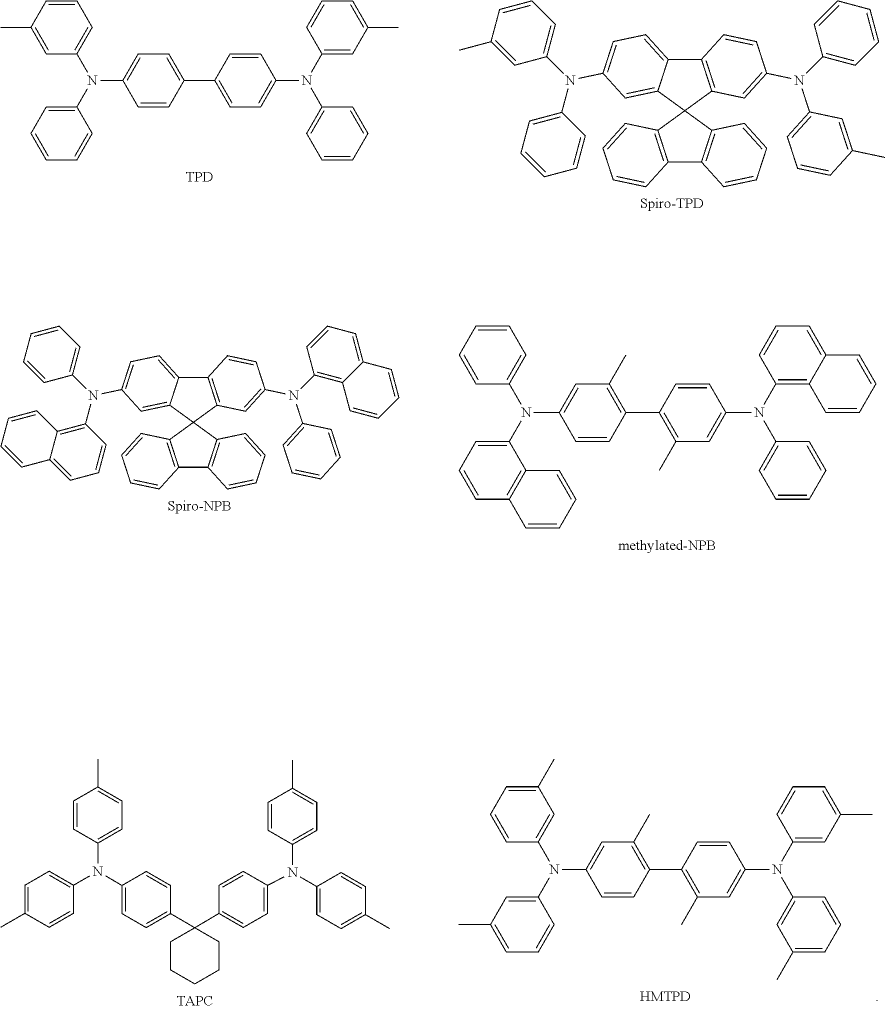

A thickness of the hole transport region may be in a range of about 50 Å to about 10,000 Å, for example, about 100 Å to about 4,000 Å. When the hole transport region includes a hole injection layer, a hole transport layer, or any combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer, and the hole transport layer are within these ranges, satisfactory hole transporting characteristics may be obtained without a substantial increase in driving voltage.

The emission auxiliary layer may increase light-emission efficiency by compensating for an optical resonance distance according to the wavelength of light emitted by the emission layer, and the electron blocking layer may block or reduce the flow of electrons from the emission layer to the hole transport region. Materials that may be included in the hole transport region may be included in the emission auxiliary layer and the electron-blocking layer.

p-Dopant

The hole transport region may further include, in addition to these materials described above, a charge-generation material for the improvement of conductive properties. The charge-generation material may be uniformly or non-uniformly dispersed in the hole transport region (for example, in the form of a single layer including (e.g., consisting of) a charge-generation material).

The charge-generation material may be, for example, a p-dopant.

For example, the p-dopant may have a lowest unoccupied molecular orbital (LUMO) energy level of equal to or less than −3.5 eV.

In an embodiment, the p-dopant may include a quinone derivative, a cyano group-containing compound, a compound containing element EL1 and element EL2, or any combination thereof.

Examples of the quinone derivative may include TCNQ, F4-TCNQ, and/or the like, and

examples of the cyano group-containing compound may include HAT-CN, a compound represented by Formula 221, and/or the like:

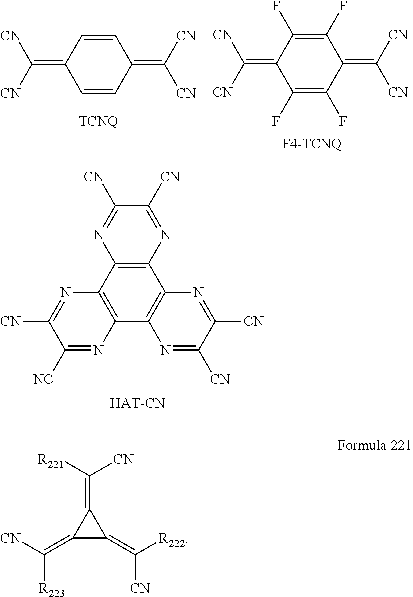

In Formula 221,

R₂₂₁ to R₂₂₃ may each independently be a C₃-C₆₀ carbocyclic group unsubstituted or substituted with at least one R₁₀ₐ or a C₁-C₆ heterocyclic group unsubstituted or substituted with at least one R₁₀ₐ, and

at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound containing element EL1 and element EL2, element EL1 may be metal, metalloid, or any combination thereof, and element EL2 may be non-metal, metalloid, or any combination thereof.

Examples of the metal may include (e.g., may be) an alkali metal (for example, lithium (Li), sodium (Na), potassium (K), rubidium (Rb), cesium (Cs), and/or the like); alkaline earth metal (for example, beryllium (Be), magnesium (Mg), calcium (Ca), strontium (Sr), barium (Ba), and/or the like); transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and/or the like); post-transition metal (for example, zinc (Zn), indium (In), tin (Sn), and/or the like); and lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and/or the like).

Examples of the metalloid may include (e.g., may be) silicon (Si), antimony (Sb), tellurium (Te), and/or the like.

Examples of the non-metal may include (e.g., may be) oxygen (O), halogen (for example, F, Cl, Br, I, and/or the like), and/or the like.

Examples of the compound containing element EL1 and element EL2 may include (e.g., may be) metal oxide, metal halide (for example, metal fluoride, metal chloride, metal bromide, metal iodide, and/or the like), metalloid halide (for example, metalloid fluoride, metalloid chloride, metalloid bromide, metalloid iodide, and/or the like), metal telluride, or any combination thereof.

Examples of the metal oxide may include (e.g., may be) tungsten oxide (for example, WO, W₂O₃, WO₂, WO₃, W₂O₅, and/or the like), vanadium oxide (for example, VO, V₂O₃, VO₂, V₂O₅, and/or the like), molybdenum oxide (MoO, Mo₂O₃, MoO₂, MoO₃, Mo₂O₅, and/or the like), rhenium oxide (for example, ReO₃, and/or the like), and/or the like.

Examples of the metal halide may include (e.g., may be) alkali metal halide, alkaline earth metal halide, transition metal halide, post-transition metal halide, lanthanide metal halide, and/or the like.

Examples of the alkali metal halide may include (e.g., may be) LiF, NaF, KF, RbF, CsF, LiCl, NaCl, KCl, RbCl, CsCl, LiBr, NaBr, KBr, RbBr, CsBr, LiI, NaI, KI, RbI, CsI, and/or the like.

Examples of the alkaline earth metal halide may include (e.g., may be) BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, BaI₂, and/or the like.

Examples of the transition metal halide may include (e.g., may be) titanium halide (for example, TiF₄, TiCl₄, TiBr₄, TiI₄, and/or the like), zirconium halide (for example, ZrF₄, ZrCl₄, ZrBr₄, ZrI₄, and/or the like), hafnium halide (for example, HfF₄, HfCl₄, HfBr₄, HfI₄, and/or the like), vanadium halide (for example, VF₃, VCl₃, VBr₃, VI₃, and/or the like), niobium halide (for example, NbF₃, NbCl₃, NbBr₃, NbI₃, and/or the like), tantalum halide (for example, TaF₃, TaCl₃, TaBr₃, TaI₃, and/or the like), chromium halide (for example, CrF₃, CrCl₃, CrBr₃, CrI₃, and/or the like), molybdenum halide (for example, MoF₃, MoCl₃, MoBr₃, MoI₃, and/or the like), tungsten halide (for example, WF₃, WCl₃, WBr₃, WI₃, and/or the like), manganese halide (for example, MnF₂, MnCl₂, MnBr₂, MnI₂, and/or the like), technetium halide (for example, TcF₂, TcCl₂, TcBr₂, TcI₂, and/or the like), rhenium halide (for example, ReF₂, ReCl₂, ReBr₂, ReI₂, and/or the like), iron halide (for example, FeF₂, FeCl₂, FeBr₂, FeI₂, and/or the like), ruthenium halide (for example, RuF₂, RuCl₂, RuBr₂, RuI₂, and/or the like), osmium halide (for example, OsF₂, OsC₁₂, OsBr₂, OsI₂, and/or the like), cobalt halide (for example, CoF₂, CoCl₂, CoBr₂, CoI₂, and/or the like), rhodium halide (for example, RhF₂, RhCl₂, RhBr₂, RhI₂, and/or the like), iridium halide (for example, IrF₂, IrCl₂, IrBr₂, IrI₂, and/or the like), nickel halide (for example, NiF₂, NiCl₂, NiBr₂, NiI₂, and/or the like), palladium halide (for example, PdF₂, PdCl₂, PdBr₂, PdI₂, and/or the like), platinum halide (for example, PtF₂, PtCl₂, PtBr₂, PtI₂, and/or the like), copper halide (for example, CuF, CuCl, CuBr, CuI, and/or the like), silver halide (for example, AgF, AgCl, AgBr, AgI, and/or the like), gold halide (for example, AuF, AuCl, AuBr, AuI, and/or the like), and/or the like.

Examples of the post-transition metal halide may include (e.g., may be) zinc halide (for example, ZnF₂, ZnCl₂, ZnBr₂, ZnI₂, and/or the like), indium halide (for example, InI₃, etc.), tin halide (for example, SnI₂, and/or the like), and/or the like.

Examples of the lanthanide metal halide may include (e.g., may be) YbF, YbF₂, YbF₃, SmF₃, YbCl, YbCl₂, YbCl₃ SmCl₃, YbBr, YbBr₂, YbBr₃, SmBr₃, YbI, YbI₂, YbI₃, SmI₃, and/or the like.

Examples of the metalloid halide may include (e.g., may be) antimony halide (for example, SbCl₅, and/or the like), and/or the like.

Examples of the metal telluride may include (e.g., may be) alkali metal telluride (for example, Li₂Te, Na₂Te, K₂Te, Rb₂Te, Cs₂Te, and/or the like), alkaline earth metal telluride (for example, BeTe, MgTe, CaTe, SrTe, BaTe, and/or the like), transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, and/or the like), post-transition metal telluride (for example, ZnTe, and/or the like), lanthanide metal telluride (for example, LaTe, CeTe, PrTe, NdTe, PmTe, EuTe, GdTe, TbTe, DyTe, HoTe, ErTe, TmTe, YbTe, LuTe, and/or the like), and/or the like.

### Emission Layer in Interlayer 130

When the light-emitting device 30 is a full-color light-emitting device, the emission layer may be patterned into a red emission layer, a green emission layer, and/or a blue emission layer according to sub-pixels. In an embodiment, the emission layer may have a stacked structure of two or more layers of a red emission layer, a green emission layer, and a blue emission layer, in which the two or more layers contact each other or are separated from each other to emit white light. In one or more embodiments, the emission layer may have a structure in which two or more materials of a red light-emitting material, a green light-emitting material, and a blue light-emitting material are mixed with each other in a single layer to emit white light.

In an embodiment, the emission layer may include a host and a dopant. The dopant may include a phosphorescent dopant, a fluorescent dopant, or any combination thereof.

In the emission layer, an amount of the dopant may be in a range of about 0.01 parts by weight to about 15 parts by weight based on 100 parts by weight of the host.

In one or more embodiments, the emission layer may include the quantum dots 1.

In one or more embodiments, the emission layer may include a delayed fluorescence material. The delayed fluorescence material may act as a host or a dopant in the emission layer.

A thickness of the emission layer may be in a range of about 100 Å to about 1,000 Å, for example, about 200 Å to about 600 Å. When the thickness of the emission layer is within these ranges, excellent luminescence characteristics may be obtained without a substantial increase in driving voltage.

### Host

In an embodiment, the host may include a compound represented by Formula 301:

[Ar₃₀₁]_{xb11}-[(L₃₀₁)_{xb1}-R₃₀₁]_{xb21}, Formula 301

wherein, in Formula 301,

Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xb11 may be 1, 2, or 3,

xb1 may be an integer from 0 to 5,

R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),

xb21 may be an integer from 1 to 5, and

Q₃₀₁ to Q₃₀₃ may respectively be the same as described in connection with Q₁.

For example, when xb11 in Formula 301 is 2 or more, two or more of Ar₃₀₁(s) may be linked to each other via a single bond.

In one or more embodiments, the host may include a compound represented by Formula 301-1, a compound represented by Formula 301-2, or any combination thereof:

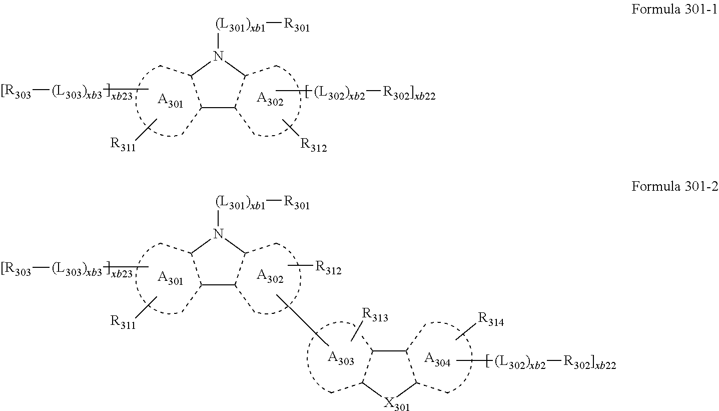

wherein, in Formulae 301-1 and 301-2,

ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

X₃₀₁ may be O, S, N-[(L₃₀₄)_{xb4}-R₃₀₄], C(R₃₀₄)(R₃₀₅), or Si(R₃₀₄)(R₃₀₅),

xb22 and xb23 may each independently be 0, 1, or 2,

L₃₀₁, xb1, and R₃₀₁ may respectively be the same as described herein,

L₃₀₂ to L₃₀₄ may each independently be the same as described in connection with L₃₀₁,

xb2 to xb4 may each independently be the same as described in connection with xb1, and

R₃₀₂ to R₃₀₅ and R₃₁₁ to R₃₁₄ may respectively be the same as described in connection with R₃₀₁.

In one or more embodiments, the host may include an alkali earth metal complex, a post-transition metal complex, or any combination thereof. For example, the host may include a Be complex (for example, Compound H55), an Mg complex, a Zn complex, or any combination thereof.

In one or more embodiments, the host may include one of Compounds H1 to H124, 9,10-di(2-naphthyl)anthracene (ADN), 2-methyl-9,10-bis(naphthalen-2-yl)anthracene (MADN), 9,10-di-(2-naphthyl)-2-t-butyl-anthracene (TBADN), 4,4′-bis(N-carbazolyl)-1,1′-biphenyl (CBP), 1,3-di-9-carbazolylbenzene (mCP), 1,3,5-tri(carbazol-9-yl)benzene (TCP), or any combination thereof:

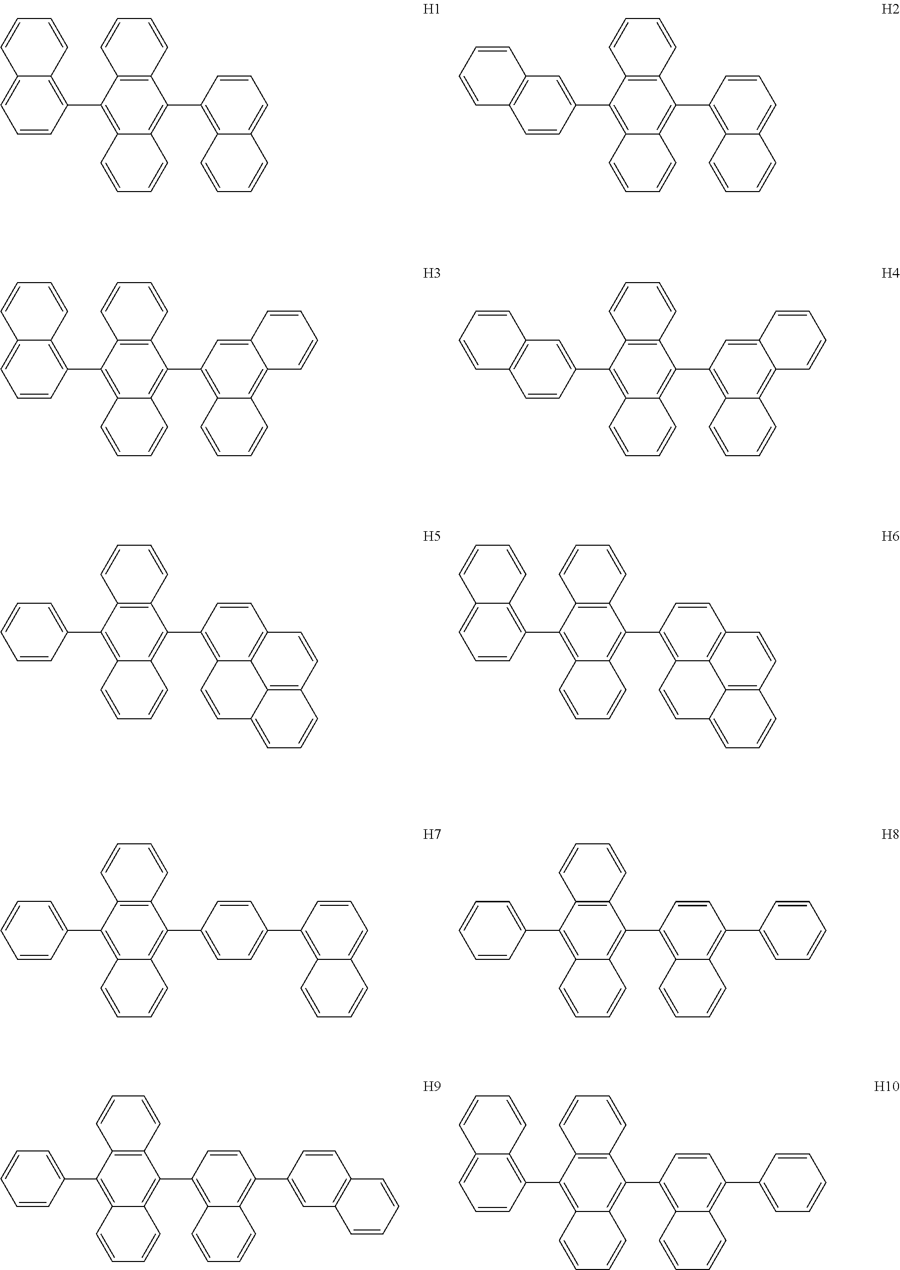

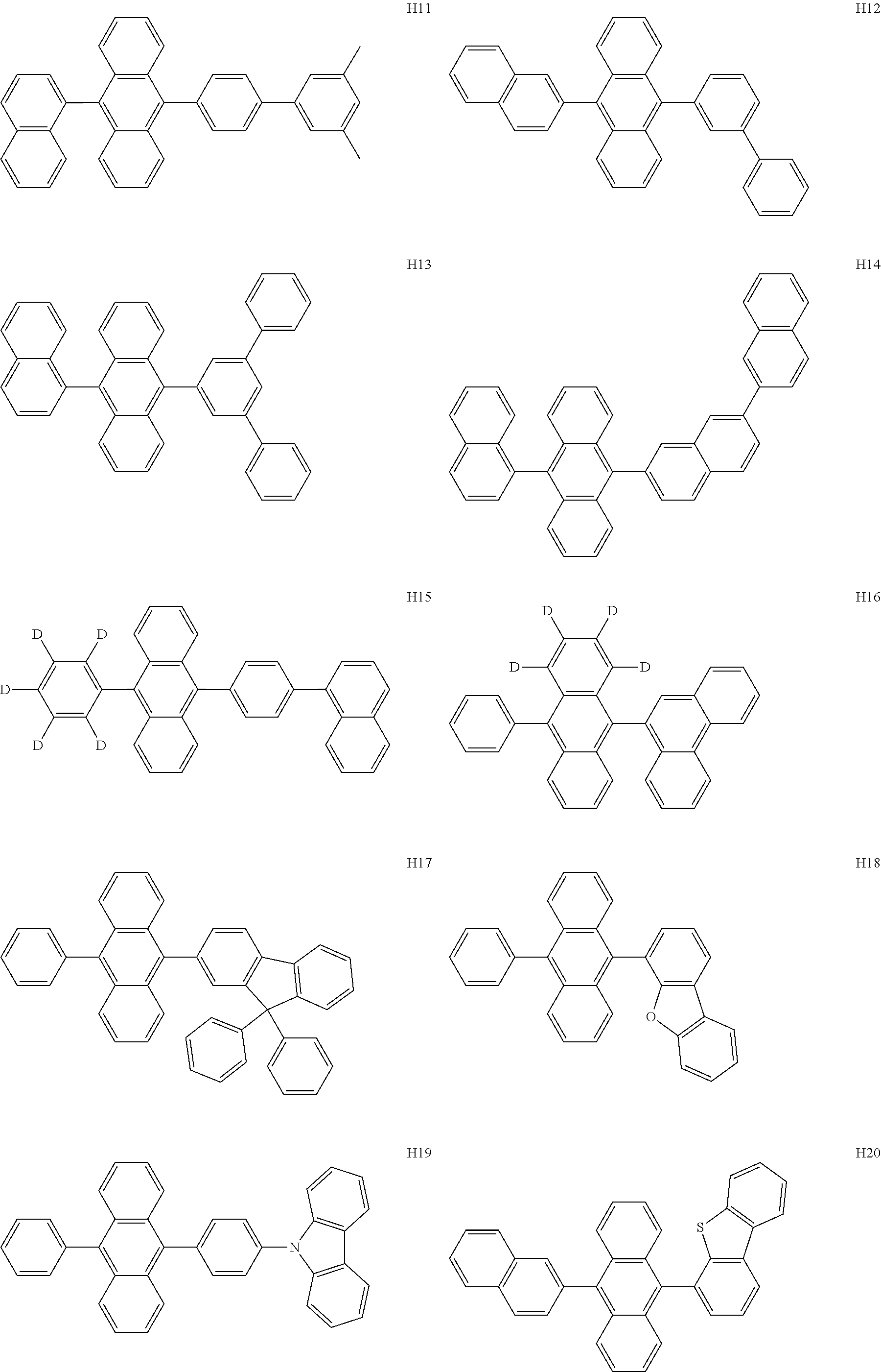

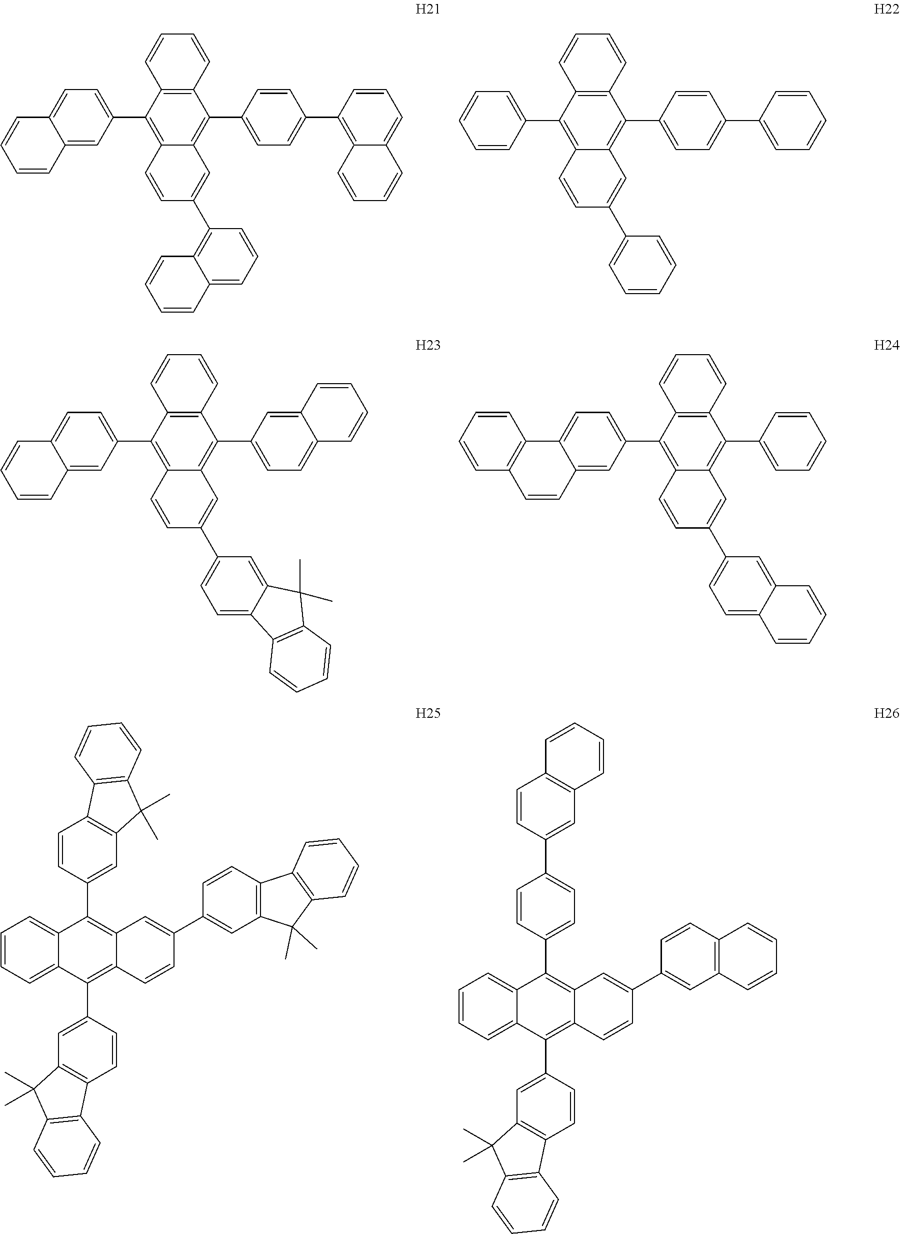

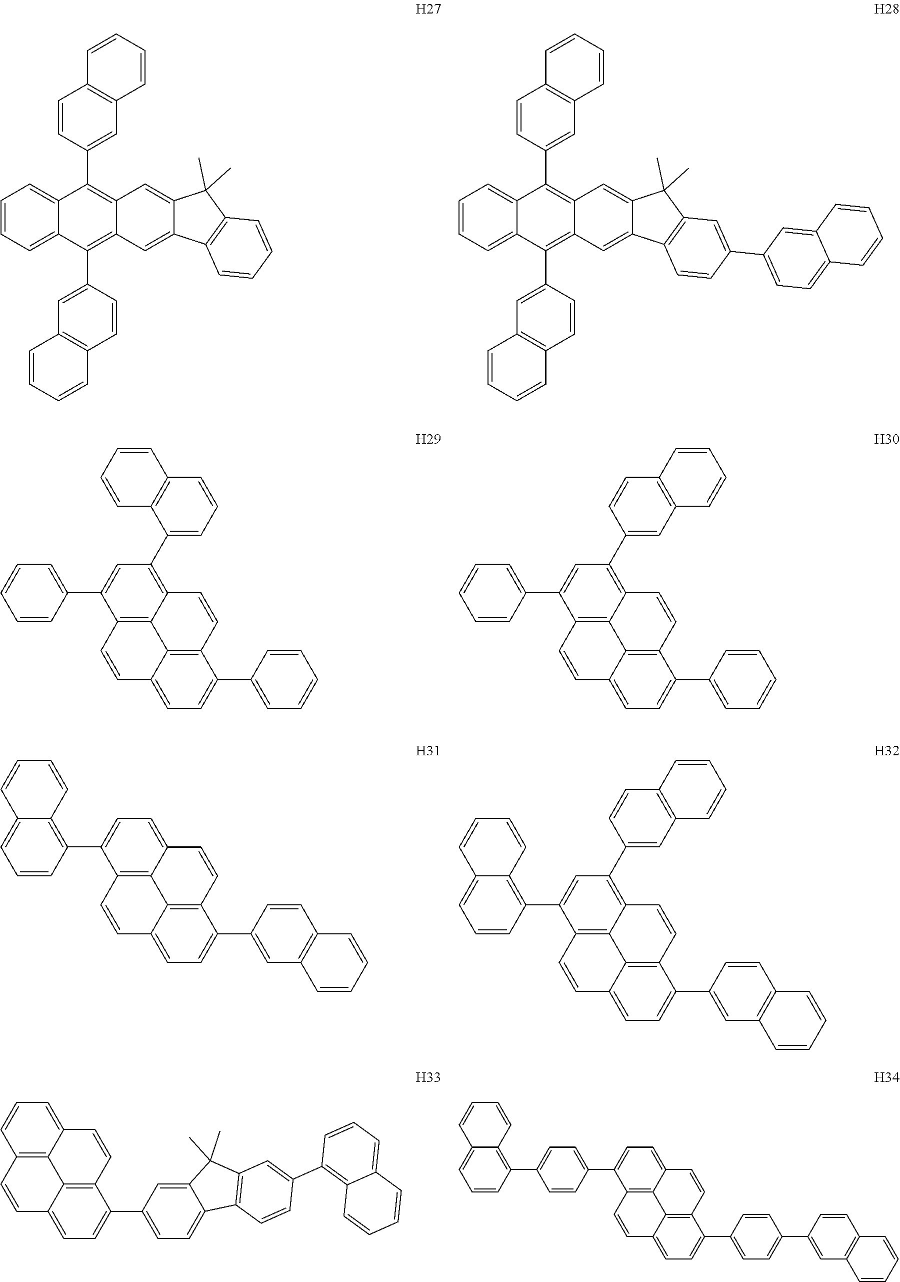

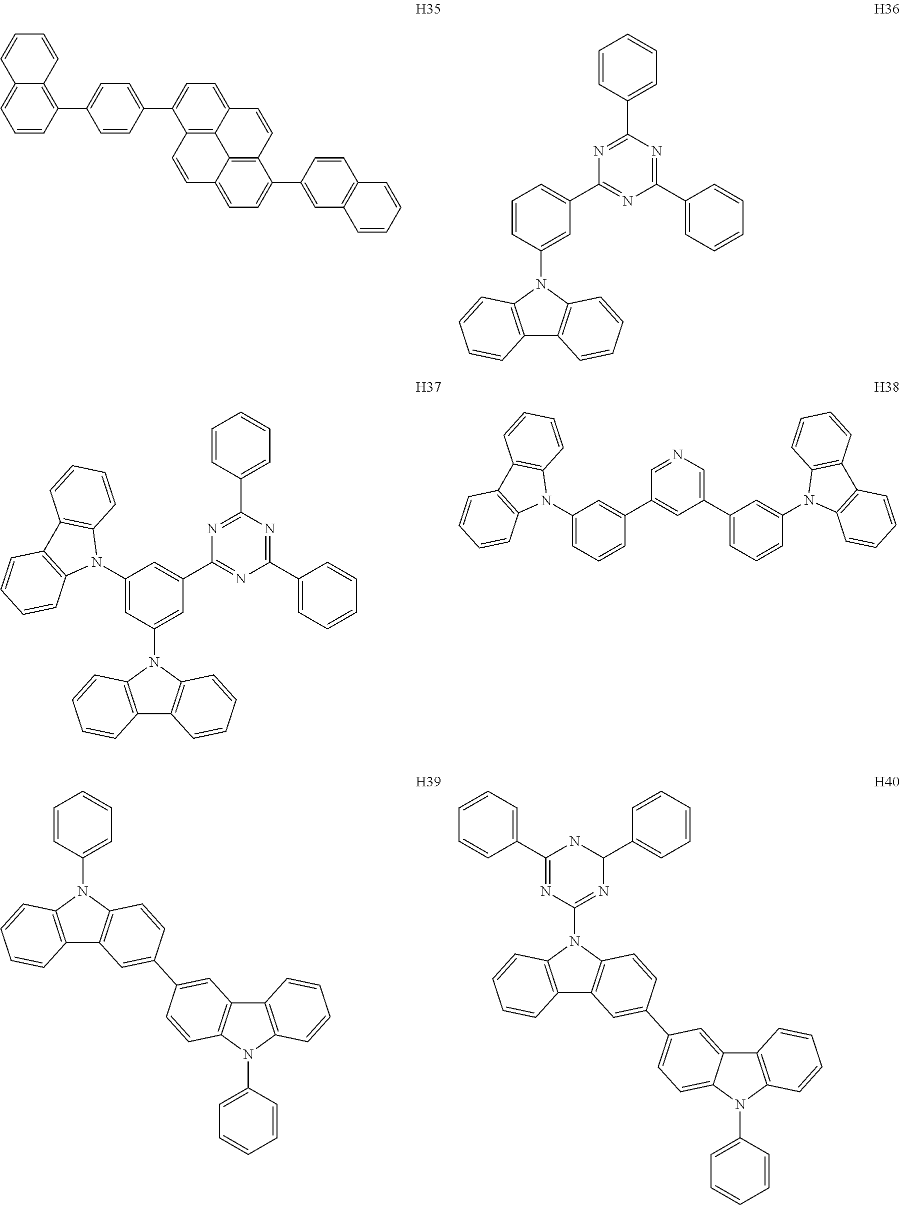

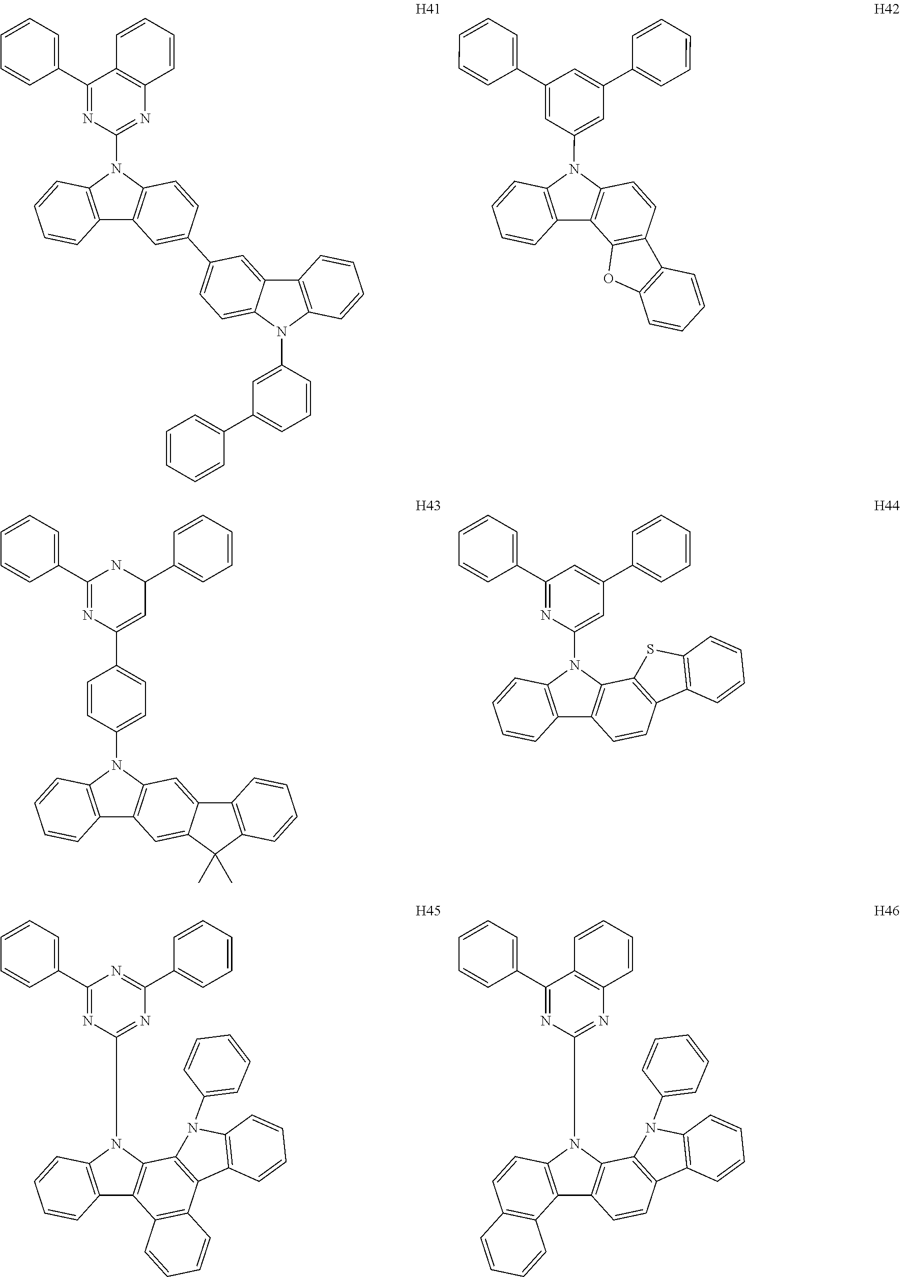

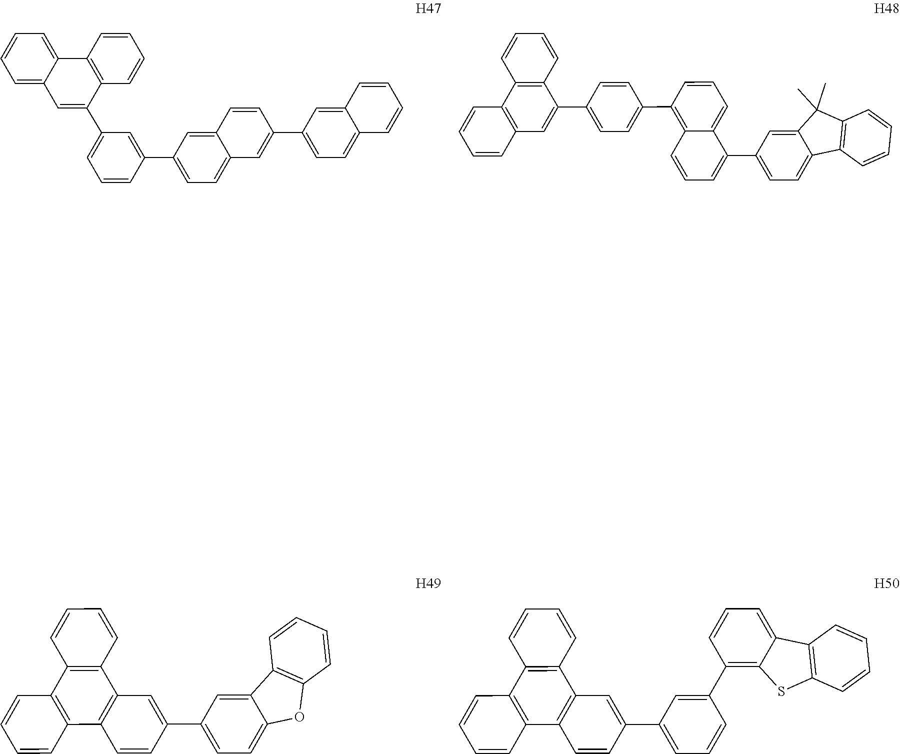

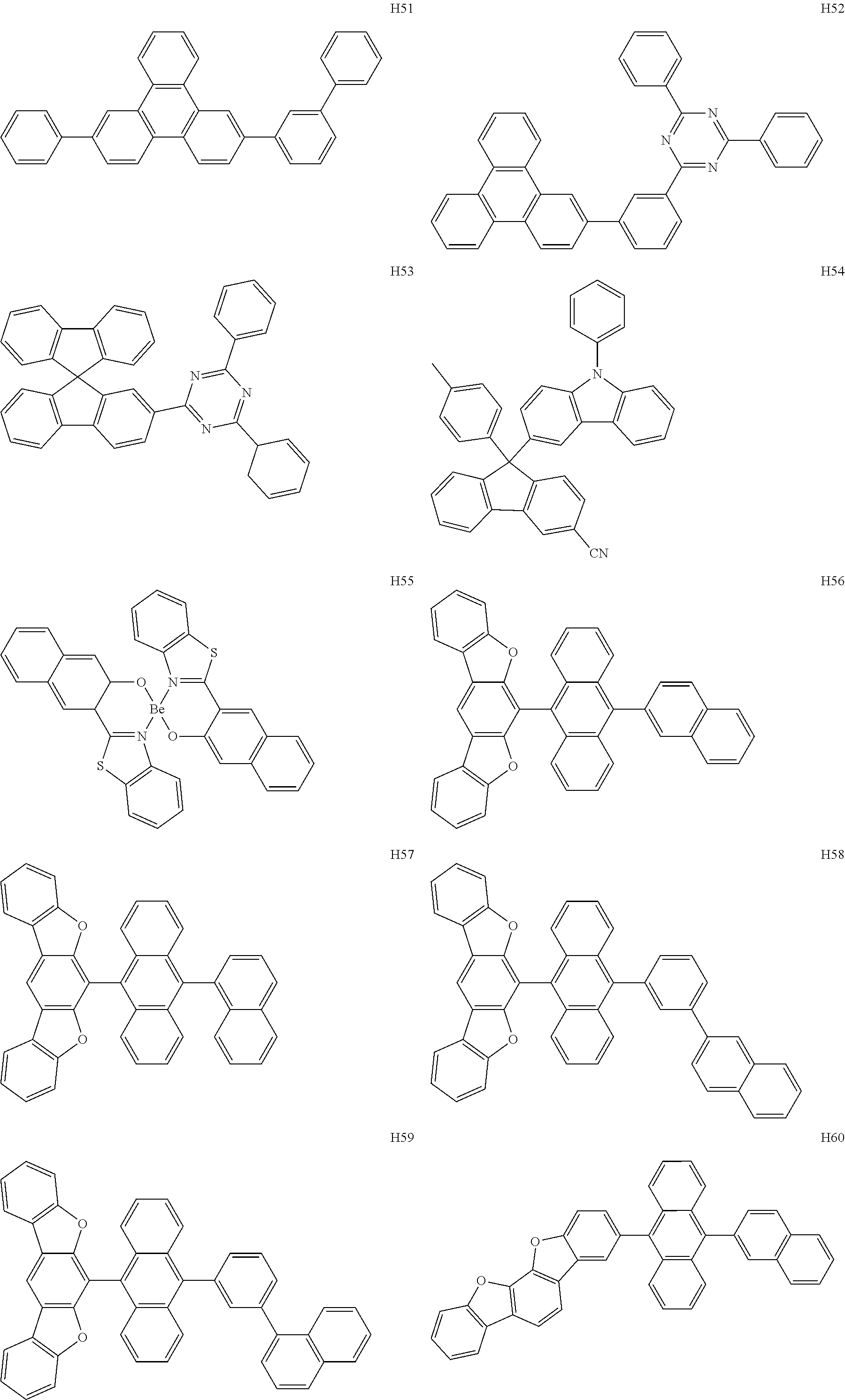

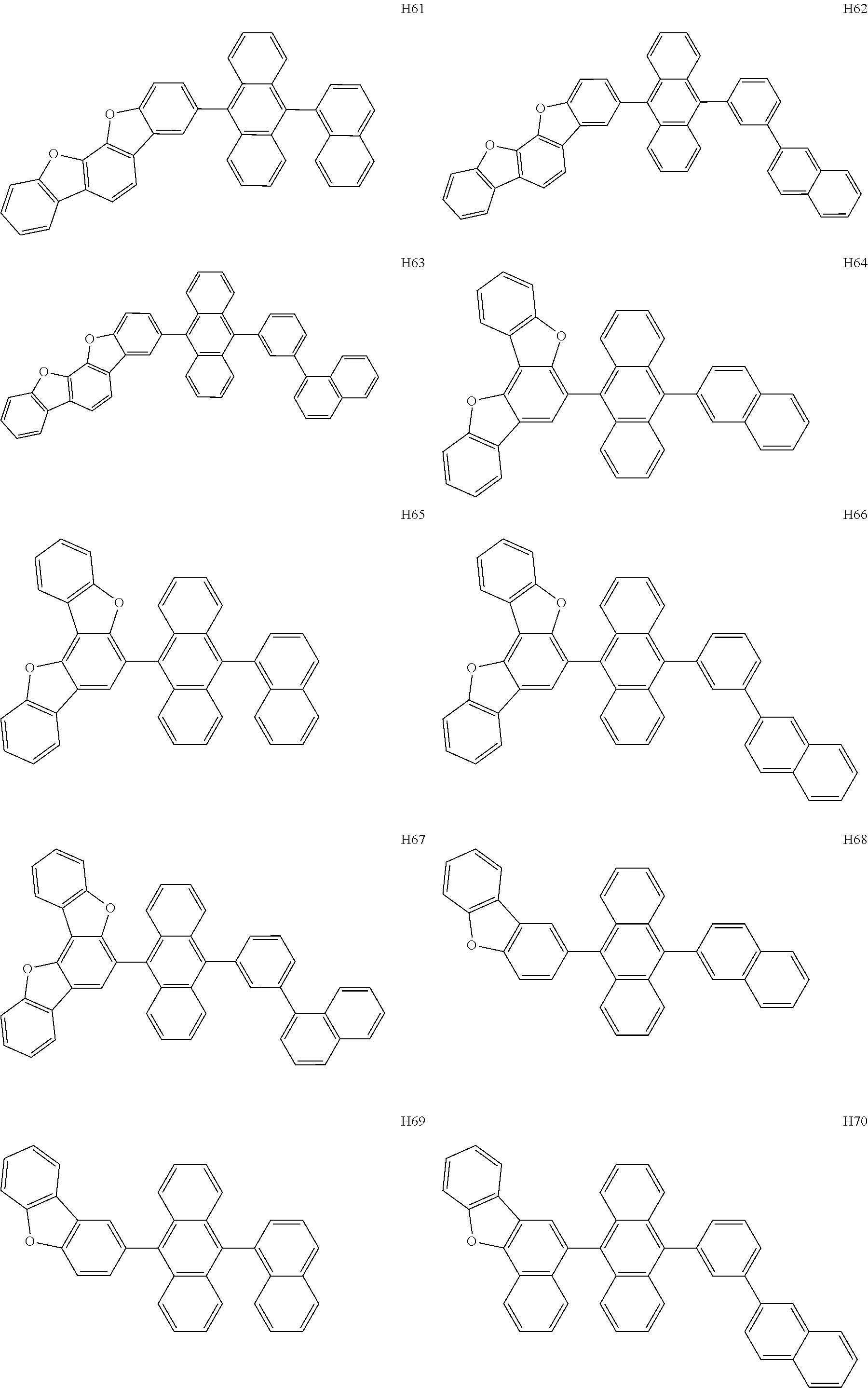

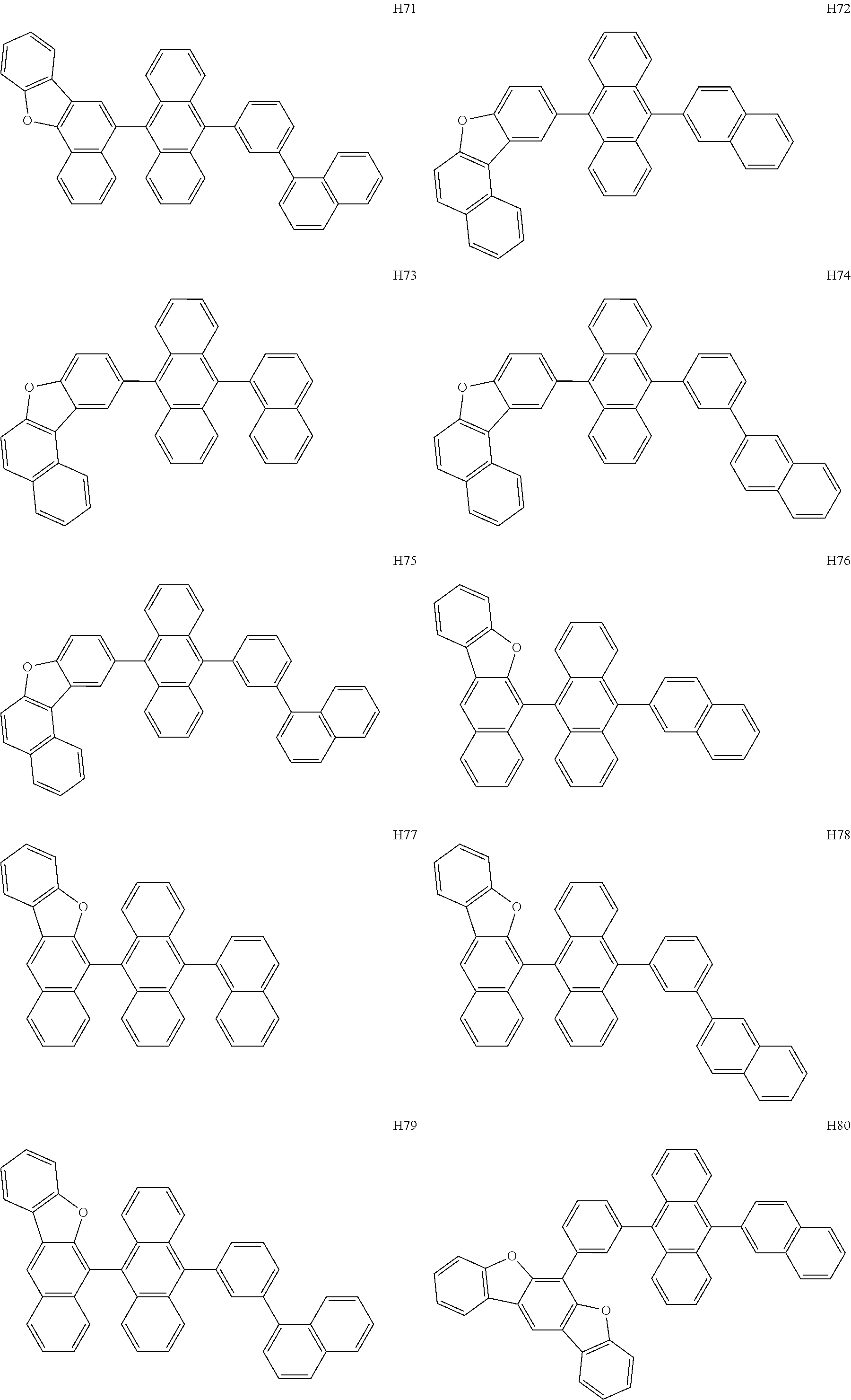

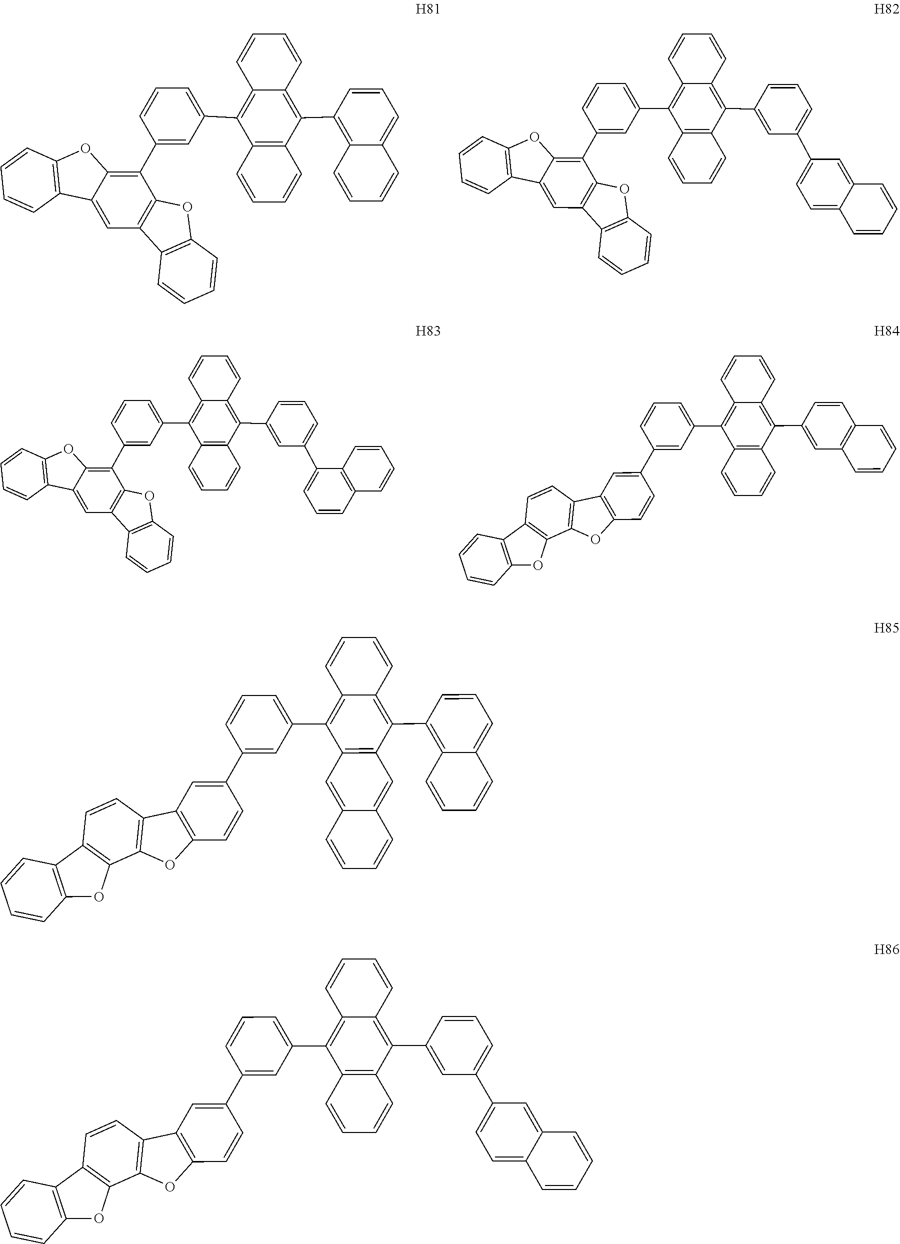

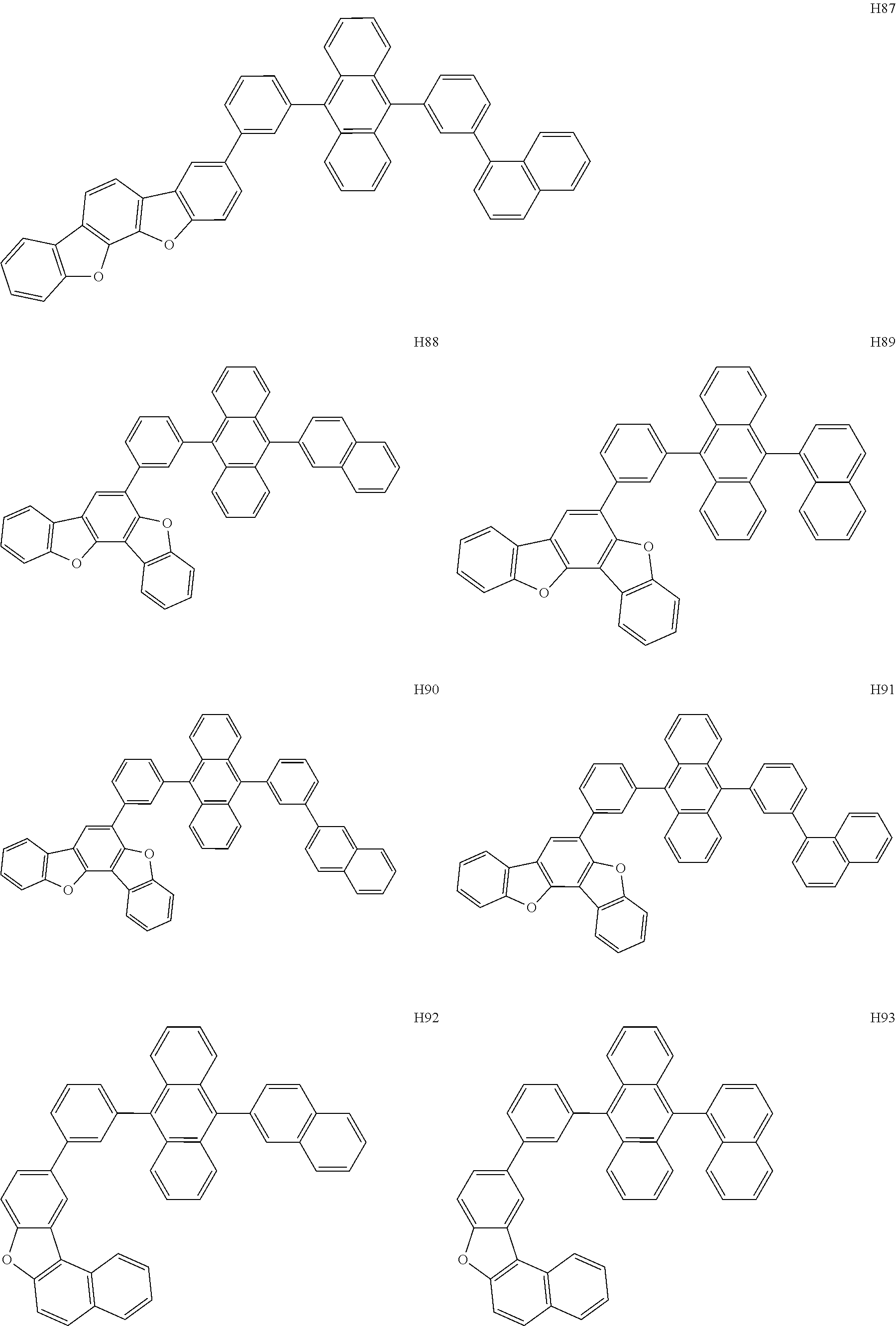

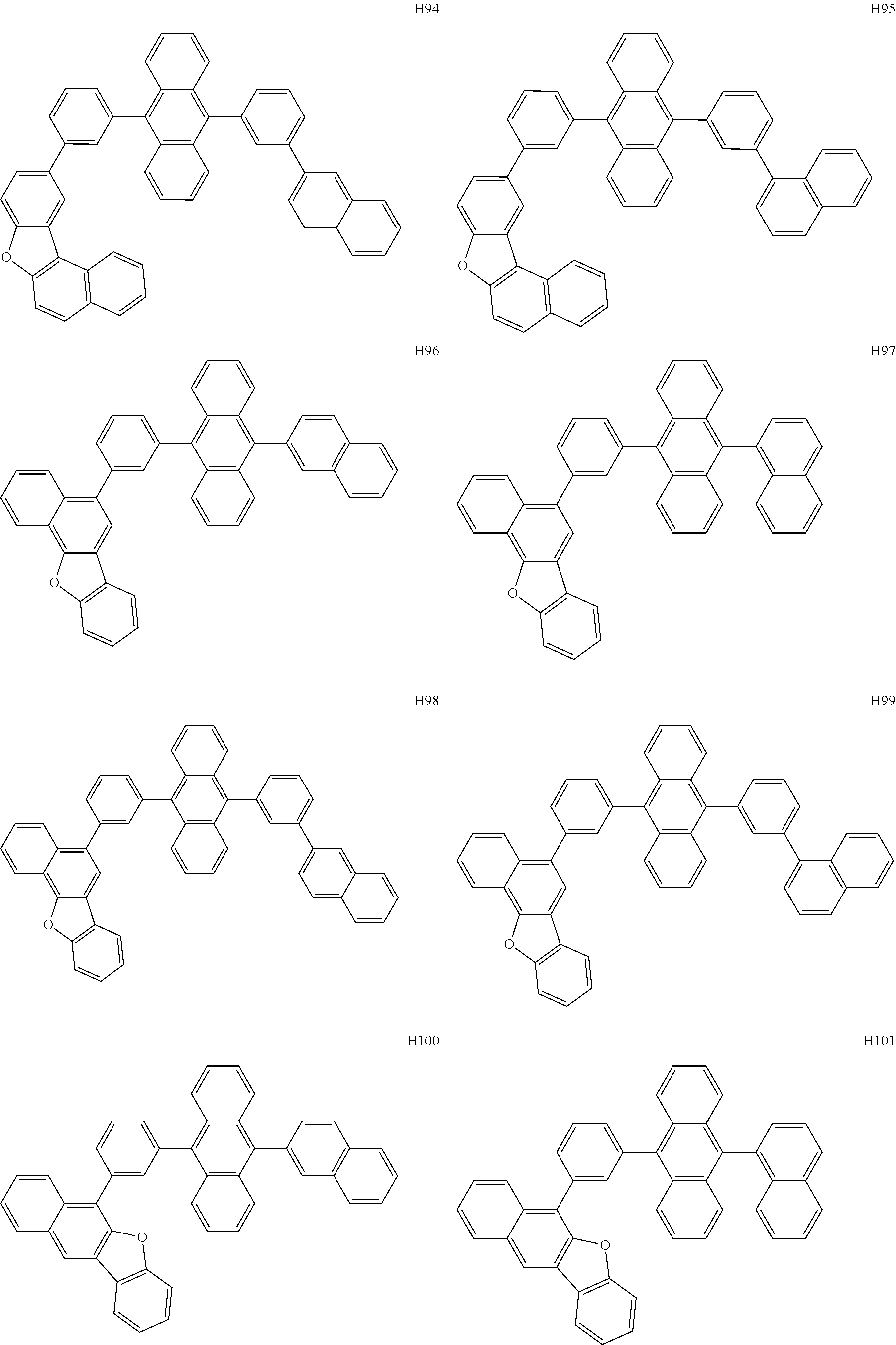

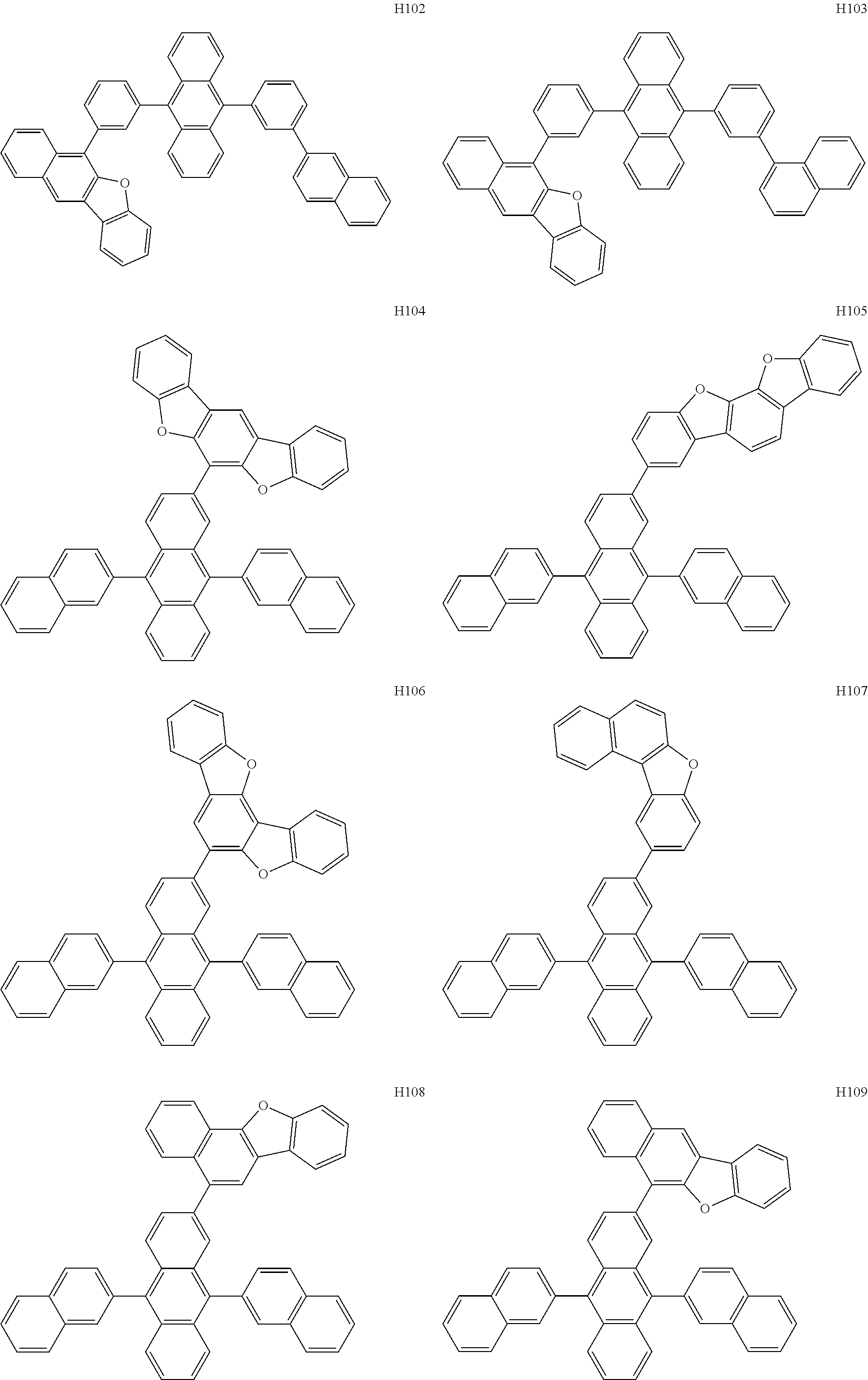

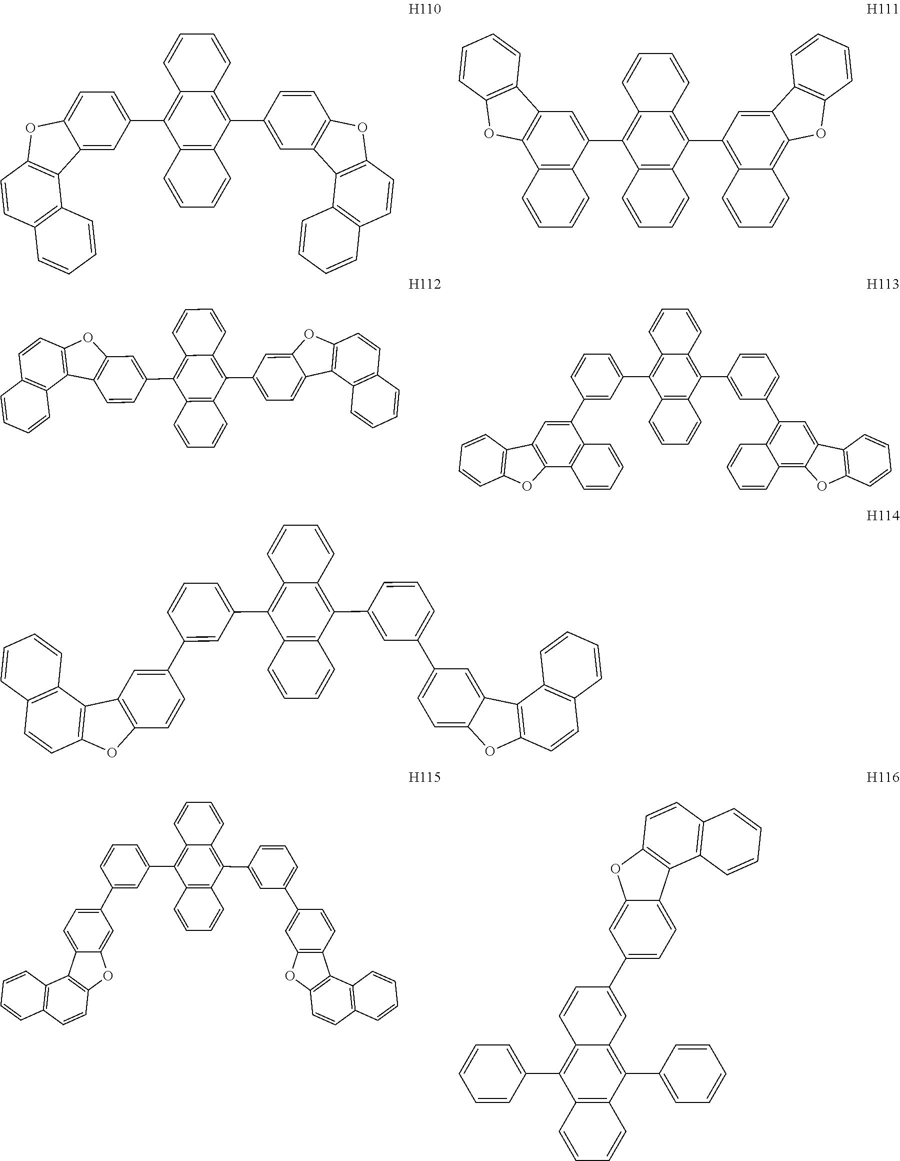

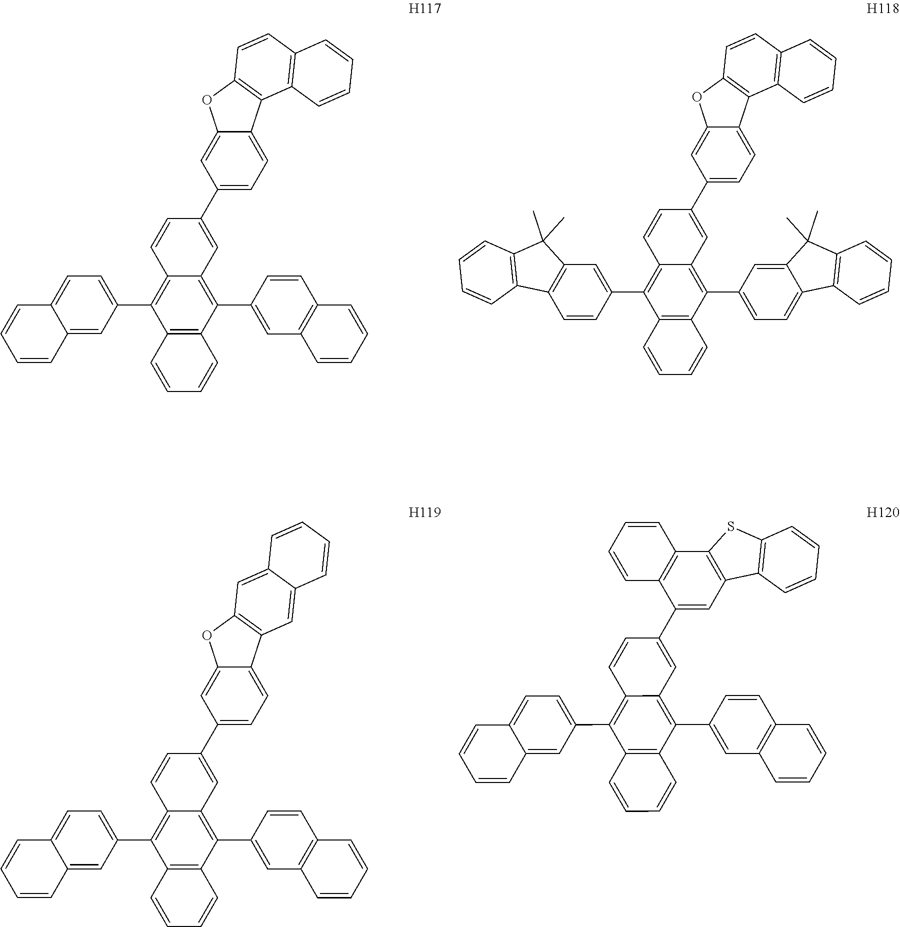 [SMILES: c1ccc2cc(-c3c4ccccc4c(-c4ccc5ccccc5c4)c4cc(-c5ccc6c(c5)oc5ccc7ccccc7c56)ccc34)ccc2c1 ; CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21 ; c1ccc2cc(-c3c4ccccc4c(-c4ccc5ccccc5c4)c4cc(-c5ccc6c(c5)oc5cc7ccccc7cc56)ccc34)ccc2c1 ; c1ccc2cc(-c3c4ccccc4c(-c4ccc5ccccc5c4)c4cc(-c5cc6c7ccccc7sc6c6ccccc56)ccc34)ccc2c1]

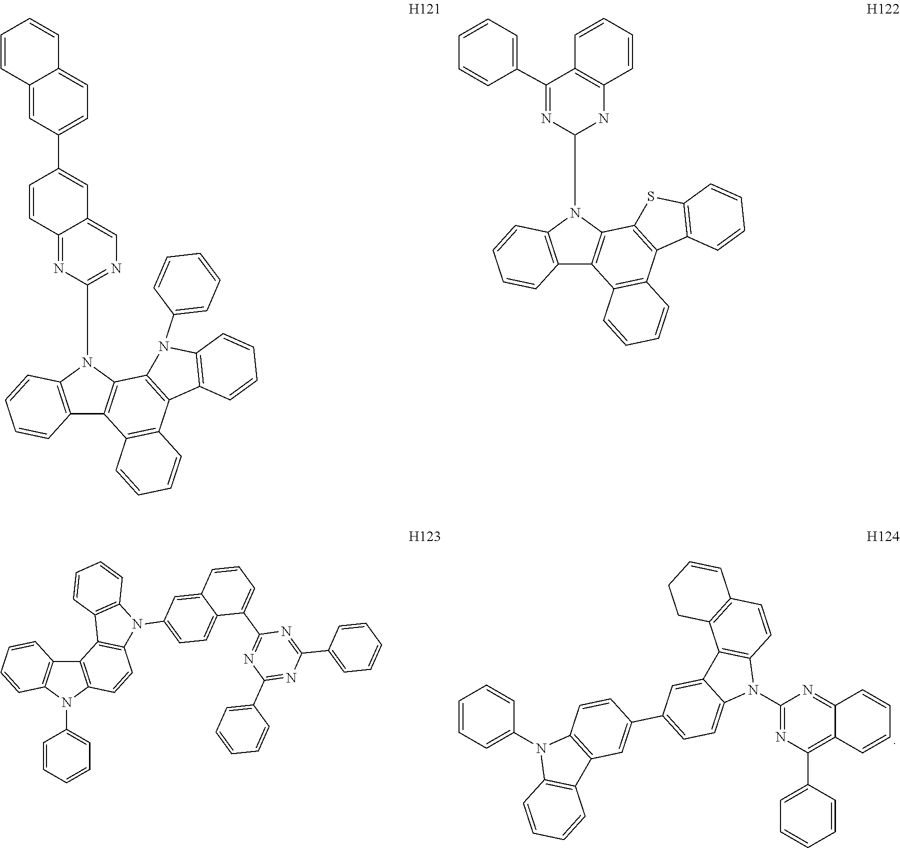

### Phosphorescent Dopant

In an embodiment, the phosphorescent dopant may include at least one transition metal as a central metal.

In an embodiment, the phosphorescent dopant may include a monodentate ligand, a bidentate ligand, a tridentate ligand, a tetradentate ligand, a pentadentate ligand, a hexadentate ligand, or any combination thereof.

In an embodiment, the phosphorescent dopant may be electrically neutral.

In an embodiment, the phosphorescent dopant may include an organometallic compound represented by Formula 401:

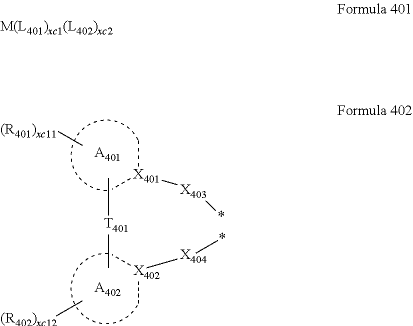

wherein, in Formulae 401 and 402,

M may be transition metal (for example, iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),

L₄₀₁ may be a ligand represented by Formula 402, and xc1 may be 1, 2, or 3, wherein, when xc1 is 2 or more, two or more of L₄₀₁(s) may be identical to or different from each other,

L₄₀₂ may be an organic ligand, and xc2 may be 0, 1, 2, 3, or 4, wherein, when xc2 is 2 or more, two or more of L₄₀₂(s) may be identical to or different from each other,

X₄₀₁ and X₄₀₂ may each independently be nitrogen or carbon,

ring A₄₀₁ and ring A₄₀₂ may each independently be a C₃-C₆₀ carbocyclic group or a C₁-C₆₀ heterocyclic group,

T₄₀₁ may be a single bond, *—O—*′, *—S—*′, *—C(═O)—*′, *—N(Q₄₁₁)-*′*—C(Q₄₁₁)(Q₄₁₂)*′, *—C(Q₄₁₁)=C(Q₄₁₂)-*′, *—C(Q₄₁₁)=*′, or *═C═*′,

X₄₀₃ and X₄₀₄ may each independently be a chemical bond (for example, a covalent bond or a coordinate bond), O, S, N(Q₄₁₃), B(Q₄₁₃), P(Q₄₁₃), C(Q₄₁₃)(Q₄₁₄), or Si(Q₄₁₃)(Q₄₁₄),

Q₄₁₁ to Q₄₁₄ may respectively be the same as described in connection with Q₁,

R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),

Q₄₀₁ to Q₄₀₃ may respectively be the same as described in connection with Q₁,

xc11 and xc12 may each independently be an integer from 0 to 10, and

* and *′ in Formula 402 each indicate a binding site to M in Formula 401.

For example, in Formula 402, i) X₄₀₁ may be nitrogen and X₄₀₂ may be carbon, or ii) each of X₄₀₁ and X₄₀₂ may be nitrogen.

When xc1 in Formula 401 is 2 or more, two ring A₄₀₁(s) in two or more of L₄₀₁(s) may optionally be linked to each other via T₄₀₂, which is a linking group, and two ring A₄₀₂(s) in two or more of L₄₀₁(s) may optionally be linked to each other via T₄₀₃, which is a linking group (see Compounds PD1 to PD4 and PD7), wherein T₄₀₂ and T₄₀₃ may respectively be the same as described in connection with T₄₀₁.

In Formula 401, L₄₀₂ may be any suitable organic ligand. For example, L₄₀₂ may include a halogen group, a diketone group (for example, an acetylacetonate group), a carboxylic acid group (for example, a picolinate group), —C(═O), an isonitrile group, a —CN group, a phosphorus group (for example, a phosphine group, a phosphite group, and/or the like), or any combination thereof.

In one or more embodiments, the phosphorescent dopant may include, for example, one of Compounds PD1 to PD39, or any combination thereof:

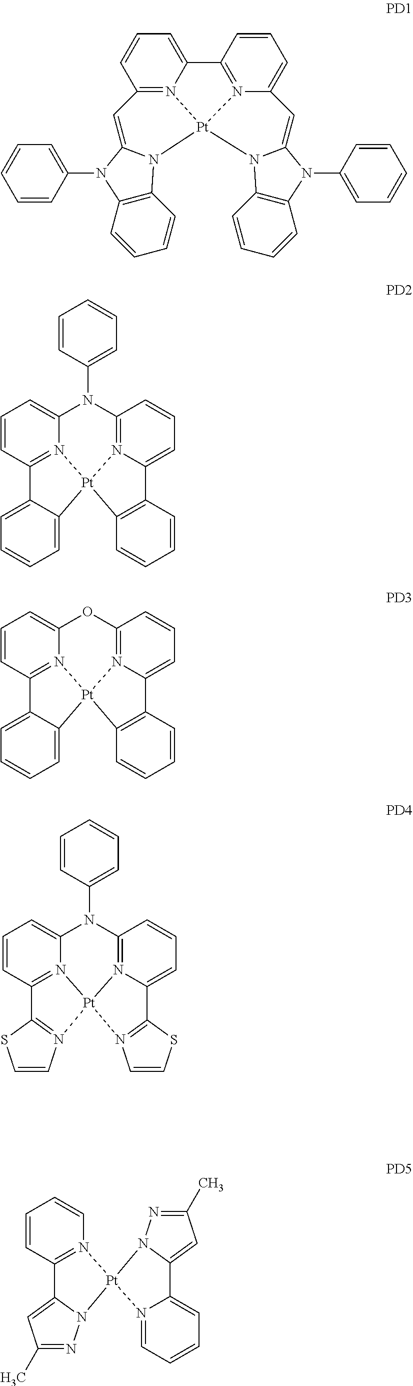

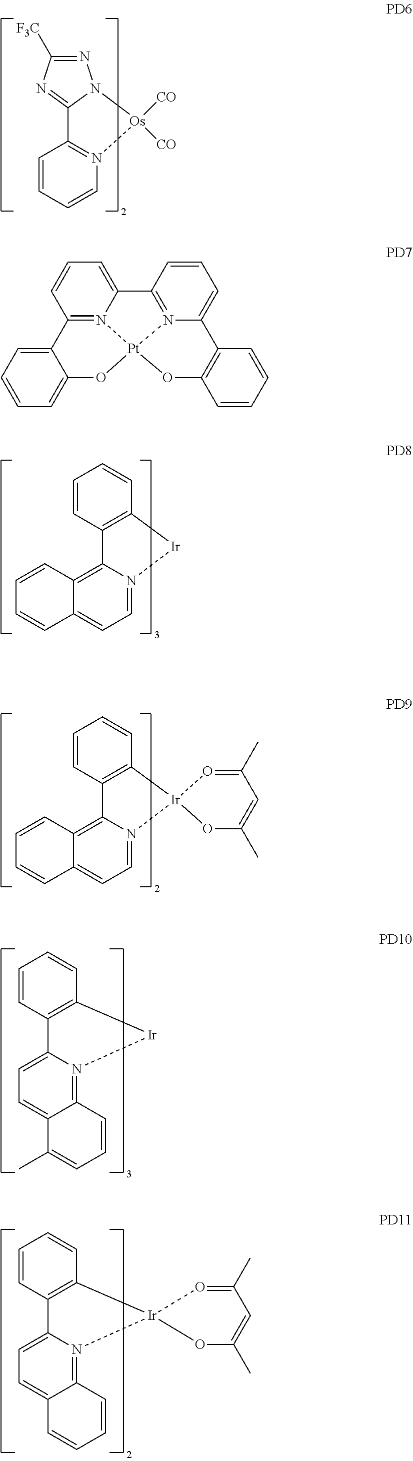

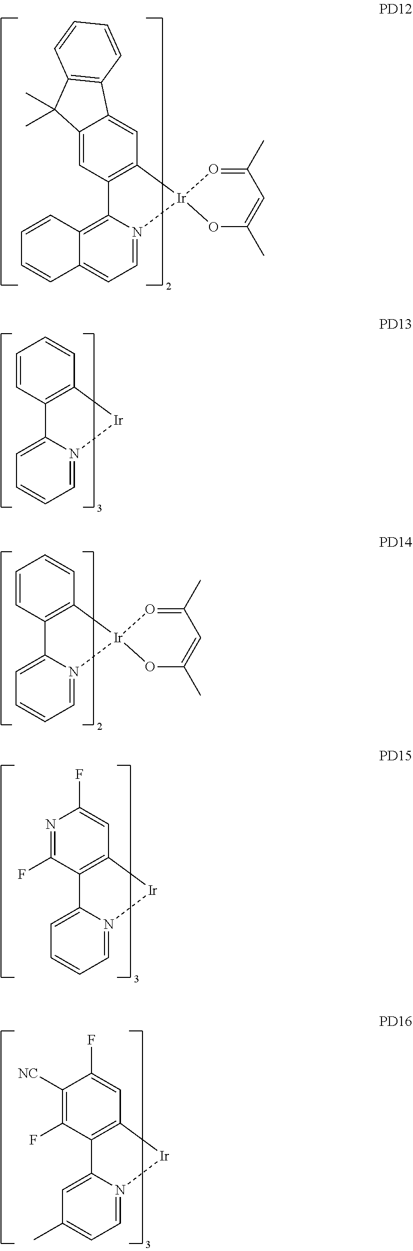

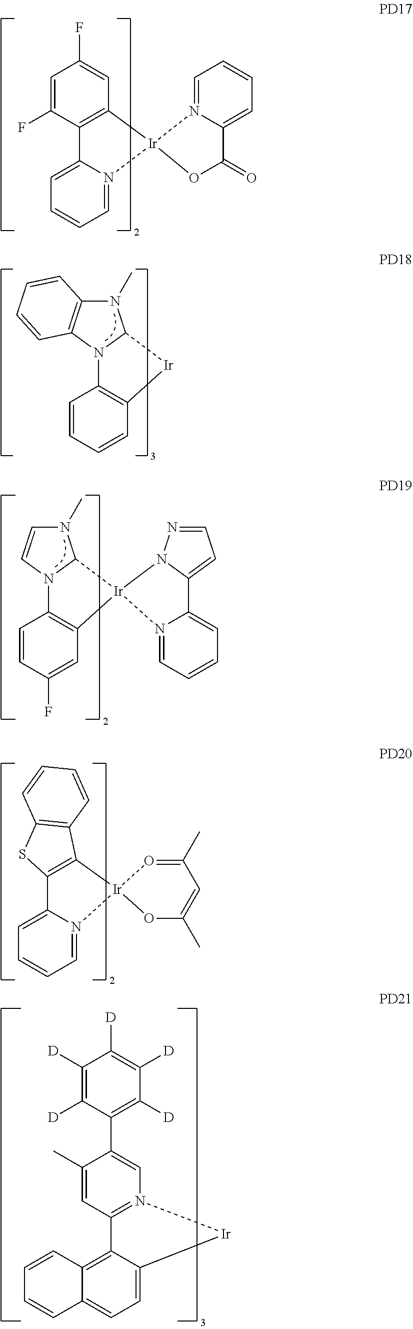

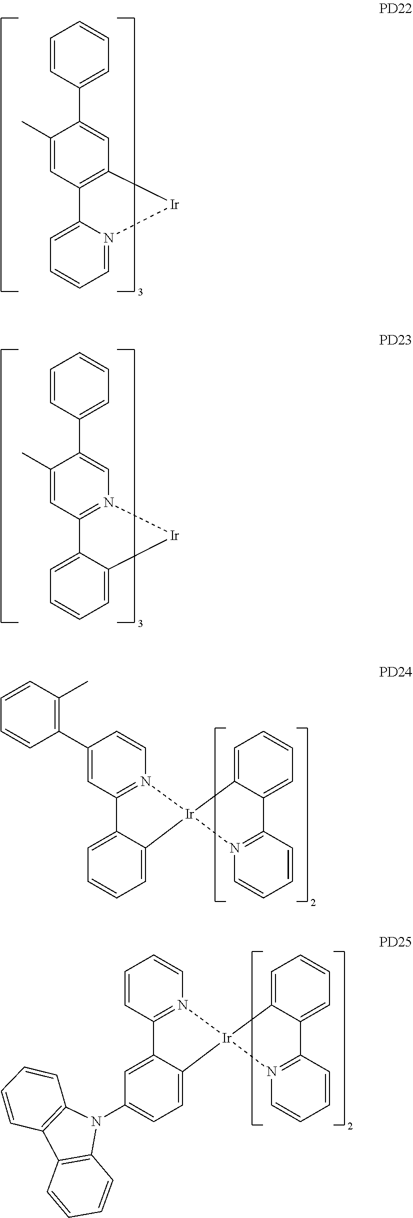

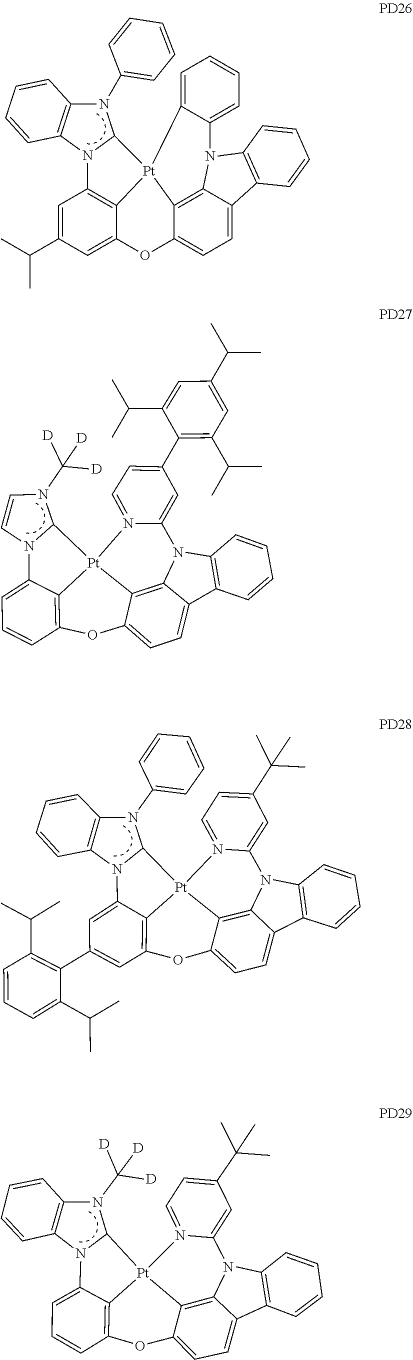

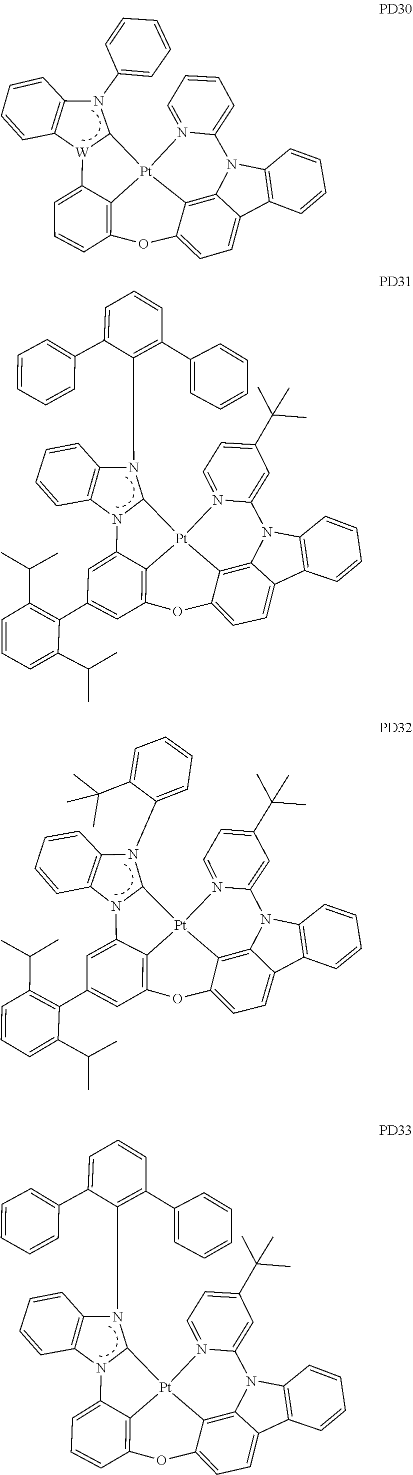

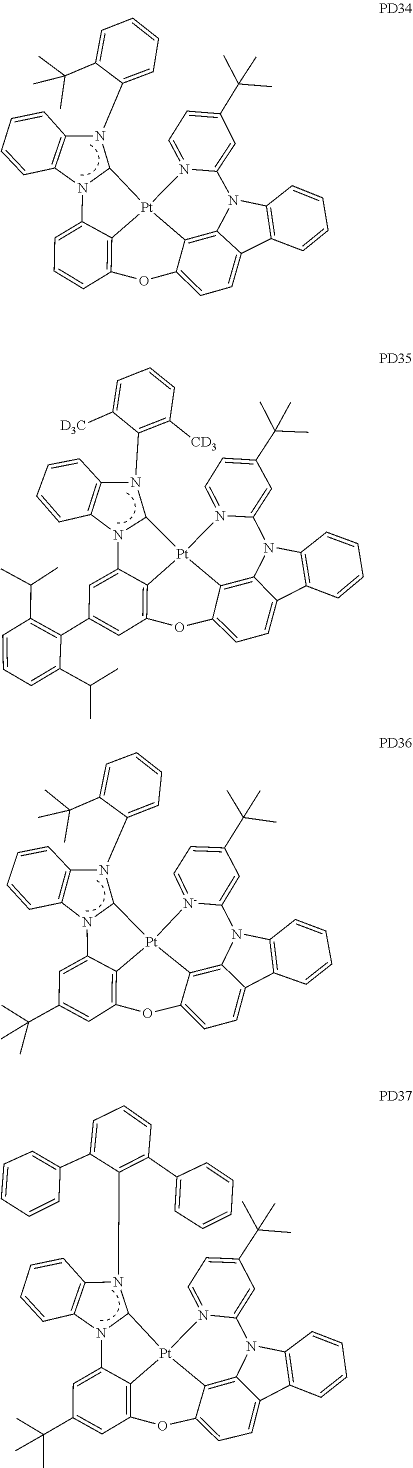

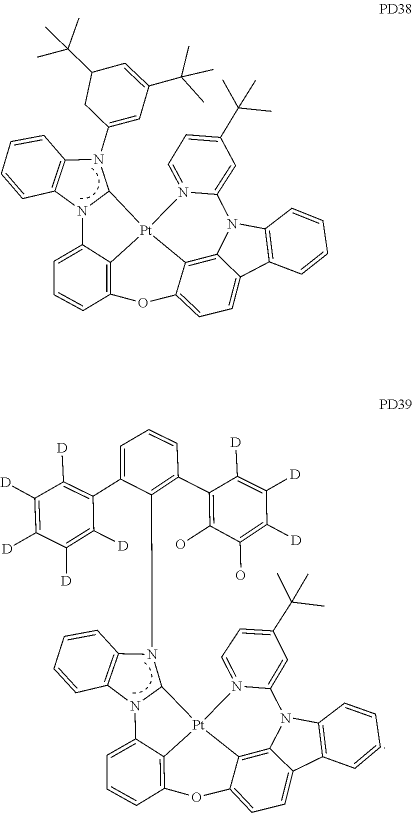

### Fluorescent Dopant

In an embodiment, the fluorescent dopant may include an amine group-containing compound, a styryl group-containing compound, or any combination thereof.

In one or more embodiments, the fluorescent dopant may include a compound represented by Formula 501:

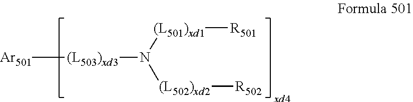

wherein, in Formula 501,

Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xd1 to xd3 may each independently be 0, 1, 2, or 3, and

xd4 may be 1, 2, 3, 4, 5, or 6.

For example, Ar₅₀₁ in Formula 501 may be a condensed cyclic group (for example, an anthracene group, a chrysene group, or a pyrene group) in which three or more monocyclic groups are condensed together.

For example, xd4 in Formula 501 may be 2.

In one or more embodiments, the fluorescent dopant may include: one of Compounds FD1 to FD36; DPVBi; DPAVBi; or any combination thereof:

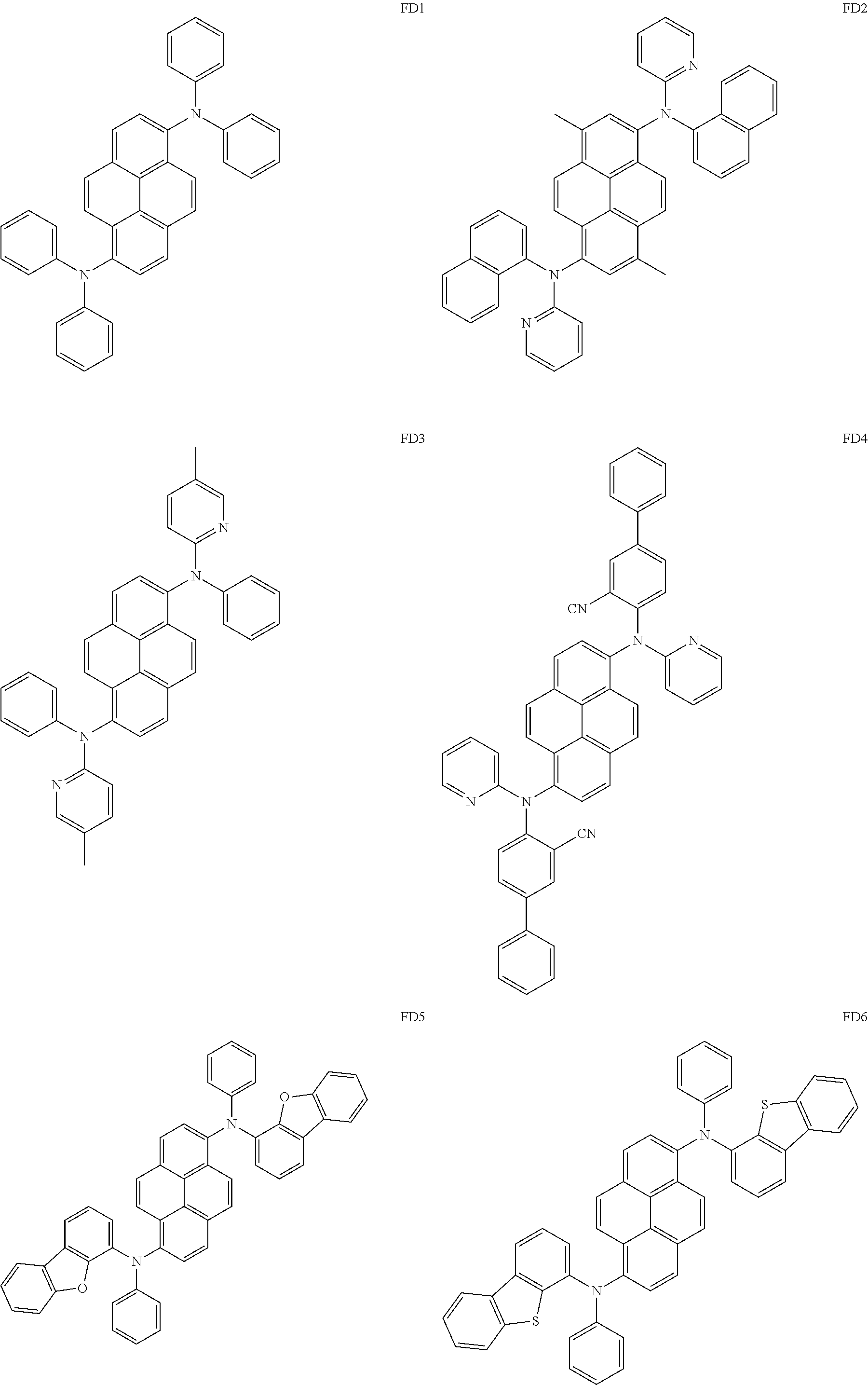

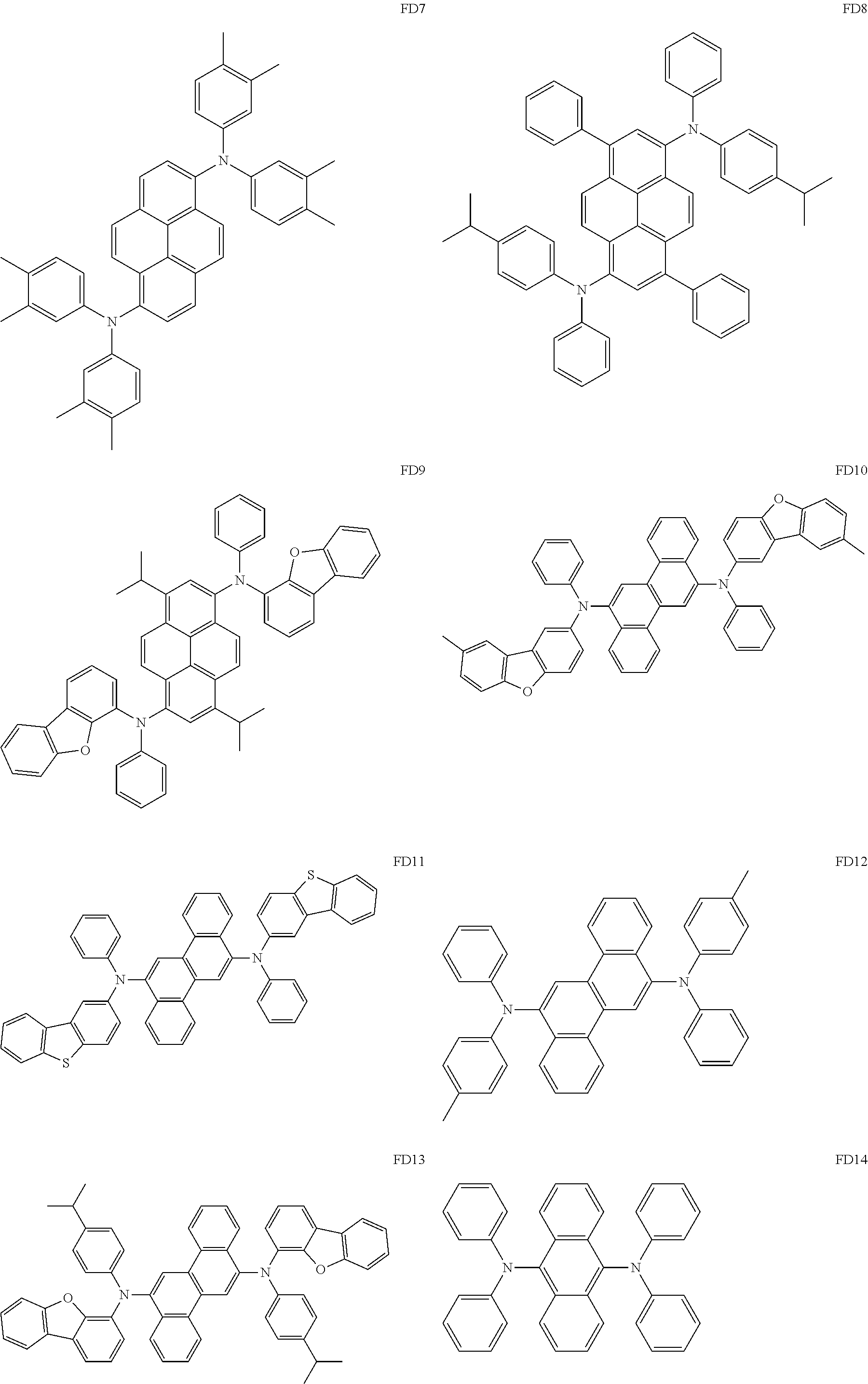

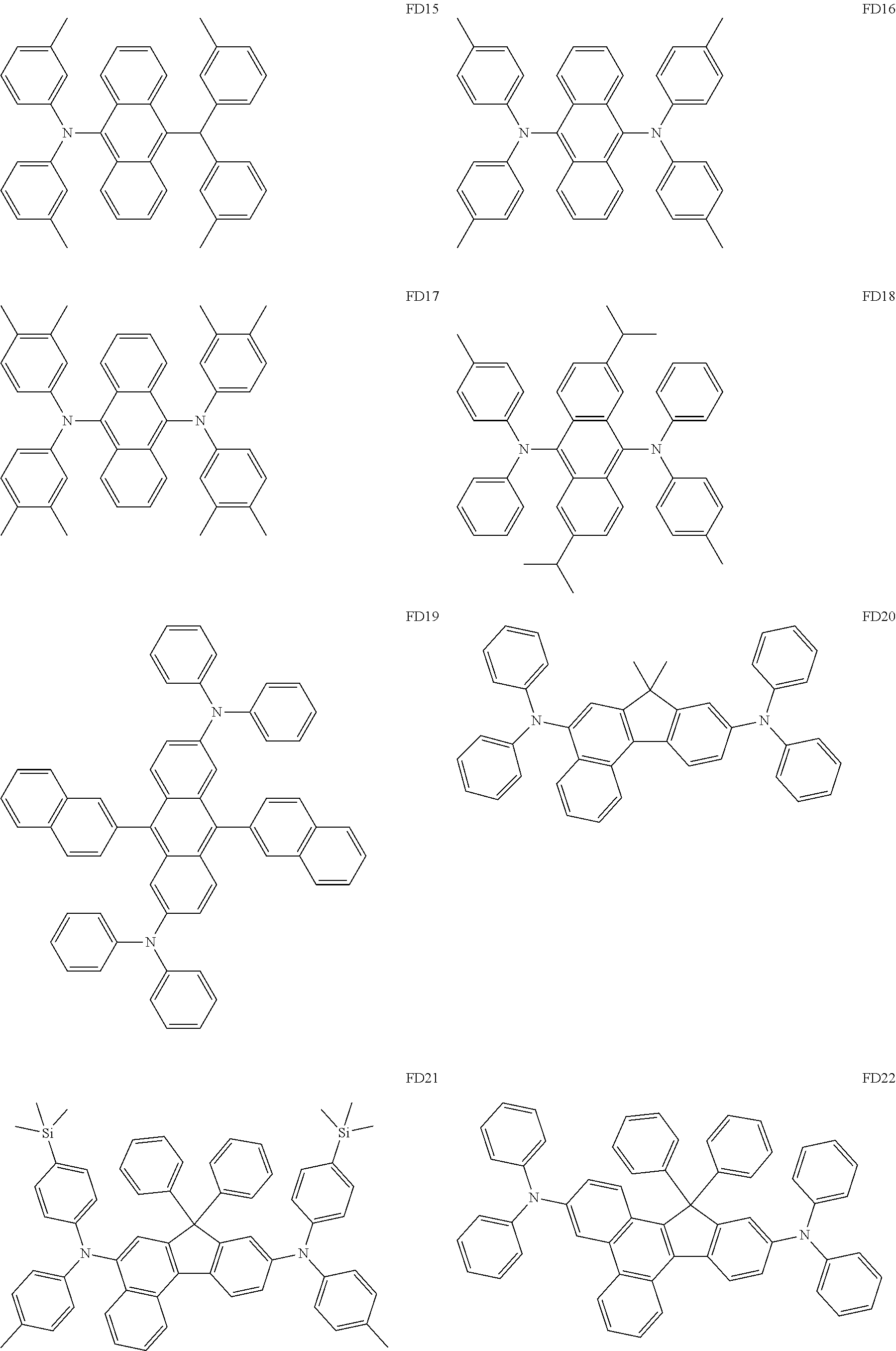

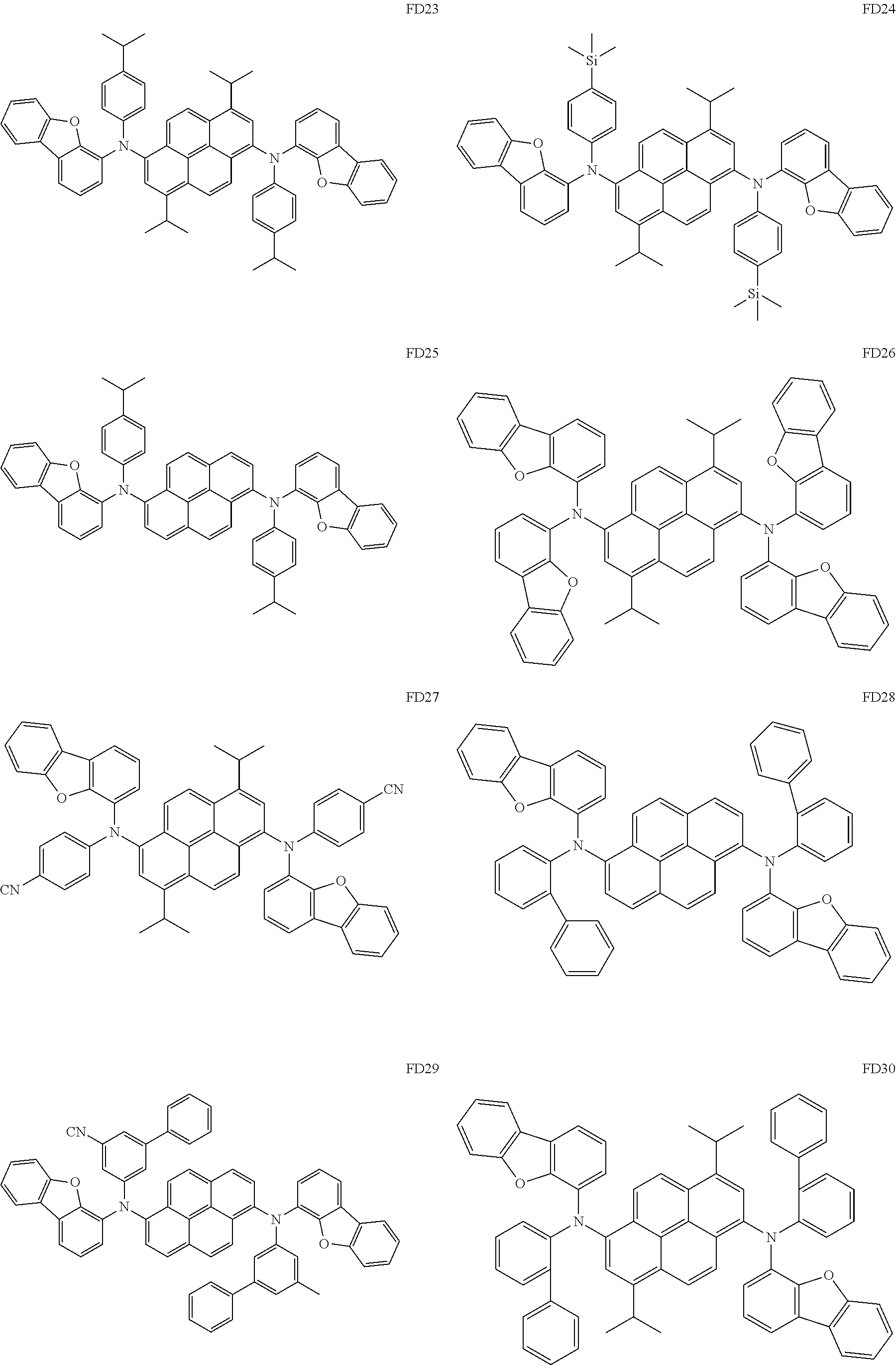

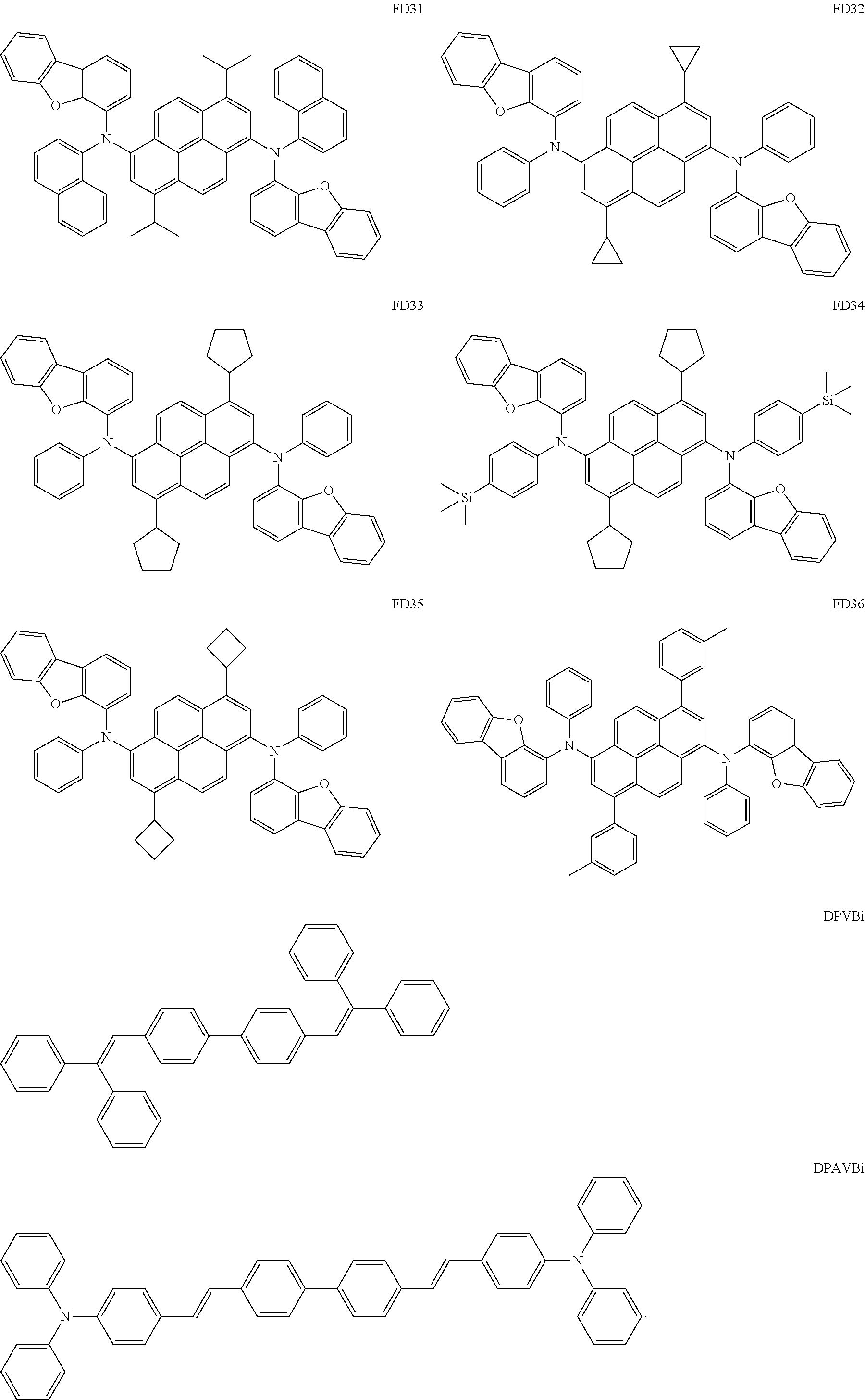

### Delayed Fluorescence Material

The emission layer may include a delayed fluorescence material.

In the present specification, the delayed fluorescence material may be selected from compounds capable of emitting delayed fluorescence based on a delayed fluorescence emission mechanism.

The delayed fluorescence material included in the emission layer may act as a host or a dopant depending on the kind (e.g., type) of other materials included in the emission layer.

In an embodiment, a difference between a triplet energy level (eV) of the delayed fluorescence material and a singlet energy level (eV) of the delayed fluorescence material may be equal to or greater than 0 eV and equal to or less than 0.5 eV. When the difference between the triplet energy level (eV) of the delayed fluorescence material and the singlet energy level (eV) of the delayed fluorescence material is within the above-described range, up-conversion from the triplet state to the singlet state of the delayed fluorescence material may effectively occur, thereby improving luminescence efficiency of the light-emitting device 30.

In an embodiment, the delayed fluorescence material may include: i) a material including at least one electron donor (for example, a π electron-rich C₃-C₆₀ cyclic group, and/or the like, such as a carbazole group) and at least one electron acceptor (for example, a sulfoxide group, a cyano group, a π electron-deficient nitrogen-containing C₁-C₆₀ cyclic group, and/or the like), ii) a material including a C₈-C₆₀ polycyclic group including at least two cyclic groups condensed to each other while sharing boron (B), and/or the like.

In one or more embodiments, the delayed fluorescence material may include at least one of Compounds DF1 to DF9:

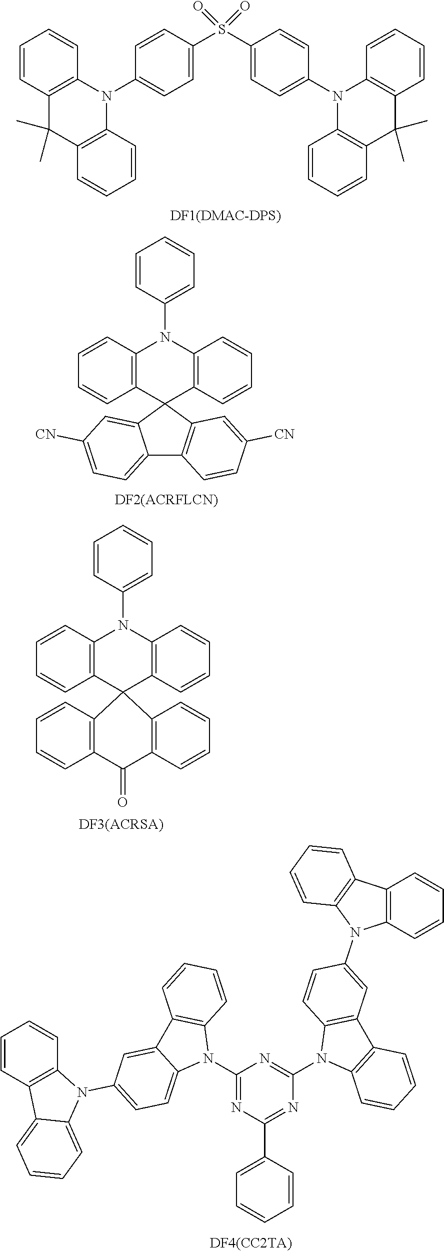

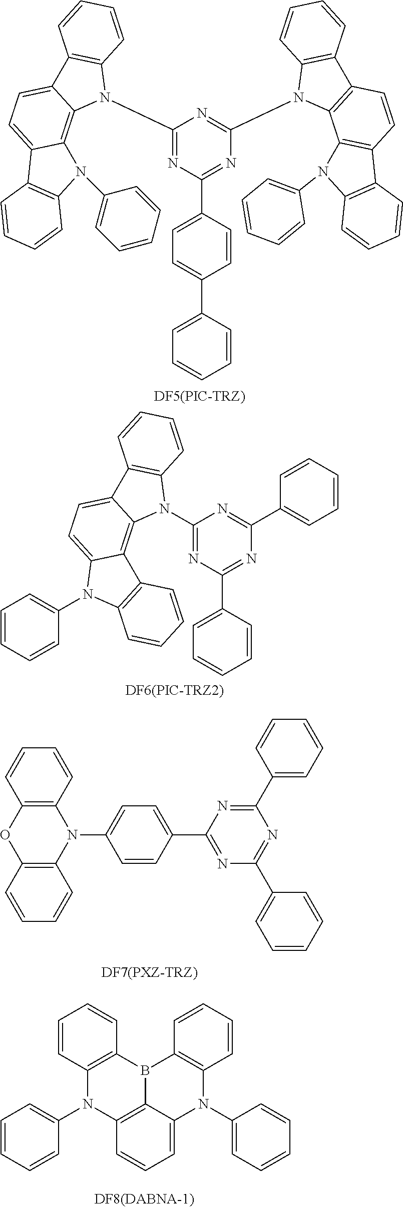 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-c3ccc(N4c5ccccc5Oc5ccccc54)cc3)n2)cc1 ; c1ccc(N2c3ccccc3B3c4ccccc4N(c4ccccc4)c4cccc2c43)cc1]

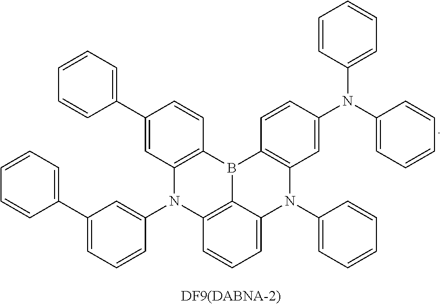 [SMILES: c1ccc(-c2cccc(N3c4cc(-c5ccccc5)ccc4B4c5ccc(N(c6ccccc6)c6ccccc6)cc5N(c5ccccc5)c5cccc3c54)c2)cc1]

### Quantum Dots

The emission layer may include quantum dots.

The term “quantum dot” as used herein refers to a crystal of a semiconductor compound, and may include any material capable of emitting light of various suitable emission wavelengths according to the size of the crystal.

A diameter of the quantum dot may be, for example, in a range of about 1 nm to about 10 nm.

The quantum dots may be synthesized by a wet chemical process, a metal organic chemical vapor deposition process, a molecular beam epitaxy process, or any process similar thereto.

The wet chemical process is a method including mixing a precursor material with an organic solvent and then growing a quantum dot particle crystal. When the crystal grows, the organic solvent naturally acts as a dispersant coordinated on the surface of the quantum dot crystal and controls the growth of the crystal so that the growth of quantum dot particles can be controlled through a low cost process which is easier to perform than vapor deposition methods, such as metal organic chemical vapor deposition (MOCVD) and/or molecular beam epitaxy (MBE).

A full width at half maximum (FWHM) of an emission wavelength spectrum of the quantum dots may be equal to or less than about 45 nm, for example, equal to or less than about 40 nm, or, equal to or less than about 30 nm, and within these ranges, color purity and/or color reproducibility may be improved. In addition, because the light emitted through the quantum dots is emitted in all directions, the wide viewing angle may be improved.

In addition, the quantum dot may be, for example, spherical, pyramidal, multi-arm, and/or cubic nanoparticles, nanotubes, nanowires, nanofibers, and/or nanoplate particles.

Because the energy band gap may be adjusted by controlling the size of the quantum dots, light having various suitable wavelength bands may be obtained from the emission layer including the quantum dots. Accordingly, by utilizing the quantum dots of different sizes, a light-emitting device that emits light of various suitable wavelengths may be implemented. In more detail, the size of the quantum dots may be selected to emit red light, green light, and/or blue light. In addition, the size of the quantum dots may be selected to emit white light by combination of light of various suitable colors.

### Electron Transport Region in Interlayer 130

The electron transport region may have i) a single-layered structure consisting of a single layer consisting of a single material, ii) a single-layered structure consisting of a single layer including (e.g., consisting of) a plurality of different materials, or iii) a multi-layered structure including a plurality of layers including different materials.

The electron transport region may include a buffer layer, a hole blocking layer, an electron control layer, an electron transport layer, an electron injection layer, or any combination thereof.

For example, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein layers of each structure are sequentially stacked from the emission layer in the respective stated order.

In an embodiment, the electron transport region (for example, the buffer layer, the hole blocking layer, the electron control layer, and/or the electron transport layer in the electron transport region) may include a metal-free compound including at least one π electron-deficient nitrogen-containing C₁-C₆₀ cyclic group.

In one or more embodiments, the electron transport region may include a compound represented by Formula 601:

[Ar₆₀₁]ₓₑ₁₁-[(L₆₀₁)ₓₑ₁-R₆₀₁]ₓₑ₂₁, Formula 601

wherein, in Formula 601,

Ar₆₀₁ and L₆₀₁ may each independently be a C₃-C₆₀ carbocyclic group unsubstituted or substituted with at least one R₁₀ₐ or a C₁-C₆ heterocyclic group unsubstituted or substituted with at least one R₁₀ₐ,

xe11 may be 1, 2, or 3,

xe1 may be 0, 1, 2, 3, 4, or 5,

R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),

Q₆₀₁ to Q₆₀₃ may respectively be the same as described in connection with Q₁,

xe21 may be 1, 2, 3, 4, or 5, and

at least one of Ar₆₀₁, L₆₀₁, and R₆₀₁ may each independently be a π electron-deficient nitrogen-containing C₁-C₆₀ cyclic group unsubstituted or substituted with at least one R₁₀ₐ.

In an embodiment, when xe11 in Formula 601 is 2 or more, two or more of Ar₆₀₁(s) may be linked to each other via a single bond.

In an embodiment, Ar₆₀₁ in Formula 601 may be a substituted or unsubstituted anthracene group.

In one or more embodiments, the electron transport region may include a compound represented by Formula 601-1:

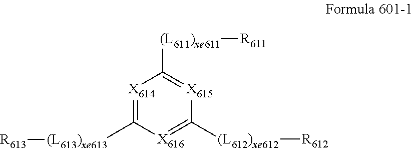

wherein, in Formula 601-1,

X₆₁₄ may be N or C(R₆₁₄), X₆₁₅ may be N or C(R₆₁₅), X₆₁₆ may be N or C(R₆₁₆), and at least one of X₆₁₄ to X₆₁₆ may be N,

L₆₁₁ to L₆₁₃ may respectively be the same as described in connection with L₆₀₁,

xe611 to xe613 may respectively be the same as described in connection with xe1,

R₆₁₁ to R₆₁₃ may respectively be the same as described in connection with R₆₀₁, and

R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

For example, xe1 and xe611 to xe613 in Formulae 601 and 601-1 may each independently be 0, 1, or 2.

In one or more embodiments, the electron transport region may include one of Compounds ET1 to ET45, 2,9-dimethyl-4,7-diphenyl-1,10-phenanthroline (BCP), 4,7-diphenyl-1,10-phenanthroline (Bphen), Alq₃, BAlq, TAZ, NTAZ, or any combination thereof:

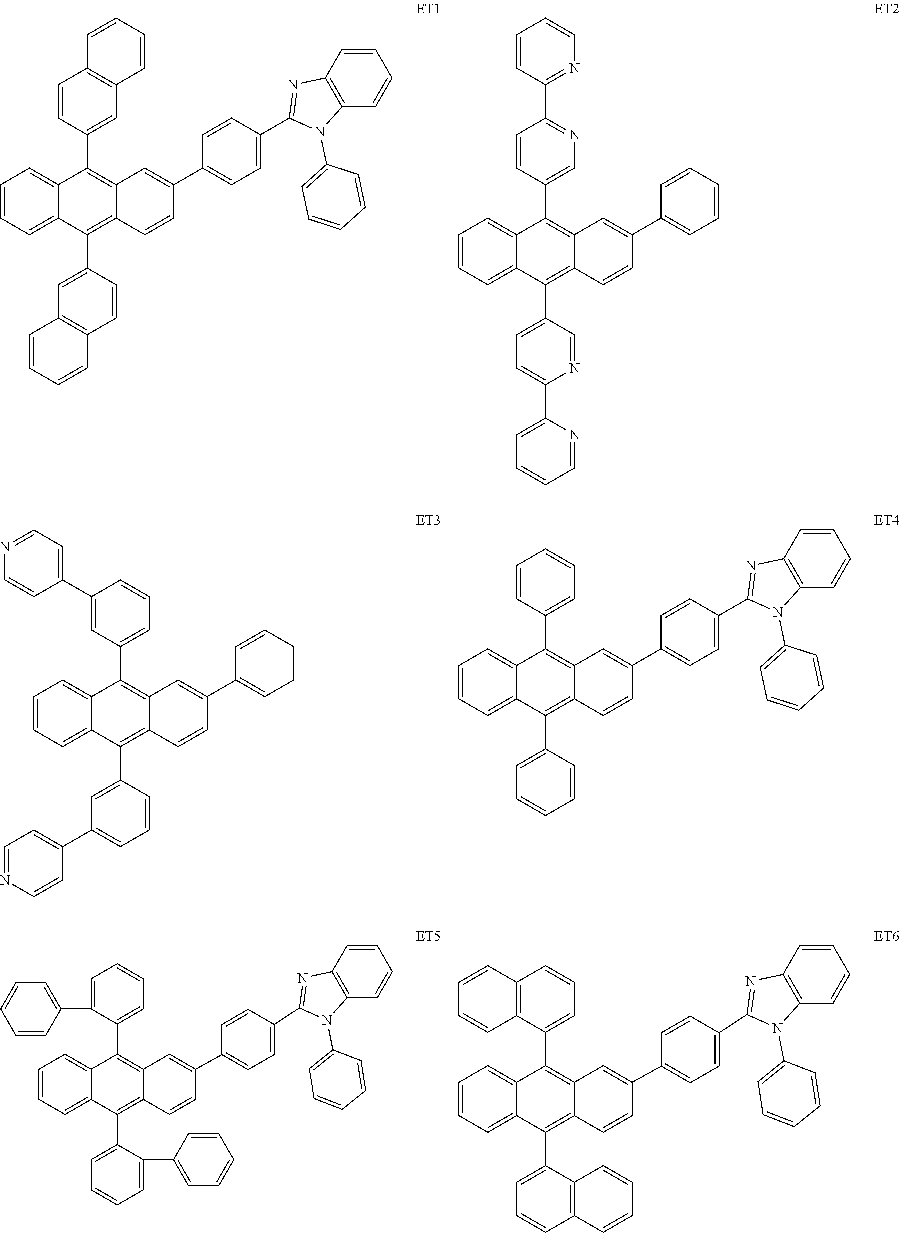

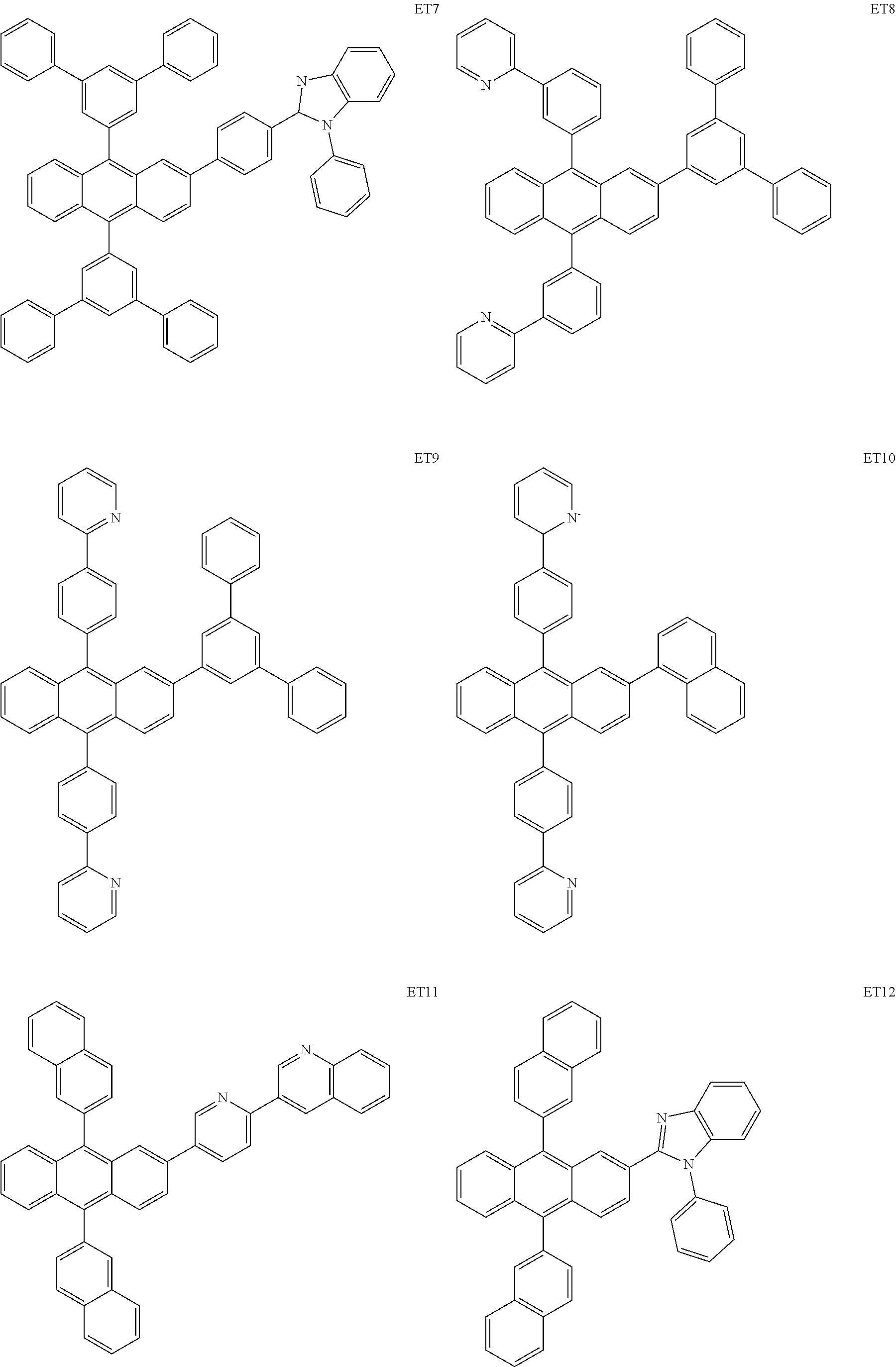

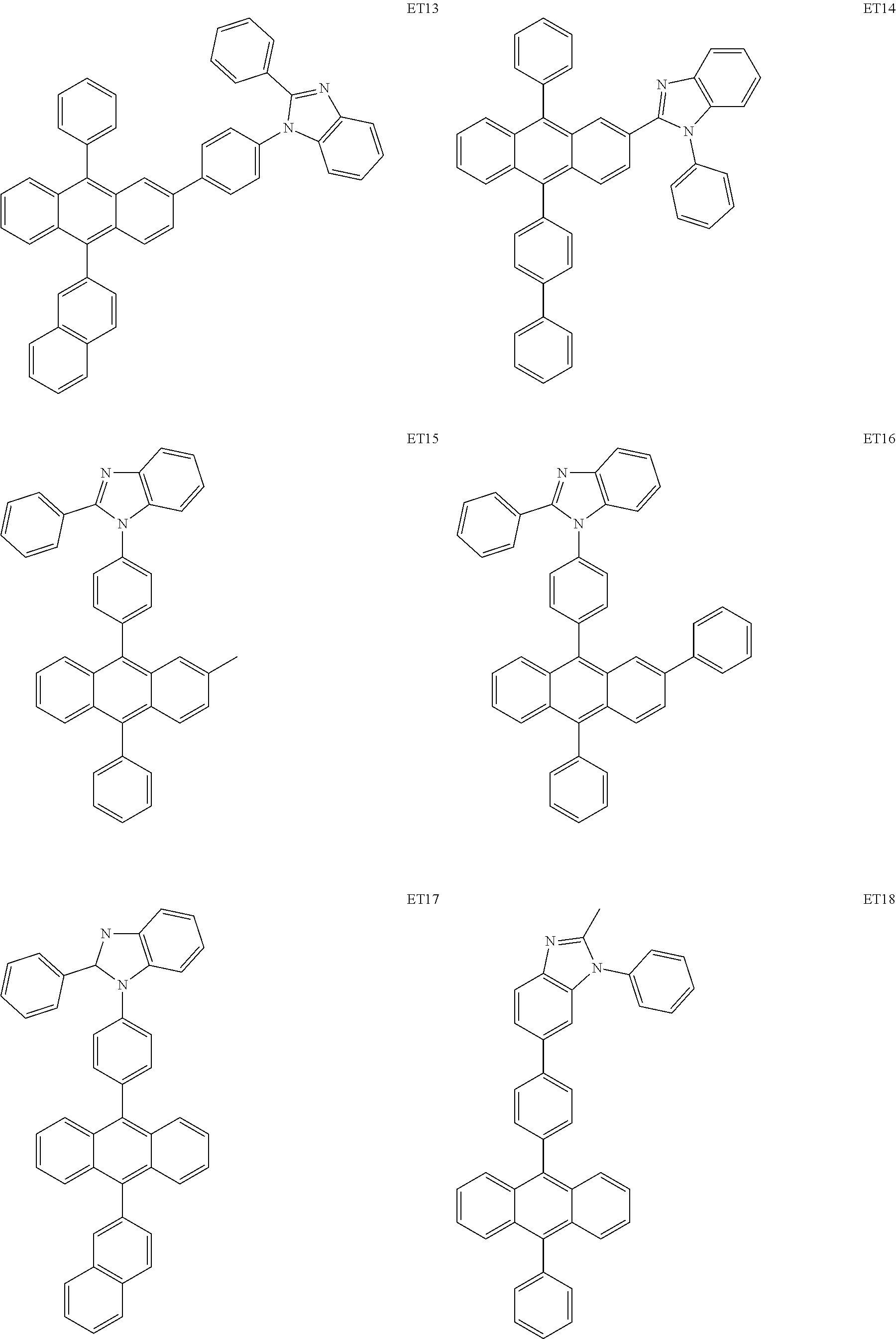

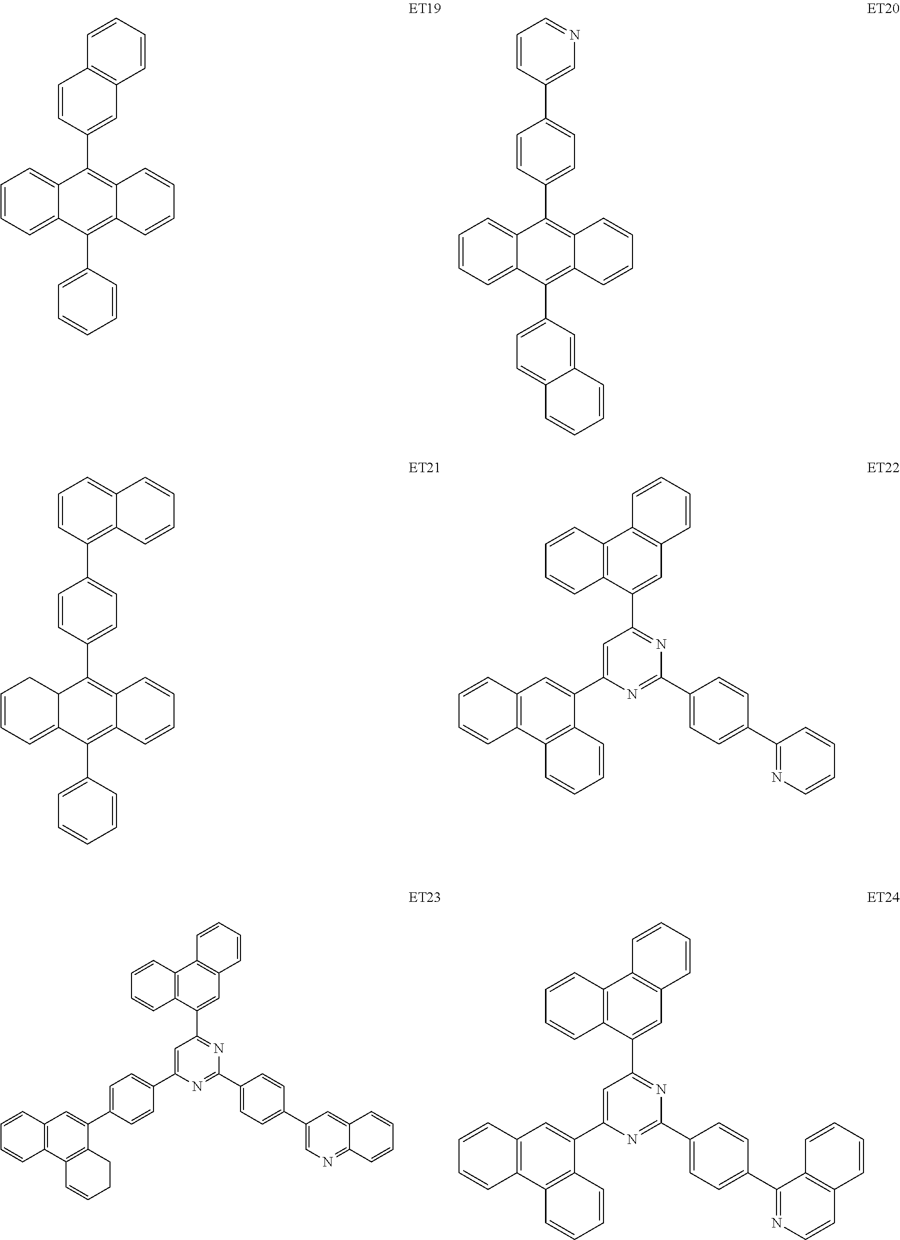

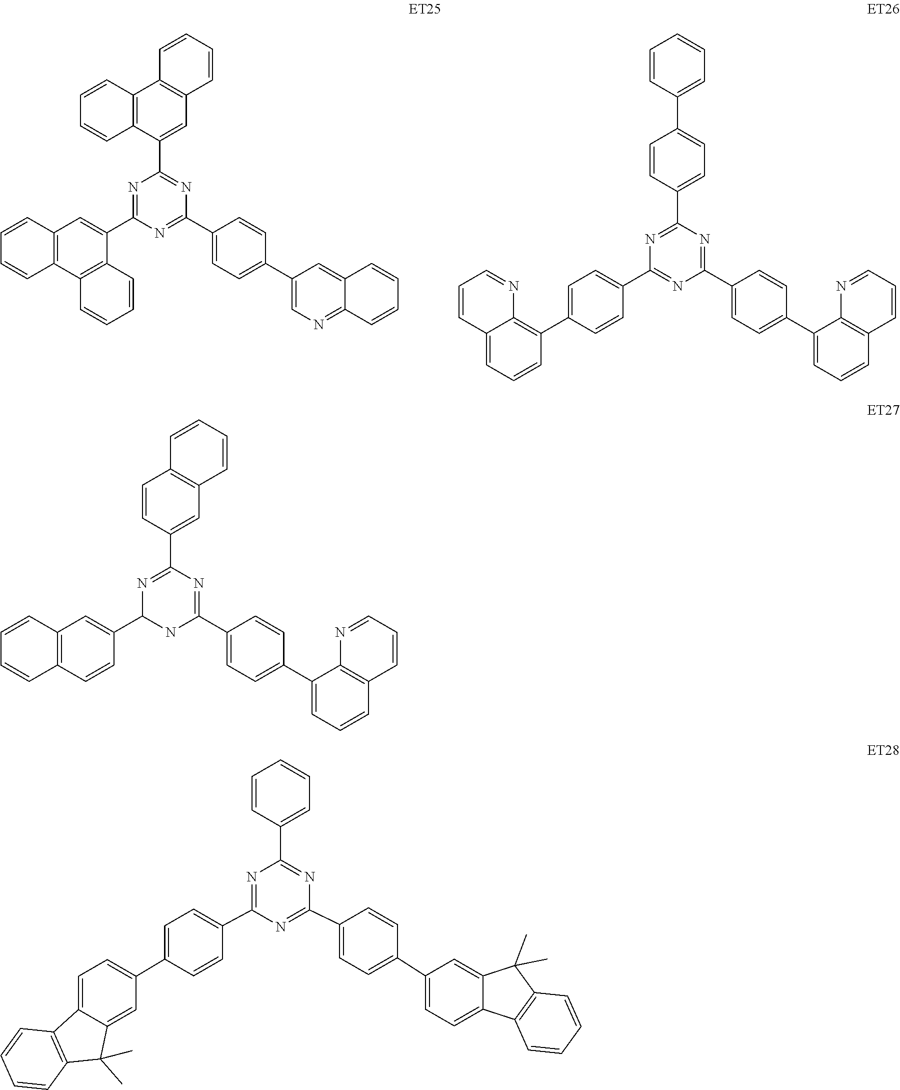

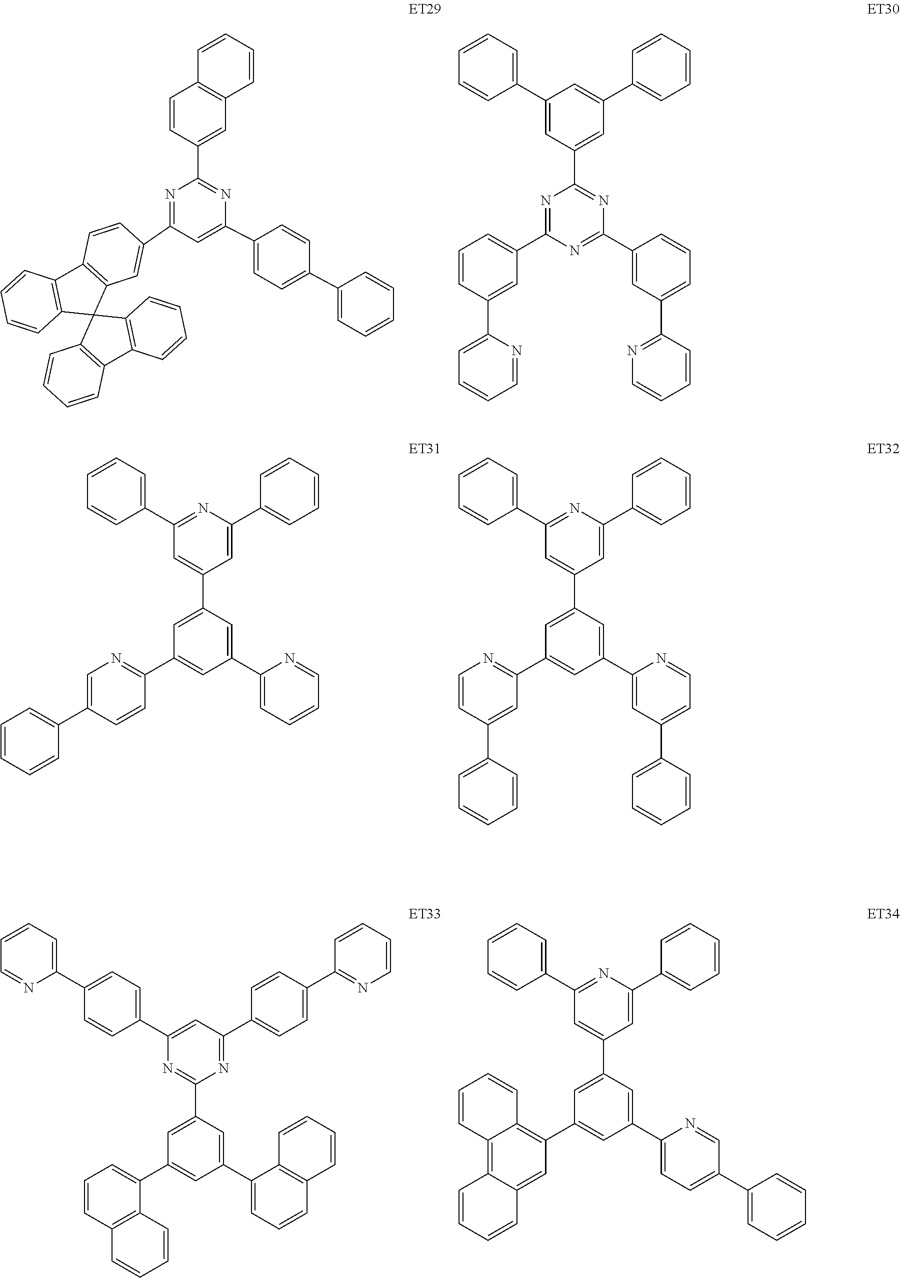

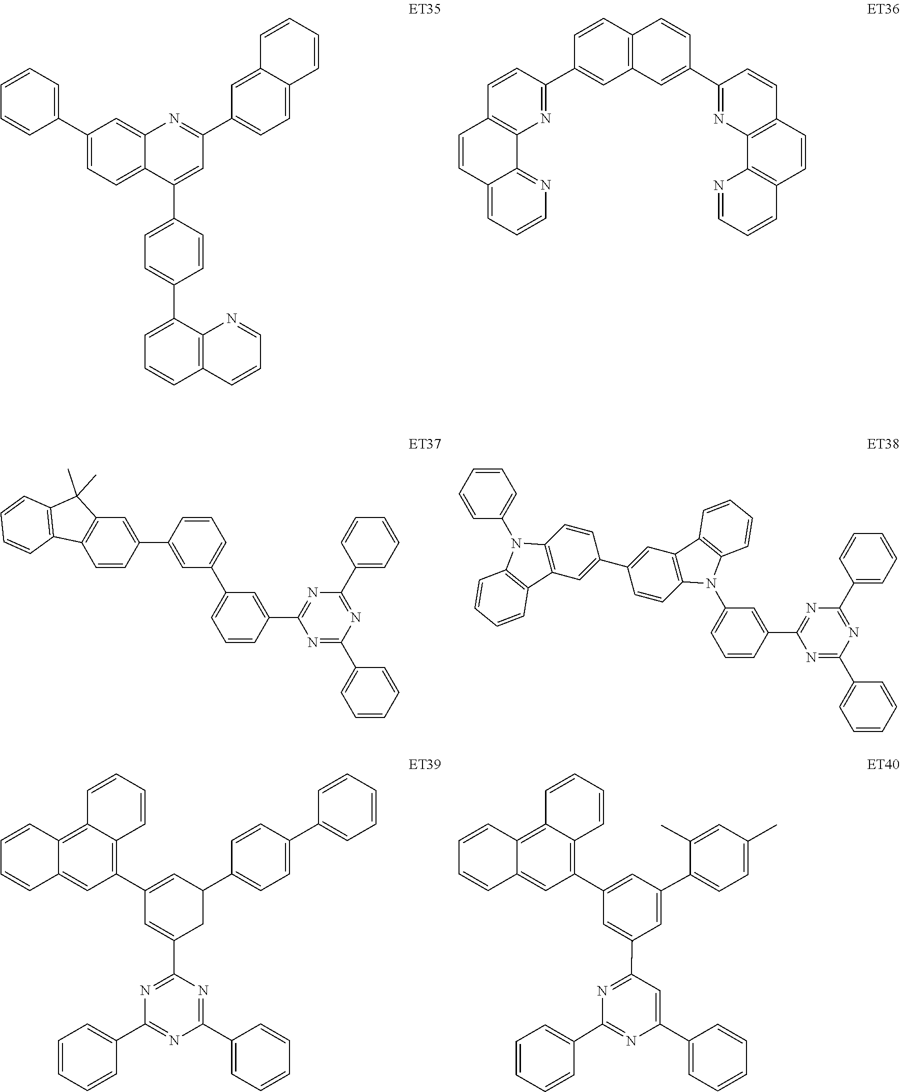 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; C1=C(c2nc(-c3ccccc3)nc(-c3ccccc3)n2)CC(c2ccc(-c3ccccc3)cc2)C=C1c1cc2ccccc2c2ccccc12 ; Cc1ccc(-c2cc(-c3cc(-c4ccccc4)nc(-c4ccccc4)n3)cc(-c3cc4ccccc4c4ccccc34)c2)c(C)c1]

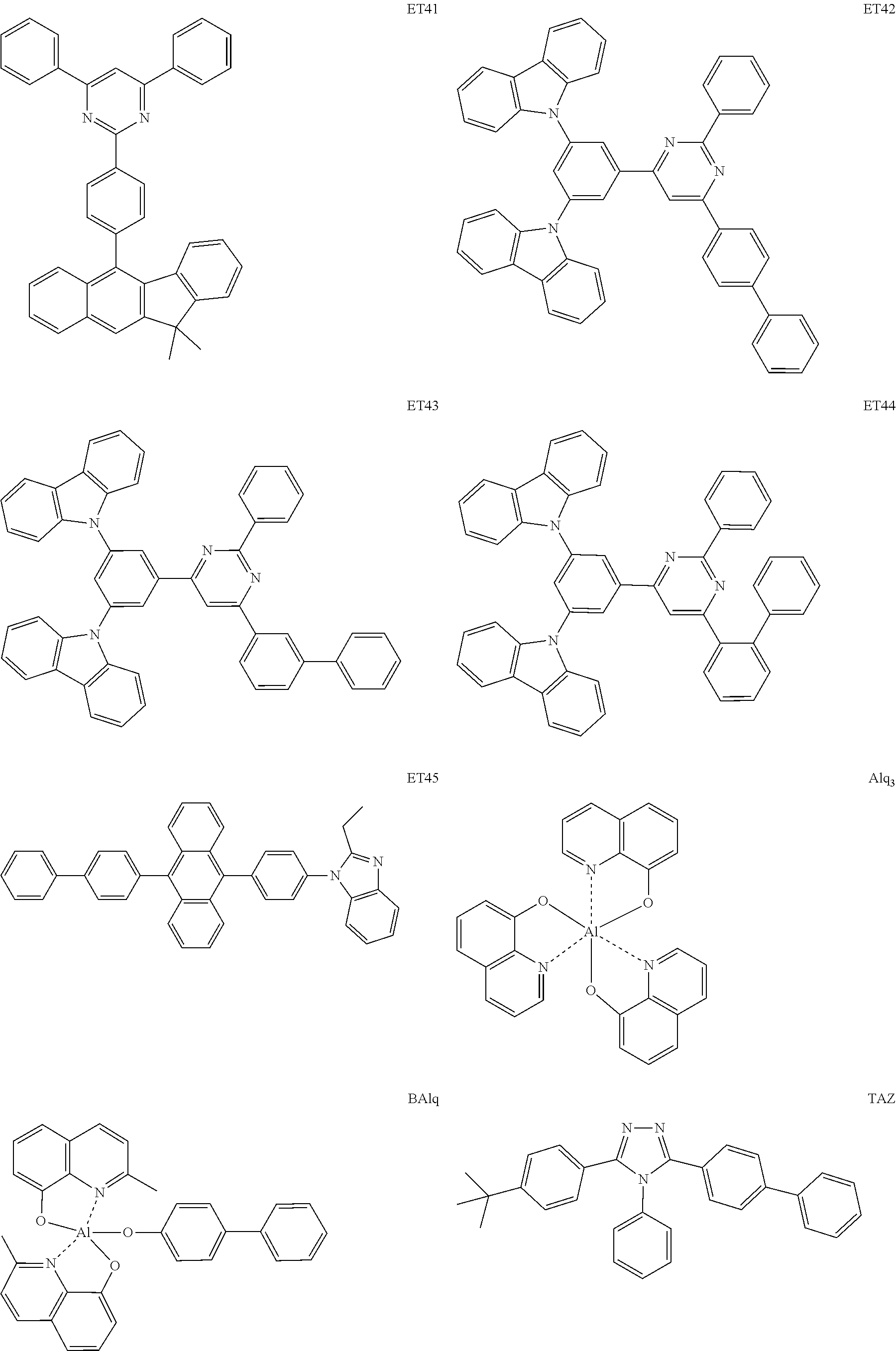

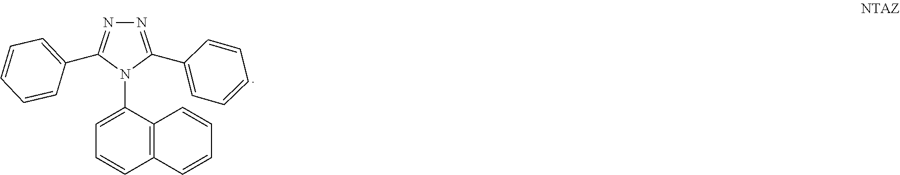 [SMILES: c1ccc(-c2nnc(-c3ccccc3)n2-c2cccc3ccccc23)cc1]

A thickness of the electron transport region may be in a range of about 100 Å to about 5,000 Å, for example, about 160 Å to about 4,000 Å. When the electron transport region includes a buffer layer, a hole blocking layer, an electron control layer, an electron transport layer, or any combination thereof, a thickness of the buffer layer, the hole blocking layer, or the electron control layer may each independently be in a range of about 20 Å to about 1,000 Å, for example, about 30 Å to about 300 Å, and a thickness of the electron transport layer may be in a range of about 100 Å to about 1,000 Å, for example, about 150 Å to about 500 Å. When the thicknesses of the buffer layer, the hole blocking layer, the electron control layer, and/or the electron transport layer are within these ranges, satisfactory electron transporting characteristics may be obtained without a substantial increase in driving voltage.

The electron transport region (for example, the electron transport layer in the electron transport region) may further include, in addition to the materials described above, a metal-containing material.

The metal-containing material may include an alkali metal complex, an alkaline earth metal complex, or any combination thereof. The metal ion of the alkali metal complex may be a Li ion, a Na ion, a K ion, a Rb ion, or a Cs ion, and the metal ion of the alkaline earth metal complex may be a Be ion, a Mg ion, a Ca ion, a Sr ion, or a Ba ion. A ligand coordinated with the metal ion of the alkali metal complex or the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

For example, the metal-containing material may include a Li complex. The Li complex may include, for example, Compound ET-D1 (LiQ) or ET-D2:

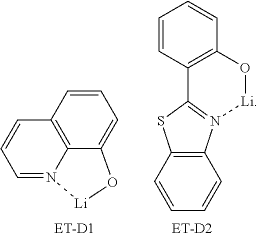

The electron transport region may include an electron injection layer that facilitates the injection of electrons from the second electrode 150. The electron injection layer may directly contact the second electrode 150.

The electron injection layer may have: i) a single-layered structure consisting of a single layer consisting of a single material, ii) a single-layered structure consisting of a single layer including (e.g., consisting of) a plurality of different materials, or iii) a multi-layered structure including a plurality of layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof.

The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may be one or more oxides, halides (for example, fluorides, chlorides, bromides, iodides, and/or the like), tellurides of the alkali metal, the alkaline earth metal, and the rare earth metal, or any combination thereof.

The alkali metal-containing compound may include one or more alkali metal oxides, such as Li₂O, Cs₂O, K₂O, and/or the like, alkali metal halides, such as LiF, NaF, CsF, KF, LiI, NaI, CsI, KI, and/or the like, or any combination thereof. The alkaline earth metal-containing compound may include an alkaline earth metal compound (e.g., oxide), such as BaO, SrO, CaO, BaxSr₁₋ₓO (wherein x is a real number satisfying the condition of 0<x<1), BaₓCa₁₋ₓO (wherein x is a real number satisfying the condition of 0<x<1), and/or the like. The rare earth metal-containing compound may include YbF₃, ScF₃, Sc₂O₃, Y₂O₃, Ce₂O₃, GdF₃, TbF₃, YbI₃, ScI₃, TbI₃, or any combination thereof.

For example, the rare earth metal-containing compound may include lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, and/or the like.

The alkali metal complex, the alkaline earth-metal complex, and the rare earth metal complex may include i) one of ions of the alkali metal, the alkaline earth metal, and the rare earth metal and ii), as a ligand bonded to the metal ion, for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof.

In an embodiment, the electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In one or more embodiments, the electron injection layer may further include an organic material (for example, the compound represented by Formula 601).

In an embodiment, the electron injection layer may include (e.g., consist of) i) an alkali metal-containing compound (for example, an alkali metal halide), or may include ii) a) an alkali metal-containing compound (for example, an alkali metal halide) and b) an alkali metal, an alkaline earth metal, a rare earth metal, or any combination thereof. In one or more embodiments, the electron injection layer may be a KI:Yb co-deposited layer, an RbI:Yb co-deposited layer, and/or the like.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or any combination thereof may be homogeneously or non-homogeneously dispersed in a matrix including (with) the organic material.

A thickness of the electron injection layer may be in a range of about 1 Å to about 100 Å, for example, about 3 Å to about 90 Å. When the thickness of the electron injection layer is within these ranges, satisfactory electron injection characteristics may be obtained without a substantial increase in driving voltage.

### Second Electrode 150

The second electrode 150 may be on the interlayer 130 having a structure as described above. The second electrode 150 may be a cathode, which is an electron injection electrode, and a material for forming the second electrode 150 may include a metal, an alloy, an electrically conductive compound, or any combination thereof, each having a low-work function.

The material for forming the second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a semi-transmissive electrode, or a reflective electrode.

The second electrode 150 may have a single-layered structure or a multi-layered structure including a plurality of layers.

### Capping Layer

A first capping layer may be arranged outside the first electrode 110, and/or a second capping layer may be arranged outside the second electrode 150. In one or more embodiments, the light-emitting device 30 may have a structure in which the first capping layer, the first electrode 110, the interlayer 130, and the second electrode 150 are sequentially stacked in the stated order, a structure in which the first electrode 110, the interlayer 130, the second electrode 150, and the second capping layer are sequentially stacked in the stated order, or a structure in which the first capping layer, the first electrode 110, the interlayer 130, the second electrode 150, and the second capping layer are sequentially stacked in the stated order.

Light generated in the emission layer of the interlayer 130 of the light-emitting device 30 may be extracted (e.g., emitted) toward the outside through the first electrode 110, which is a semi-transmissive electrode or a transmissive electrode, and the first capping layer. Light generated the emission layer of the interlayer 130 of the light-emitting device 30 may be extracted (e.g., emitted) toward the outside through the second electrode 150, which is a semi-transmissive electrode or a transmissive electrode, and the second capping layer.

The first capping layer and the second capping layer may increase external luminescence efficiency according to the principle of constructive interference. Accordingly, the light extraction efficiency of the light-emitting device 30 is increased, so that the luminescence efficiency of the light-emitting device 30 may be improved.

Each of the first capping layer and the second capping layer may include a material having a refractive index of equal to or greater than 1.6 (at 589 nm).

The first capping layer and the second capping layer may each independently be an organic capping layer including an organic material, an inorganic capping layer including an inorganic material, or an organic-inorganic composite capping layer including an organic material and an inorganic material.

In an embodiment, at least one selected from the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may each optionally be substituted with a substituent including O, N, S, Se, Si, F, Cl, Br, I, or any combination thereof. In one or more embodiments, at least one selected from the first capping layer and the second capping layer may each independently include an amine group-containing compound.

For example, at least one selected from the first capping layer and the second capping layer may each independently include a compound represented by Formula 201, a compound represented by Formula 202, or any combination thereof.

In one or more embodiments, at least one selected from the first capping layer and the second capping layer may each independently include one of Compounds HT28 to HT33, one of Compounds CP1 to CP6, β-NPB, or any combination thereof:

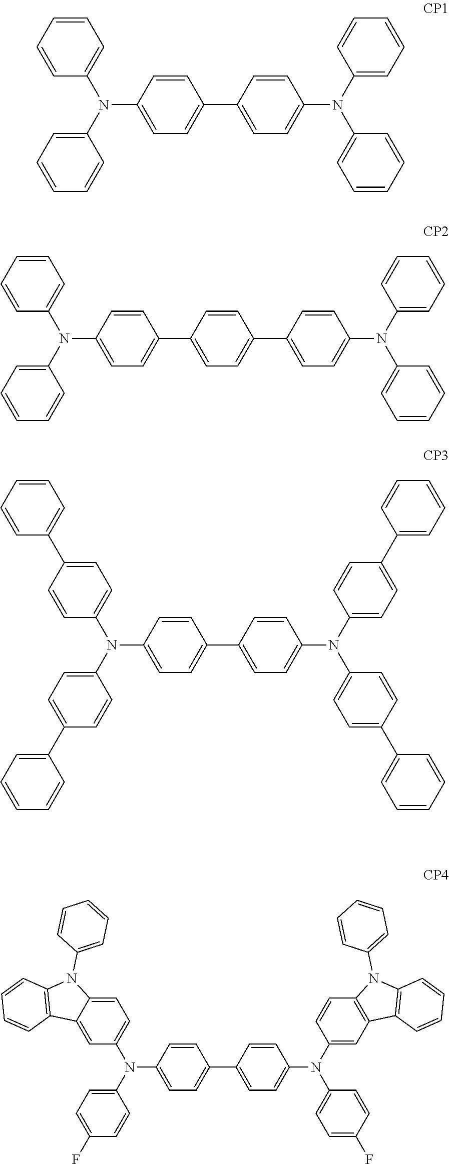 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

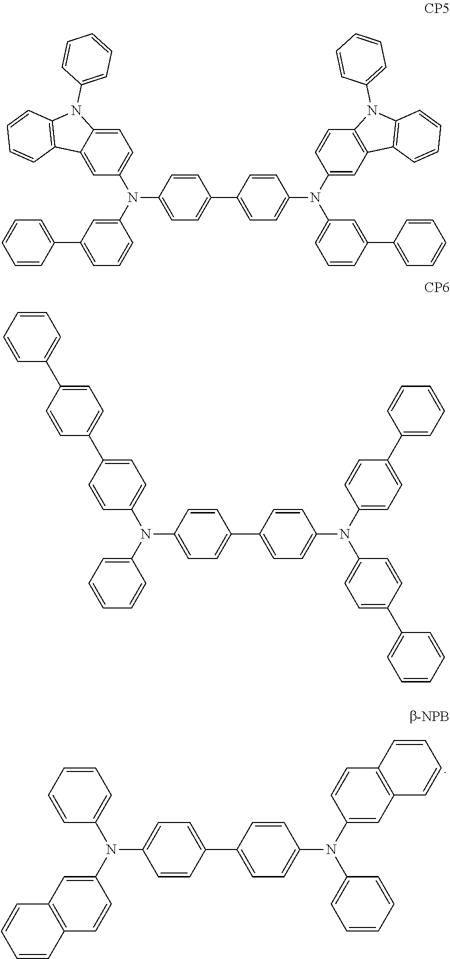 [SMILES: c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

### Film

The quantum dot 1 may be included in various suitable films. Accordingly, another aspect of the present disclosure provides a film including the quantum dot 1. The film may be, for example, an optical member (or a light control member or means) (for example, a color filter, a color conversion member, a capping layer, a light extraction efficiency enhancement layer, a selective light absorbing layer, a polarizing layer, a quantum dot-containing layer, and/or the like), a light-blocking member (for example, a light reflective layer, a light absorbing layer, and/or the like), and/or a protective member (for example, an insulating layer, a dielectric layer, and/or the like).

### Electronic Apparatus

The light-emitting device may be included in various suitable electronic apparatuses. For example, the electronic apparatus including the light-emitting device may be a light-emitting apparatus, an authentication apparatus, and/or the like.

The electronic apparatus (for example, a light-emitting apparatus) may further include, in addition to the light-emitting device, i) a color filter, ii) a color conversion layer, or iii) both a color filter and a color conversion layer. The color filter and/or the color conversion layer may be arranged in at least one traveling direction of light emitted from the light-emitting device. For example, the light emitted from the light-emitting device may be blue light or white light. For details on the light-emitting device, related description provided above may be referred to. In an embodiment, the color conversion layer may include quantum dots. The quantum dots may be, for example, the same as described herein.

The electronic apparatus may include a first substrate. The first substrate may include a plurality of subpixel areas, the color filter may include a plurality of color filter areas respectively corresponding to the subpixel areas, and the color conversion layer may include a plurality of color conversion areas respectively corresponding to the subpixel areas.

A pixel-defining film may be arranged among the subpixel areas to define each of the subpixel areas.

The color filter including the plurality of color filter areas may further include light-shielding patterns interposed between the color filter areas, and the color conversion layer including the plurality of color conversion areas may further include light-shielding patterns interposed between the color conversion areas.

The plurality of color filter areas (or the plurality of color conversion areas) may include a first area emitting a first color light, a second area emitting a second color light, and/or a third area emitting a third color light, wherein the first color light, the second color light, and/or the third color light may have different maximum emission wavelengths from one another. For example, the first color light may be red light, the second color light may be green light, and the third color light may be blue light. In one or more embodiments, the color filter areas (or the color conversion areas) may include quantum dots. For example, the first area may include red quantum dots, the second area may include green quantum dots, and the third area may not include quantum dots. Details for the quantum dots may be the same as described herein. Each of the first area, the second area, and/or the third area may further include a scatter.

In an embodiment, the light-emitting device may emit a first light, the first area may absorb the first light to emit a first first-color light, the second area may absorb the first light to emit a second first-color light, and the third area may absorb the first light to emit a third first-color light. In this regard, the first first-color light, the second first-color light, and the third first-color light may have different maximum emission wavelengths from one another. In particular, the first light may be blue light, the first first-color light may be red light, the second first-color light may be green light, and the third first-color light may be blue light.

The electronic apparatus may further include a thin-film transistor, in addition to the light-emitting device described above. The thin-film transistor may include a source electrode, a drain electrode, and an activation layer, wherein one of the source electrode or the drain electrode may be electrically connected to one of the first electrode or the second electrode of the light-emitting device.

The thin-film transistor may further include a gate electrode, a gate insulating film, and/or the like.

The activation layer may include crystalline silicon, amorphous silicon, an organic semiconductor, an oxide semiconductor, and/or the like.

The electronic apparatus may further include a sealing portion for sealing the light-emitting device. The sealing portion and/or the color conversion layer may be arranged between the color filter and the light-emitting device. The sealing portion allows light from the light-emitting device to be extracted to the outside, while concurrently or simultaneously preventing or substantially preventing ambient air and moisture from penetrating into the light-emitting device. The sealing portion may be a sealing substrate including a transparent glass substrate or a plastic substrate. The sealing portion may be a thin-film encapsulation layer including at least one layer of an organic layer and/or an inorganic layer. When the sealing portion is a thin-film encapsulating layer, the electronic apparatus may be flexible.

Various suitable functional layers may be additionally arranged on the sealing portion, in addition to the color filter and/or the color conversion layer, according to the use of the electronic apparatus. Examples of the functional layers may include (e.g., may be) a touch screen layer, a polarizing layer, and/or the like. The touch screen layer may be a pressure-sensitive touch screen layer, a capacitive touch screen layer, and/or an infrared touch screen layer. The authentication apparatus may be, for example, a biometric authentication apparatus that authenticates an individual by utilizing biometric information of a living body (for example, fingertips, pupils, and/or the like).

The authentication apparatus may further include, in addition to the light-emitting device as described above, a biometric information collector.

The electronic apparatus may be applied to various suitable displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, and/or endoscope displays), fish finders, various suitable measuring instruments, meters (for example, meters for a vehicle, an aircraft, and/or a vessel), projectors, and/or the like.

### Optical Member and Apparatus

Another aspect of the present disclosure provides an optical member including the quantum dot 1.

The optical member may be a color conversion member.

The color conversion member may include a substrate and a pattern layer formed on the substrate.

The substrate may be a substrate (e.g., an independent substrate) constituting the color conversion member, or may be a region of various suitable apparatuses (for example, a display apparatus) in which the color conversion member is located (e.g., is formed on). The substrate may be glass, silicon (Si), silicon oxide (SiOx), or a polymer substrate, and the polymer substrate may be polyethersulfone (PES) or polycarbonate (PC).

The pattern layer may include quantum dots in the form of a thin film. For example, the pattern layer may be a thin film including (e.g., consisting of) the quantum dots.

The color conversion member including the substrate and the pattern layer may further include a partition wall or a black matrix, each formed between the pattern layers. Meanwhile, the color conversion member may further include a color filter to further improve light conversion efficiency.

The color conversion member may include a red pattern layer capable of emitting red light, a green pattern layer capable of emitting green light, a blue pattern layer capable of emitting blue light, or any combination thereof. The red pattern layer, the green pattern layer, and/or the blue pattern layer may be implemented by controlling the components, compositions, and/or structure of the quantum dots.

Another aspect of the present disclosure provides an apparatus including the quantum dot (or the optical member including the quantum dot).

The apparatus may further include a light source, and the quantum dot (or the optical member including the quantum dot) may be arranged on a path of light emitted from the light source.

The light source may emit blue light, red light, green light, or white light. For example, the light source may emit blue light.

The light source may be an organic light-emitting device (OLED) or a light-emitting diode (LED).

The light emitted from the light source as described above may be photoconverted by the quantum dots while passing through the quantum dots.

Accordingly, due to the quantum dots, light having a wavelength that is different from that of the light emitted from the light source may be emitted.

The apparatus may be a display apparatus, a lighting apparatus, and/or the like.

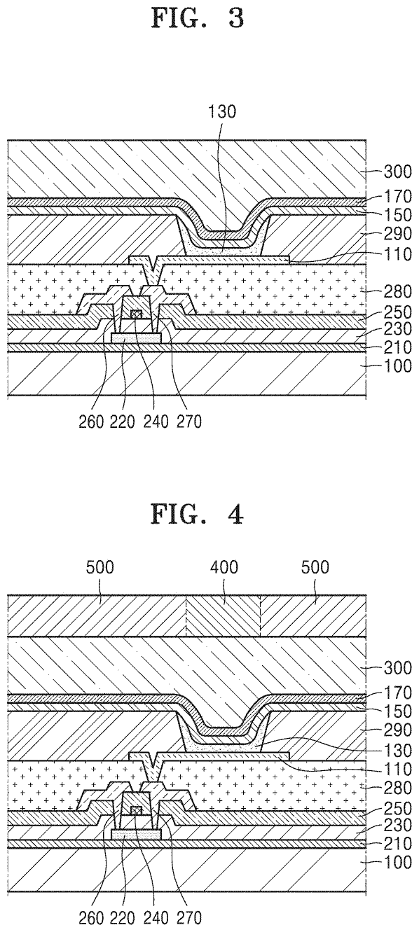

### Description of FIGS. 3 and 4

FIG. 3 is a cross-sectional view showing a light-emitting apparatus according to an embodiment of the present disclosure.

The light-emitting apparatus of FIG. 3 includes a substrate 100, a thin-film transistor (TFT), a light-emitting device, and an encapsulation portion 300 that seals the light-emitting device.

The substrate 100 may be a flexible substrate, a glass substrate, or a metal substrate. A buffer layer 210 may be arranged on the substrate 100. The buffer layer 210 may prevent or substantially prevent penetration of impurities through the substrate 100 and may provide a flat surface on the substrate 100.

The TFT may be arranged on the buffer layer 210. The TFT may include an activation layer 220, a gate electrode 240, a source electrode 260, and a drain electrode 270.

The activation layer 220 may include an inorganic semiconductor, such as silicon or polysilicon, an organic semiconductor, and/or an oxide semiconductor, and may include a source region, a drain region, and a channel region.

A gate insulating film 230 for insulating the activation layer 220 from the gate electrode 240 may be arranged on the activation layer 220, and the gate electrode 240 may be arranged on the gate insulating film 230.

An interlayer insulating film 250 may be arranged on the gate electrode 240. The interlayer insulating film 250 may be arranged between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be arranged on the interlayer insulating film 250. The interlayer insulating film 250 and the gate insulating film 230 may be formed to expose the source region and the drain region of the activation layer 220, and the source electrode 260 and the drain electrode 270 may be arranged in contact with the exposed portions of the source region and the drain region of the activation layer 220.

The TFT may be electrically connected to the light-emitting device to drive the light-emitting device, and may be covered by a passivation layer 280. The passivation layer 280 may include an inorganic insulating film, an organic insulating film, or any combination thereof. The light-emitting device may be provided on the passivation layer 280. The light-emitting device may include the first electrode 110, the interlayer 130, and the second electrode 150.

The first electrode 110 may be arranged on the passivation layer 280. The passivation layer 280 may expose a portion of the drain electrode 270 without completely covering the drain electrode 270, and the first electrode 110 may be arranged to be connected to the exposed portion of the drain electrode 270.

A pixel defining layer 290 including an insulating material may be arranged on the first electrode 110. The pixel defining layer 290 may expose a region of the first electrode 110, and the interlayer 130 may be formed in the exposed region of the first electrode 110. The pixel defining layer 290 may be a polyimide organic film and/or a polyacrylic organic film. In one or more embodiments, at least some layers of the interlayer 130 may extend beyond the upper portion of the pixel defining layer 290 and may thus be located in the form of a common layer.

The second electrode 150 may be arranged on the interlayer 130, and a capping layer 170 may be additionally formed on the second electrode 150. The capping layer 170 may be formed to cover the second electrode 150.

The encapsulation portion 300 may be arranged on the capping layer 170. The encapsulation portion 300 may be arranged on the light-emitting device to protect the light-emitting device from moisture and/or oxygen. The encapsulation portion 300 may include: an inorganic film including silicon nitride (SiNx), silicon oxide (SiOx), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (for example, polymethyl methacrylate, polyacrylic acid, and/or the like), an epoxy-based resin (for example, aliphatic glycidyl ether (AGE) and/or the like), or any combination thereof; or any combination of the inorganic film and the organic film.

FIG. 4 is a cross-sectional view showing a light-emitting apparatus according to another embodiment of the present disclosure.

The light-emitting apparatus of FIG. 4 is the same as the light-emitting apparatus of FIG. 3, except that a light-shielding pattern 500 and a functional region 400 are additionally arranged on the encapsulation portion 300. The functional region 400 may include i) a color filter area, ii) a color conversion area, or iii) a combination of a color filter area and a color conversion area. In an embodiment, a light-emitting device included in the light-emitting apparatus of FIG. 4 may be a tandem light-emitting device.

### Manufacturing Method

Respective layers included in the hole transport region, the emission layer, and respective layers included in the electron transport region may be formed in a certain region by utilizing one or more suitable methods selected from vacuum deposition, spin coating, casting, Langmuir-Blodgett (LB) deposition, ink-jet printing, laser-printing, laser-induced thermal imaging, and/or the like.

When respective layers included in the hole transport region, the emission layer, and respective layers included in the electron transport region are formed by vacuum deposition, the deposition conditions may include a deposition temperature in a range of about 100° C. to about 500° C., a vacuum degree of about 10⁻⁸ torr to about 10⁻³ torr, and a deposition speed in a range of about 0.01 Å/sec to about 100 Å/sec, depending on a material to be included in a layer to be formed and the structure of a layer to be formed.

### DEFINITION OF TERMS

The term “C₃-C₆₀ carbocyclic group” as used herein refers to a cyclic group consisting of only three to sixty carbon atoms as ring-forming atoms, and the term “C₁-C₆₀ heterocyclic group” as used herein refers to a cyclic group that has, in addition to one to sixty carbon atoms, at least one heteroatom as a ring-forming atom. The C₃-C₆₀ carbocyclic group and the C₁-C₆₀ heterocyclic group may each independently be a monocyclic group including (e.g., consisting of) one ring or a polycyclic group in which two or more rings are condensed together. For example, the C₁-C₆₀ heterocyclic group may have 3 to 61 ring-forming atoms.

The term “cyclic group” as used herein may include both the C₃-C₆₀ carbocyclic group and the C₁-C₆₀ heterocyclic group.

The term “π electron-rich C₃-C₆₀ cyclic group” as used herein refers to a cyclic group that has 3 to 60 carbon atoms and does not include *—N═*′ as a ring-forming moiety, and the term “π electron-deficient nitrogen-containing C₁-C₆₀ cyclic group” as used herein refers to a heterocyclic group that has 1 to 60 carbon atoms and includes *—N═*′ as a ring-forming moiety.

For example,

the C₃-C₆₀ carbocyclic group may be i) a T1 group or ii) a condensed cyclic group in which at least two T1 groups are condensed with each other (for example, the C₃-C₆₀ carbocyclic group may be a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, and/or an indenoanthracene group),

the C₁-C₆₀ heterocyclic group may be i) a T2 group, ii) a condensed cyclic group in which at least two T2 groups are condensed with each other, or iii) a condensed cyclic group in which at least one T2 group and at least one T1 group are condensed with each other (for example, the C₁-C₆₀ heterocyclic group may be a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),

the π electron-rich C₃-C₆₀ cyclic group may be i) a T1 group, ii) a condensed cyclic group in which at least two T1 groups are condensed with each other, iii) a T3 group, iv) a condensed cyclic group in which at least two T3 groups are condensed with each other, or v) a condensed cyclic group in which at least one T3 group and at least one T1 group are condensed with each other (for example, the π electron-rich C₃-C₆₀ cyclic group may be the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, and/or the like),

the π electron-deficient nitrogen-containing C₁-C₆₀ cyclic group may be i) a T4 group, ii) a condensed cyclic group in which at least two T4 groups are condensed with each other, iii) a condensed cyclic group in which at least one T4 group and at least one T1 group are condensed with each other, iv) a condensed cyclic group in which at least one T4 group and at least one T3 group are condensed with each other, or v) a condensed cyclic group in which at least one T4 group, at least one T1 group, and at least one T3 group are condensed with one another (for example, the π electron-deficient nitrogen-containing C₁-C₆₀ cyclic group may be a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),

the T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or a bicyclo[2.2.1]heptane) group, a norbornene group, a bicyclo[1.1.1]pentane group, a bicyclo[2.1.1]hexane group, a bicyclo[2.2.2]octane group, or a benzene group,

the T2 group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,

the T3 group may be a furan group, a thiophene group, a 1H-pyrrole group, a silole group, or a borole group, and

the T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “the cyclic group,” “the C₃-C₆₀ carbocyclic group,” “the C₁-C₆₀ heterocyclic group,” “the π electron-rich C₃-C₆₀ cyclic group,” and/or “the π electron-deficient nitrogen-containing C₁-C₆₀ cyclic group” as used herein refer to a group condensed with any cyclic group, a monovalent group, or a polyvalent group (for example, a divalent group, a trivalent group, a tetravalent group, and/or the like), depending on the structure of a formula for which the corresponding term is used. For example, the “benzene group” may be a benzo group, a phenyl group, a phenylene group, and/or the like, which may be easily understood by one of ordinary skill in the art according to the structure of a formula including the “benzene group”.

Examples of the monovalent C₃-C₆₀ carbocyclic group and the monovalent C₁-C₆ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group. Examples of the divalent C₃-C₆₀ carbocyclic group and the divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein refers to a linear or branched aliphatic hydrocarbon monovalent group that has one to sixty carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an iso-nonyl group, a sec-nonyl group, a tert-nonyl group, an n-decyl group, an isodecyl group, a sec-decyl group, a tert-decyl group, and/or the like. The term “C₁-C₆₀ alkylene group” as used herein refers to a divalent group having the same structure as the C₁-C₆₀ alkyl group.

The term “C₂-C₆₀ alkenyl group” as used herein refers to a monovalent hydrocarbon group having at least one carbon-carbon double bond at a main chain (e.g., in the middle) or at a terminal end (e.g., the terminus) of the C₂-C₆₀ alkyl group, and examples thereof may include an ethenyl group, a propenyl group, a butenyl group, and/or the like. The term “C₂-C₆₀ alkenylene group” as used herein refers to a divalent group having the same structure as the C₂-C₆₀ alkenyl group.

The term “C₂-C₆₀ alkynyl group” as used herein refers to a monovalent hydrocarbon group having at least one carbon-carbon triple bond at a main chain (e.g., in the middle) or at a terminal end (e.g., the terminus) of the C₂-C₆₀ alkyl group, and examples thereof may include an ethynyl group, a propynyl group, and/or the like. The term “C₂-C₆₀ alkynylene group” as used herein refers to a divalent group having the same structure as the C₂-C₆₀ alkynyl group.

The term “C₁-C₆₀ alkoxy group” as used herein refers to a monovalent group represented by —OA₁₀₁ (wherein A₁₀₁ is the C₁-C₆₀ alkyl group), and examples thereof may include a methoxy group, an ethoxy group, an isopropyloxy group, and/or the like.

The term “C₃-C₁₀ cycloalkyl group” as used herein refers to a monovalent saturated hydrocarbon cyclic group having three to ten carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, a bicyclo[2.2.2]octyl group, and/or the like. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent cyclic group that further includes, in addition to 1 to 10 carbon atoms, at least one heteroatom as a ring-forming atom, and examples thereof may include a 1,2,3,4-oxatriazolidinyl group, a tetrahydrofuranyl group, a tetrahydrothiophenyl group, and/or the like. The term “C₁-C₁₀ heterocycloalkylene group” as used herein refers to a divalent group having the same structure as the C₁-C₁₀ heterocycloalkyl group.

The term “C₃-C₁₀ cycloalkenyl group” as used herein refers to a monovalent cyclic group that has 3 to 10 carbon atoms, at least one carbon-carbon double bond in the ring thereof, and no aromaticity, and examples thereof may include a cyclopentenyl group, a cyclohexenyl group, a cycloheptenyl group, and/or the like. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent cyclic group that has, in addition to 1 to 10 carbon atoms, at least one heteroatom as a ring-forming atom, and at least one double bond (e.g., carbon-carbon double bond) in the cyclic structure thereof. Examples of the C₁-C₁₀ heterocycloalkenyl group may include a 4,5-dihydro-1,2,3,4-oxatriazolyl group, a 2,3-dihydrofuranyl group, a 2,3-dihydrothiophenyl group, and/or the like. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Examples of the C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and/or the like. When the C₆-C₆₀ aryl group and the C₆-C₆₀ arylene group each include two or more rings, the rings may be condensed with each other.

The term “C₁-C₆₀ heteroaryl group” as used herein refers to a monovalent group having a heterocyclic aromatic system that has, in addition to 1 to 60 carbon atoms, at least one heteroatom as a ring-forming atom. The term “C₁-C₆₀ heteroarylene group” as used herein refers to a divalent group having a heterocyclic aromatic system that has, in addition to 1 to 60 carbon atoms, at least one heteroatom as a ring-forming atom. Examples of the C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and/or the like. When the C₁-C₆₀ heteroaryl group and the C₁-C₆₀ heteroarylene group each include two or more rings, the rings may be condensed with each other.

The term “monovalent non-aromatic condensed polycyclic group” as used herein refers to a monovalent group having two or more rings condensed to each other, only carbon atoms (for example, having 8 to 60 carbon atoms) as ring-forming atoms, and no aromaticity in its entire molecular structure. Examples of the monovalent non-aromatic condensed polycyclic group may include an indenyl group, a fluorenyl group, a spiro-bifluorenyl group, a benzofluorenyl group, an indenophenanthrenyl group, and an indeno anthracenyl group. The term “divalent non-aromatic condensed polycyclic group” as used herein refers to a divalent group having the same structure as the monovalent non-aromatic condensed polycyclic group described above.

The term “monovalent non-aromatic condensed heteropolycyclic group” as used herein refers to a monovalent group having two or more rings condensed with each other, at least one heteroatom other than carbon atoms (for example, having 1 to 60 carbon atoms), as a ring-forming atom, and no aromaticity in its entire molecular structure. Examples of the monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indeno carbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, a benzothienodibenzothiophenyl group, and/or the like. The term “divalent non-aromatic condensed heteropolycyclic group” as used herein refers to a divalent group having the same structure as the monovalent non-aromatic condensed heteropolycyclic group described above.

The term “C₆-C₆₀ aryloxy group” as used herein refers to a monovalent group represented by —OA₁₀₂ (wherein A₁₀₂ is the C₆-C₆₀ aryl group), and the term “C₆-C₆₀ arylthio group” as used herein refers to a monovalent group represented by -SA₁₀₃ (wherein A₁₀₃ is the C₆-C₆₀ aryl group).

The term “C₇-C₆₀ arylalkyl group” as used herein refers to a monovalent group represented by -A₁₀₄A₁₀₅ (wherein A₁₀₄ is a C₁-C₅₄ alkylene group and A₁₀₅ is a C₆-C₅₉ aryl group), and the term “C₂-C₆₀ heteroarylalkyl group” as used herein refers to a monovalent group represented by -A₁₀₆A₁₀₇ (wherein A₁₀₆ is a C₁-C₅₉ alkylene group and A₁₀₇ is a C₁-C₅₉ heteroaryl group).

The term “R₁₀ₐ” as used herein may be:

deuterium, —F, —Cl, —Br, —I, a hydroxyl group, a cyano group, or a nitro group,

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof,

a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the present specification, Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ aryl alkyl group, or a C₂-C₆₀ heteroaryl alkyl group, each unsubstituted or substituted with deuterium, —F, a cyano group, a C₁-C₆₀ alkyl group, a C₁-C₆ alkoxy group, a phenyl group, a biphenyl group, or any combination thereof.

The term “heteroatom” as used herein refers to any atom other than a carbon atom. Examples of the heteroatom may include O, S, N, P, Si, B, Ge, Se, or any combination thereof.

The term “third-row transition metal” as used herein refers to hafnium (Hf), tantalum (Ta), tungsten (W), rhenium (Re), osmium (Os), iridium (Ir), platinum (Pt), gold (Au), and/or the like.

“Ph” as used herein refers to a phenyl group, “Me” as used herein refers to a methyl group, “Et” as used herein refers to an ethyl group, “ter-Bu” or “Bu^{t}” as used herein refers to a tert-butyl group, and “OMe” as used herein refers to a methoxy group.

The term “biphenyl group” as used herein refers to “a phenyl group substituted with a phenyl group”. In other words, the “biphenyl group” belongs to “a substituted phenyl group having a C₆-C₆₀ aryl group as a substituent”.

The term “terphenyl group” as used herein refers to “a phenyl group substituted with a biphenyl group”. In other words, the “terphenyl group” belongs to “a substituted phenyl group having, as a substituent, a C₆-C₆₀ aryl group substituted with a C₆-C₆₀ aryl group”.

In the present specification, * and *′, unless defined otherwise, each refer to a binding site to a neighboring atom in a corresponding formula or moiety.

Hereinafter, compounds according to embodiments and light-emitting devices according to embodiments will be described in more detail with reference to the following synthesis examples and examples. The wording “B was utilized instead of A” used in describing Synthesis Examples refers to that an identical molar equivalent of B was utilized in place of A.

### EXAMPLES

As for reagents, unless otherwise indicated, products of Samchun Pure Chemical were utilized.

### Synthesis Example 1: Synthesis of Quantum Dot 1

### Synthesis Example 1-1: Synthesis of Ligand 1

### (1) Synthesis of 3-Bromo-2,2-Bisbromomethyl Propanoic Acid

12 ml of a mixture of nitric acid and fuming nitric acid (mixed at a volume ratio of 9:1) was added to a reaction vessel and heated at 70° C. Then, 3.0 g (0.009 mol) of pentaerythritol tribromide was added thereto over 15 minutes, and the resulting mixture was heated to 90° C. Here, brown nitrogen dioxide gas was generated. After 3 hours, the resulting mixture was put in ice water and stirred rapidly. A white solid thus obtained was filtered, washed with cold water, and dried under vacuum.

### (2) Synthesis of 3-Mercapto-2,2-Bismercaptomethyl Propanoic Acid

3.3 g (58 mmol) of sodium hydrosulfide hydrate was dissolved in 25 ml of distilled water, and nitrogen gas was bubbled thereinto. Then, 2.0 g (5.90 mmol) of 3-bromo-2,2-bisbromomethyl propanoic acid of Synthesis Example 1-1 was added to the reaction solution over 30 minutes and refluxed for 24 hours. Afterwards, the resulting reaction solution was treated with sulfuric acid at 15° C. until the generation of hydrogen sulfide gas stopped. An extraction process was performed on the treated solution by utilizing dichloromethane, and the extract was dried with magnesium sulfate. Then, the solvent was removed therefrom.

A solid thus obtained was dissolved in 30 ml (mL) (0.25 M) of a sodium bicarbonate solution, and an excess of sodium bromide was added thereto at 0° C. and stirred for 3 hours. The reaction solution was treated with 6 normal hydrochloric acid (pH of about 4), and an extraction process was performed thereon by utilizing dichloromethane. Next, the extract was dried with magnesium sulfate, and the solvent was removed therefrom, thereby preparing Ligand 1.

### Synthesis Example 1-2: Formation of Quantum Dot 1

Reagents: Zinc acetate, anhydrous (99.9+%, powder), selenium (99.99%, powder), tellurium (99.99%), sulfur (99.998%), 1-octadecene (90%), oleic acid (90%) diphenylphosphine (DPP, 98%), trioctylphosphine (TOP, 97%), 1-octanethiol (98.5%), hexane anhydrous, acetone (99.9%), and zinc stearate (technical grade).

In a 3-neck flask, 0.3667 g (1.7 mmol) of zinc acetate, 1.5 ml of oleic acid, and 15 ml of 1-octadecene was added, and a deaeration process was performed under vacuum at 100° C. for 1 hour. Then, the reaction solution was heated at 220° C. in nitrogen atmosphere, and 0.5 ml (2 M) of a DPP-Se solution and 1 ml (0.054 M) of a TOP-Te solution were added thereto, maintained at 220° C. for 20 minutes, and then maintained at 300° C. for 1 hour to produce a ZnSeTe core.

For a shell, two kinds (e.g., types) of precursors, i.e., a zinc precursor and a zinc straight precursor, were utilized. The zinc precursor was prepared by heating 0.55 g of zinc acetate, 1.2 ml of 1-octadecene, and 2 ml of oleic acid in a 2-neck flask at 220° C., and the zinc straight precursor was prepared by adding 5 g (7.9 mmol) of zinc stearate and 16 ml of 1-octadecene to a 2-neck flask, degassing at 100° C. for 1 hour, and maintaining in a nitrogen atmosphere.

After the ZnSeTe core was grown, 3.2 ml (0.8 M) of the zinc precursor was added thereto, and after stabilization at 300° C., 1 ml (1.25 M) of TOP-Se was added thereto and maintained for 80 minutes. 3.2 ml (0.8 M) of the zinc precursor was added thereto, and after stabilization at 300° C., 1 ml of a mixed solution containing 0.5 ml of TOP-Se and 0.5 ml of TOP-S was added thereto and maintained for 30 minutes. 5 ml (1.25 M) of the zinc precursor was added thereto, and after stabilization at 300° C., 1 ml (1.25 M) of TOP-S was added thereto and maintained for 30 minutes. 5 ml (0.5 M) of the zinc straight precursor was added thereto, and after maintaining for 30 minutes, the reaction temperature was lowered to 230° C. After temperature stabilization, 1 ml of 1-octanethiol was added thereto dropwise, maintained for 30 minutes, and then cooled to room temperature. Then, a purification process was performed thereon utilizing hexane and acetone at 8,000 rpm, thereby preparing Quantum dot 1.

### Synthesis Example 2: Synthesis of Quantum Dot 2

### Synthesis Example 2-1: Synthesis of Ligand 2

3.3 g (58 mmol) of sodium hydrosulfide was dissolved in 25 ml of distilled water, and nitrogen gas was bubbled thereinto. 1.936 g (5.96 mmol) of pentaerythritol tribromide was added thereto over 30 minutes and refluxed for 24 hours. Afterwards, the resulting reaction solution was treated with sulfuric acid at 15° C. until the generation of hydrogen sulfide gas stopped. Then, an extraction process was performed thereon by utilizing dichloromethane. The extract was dried with magnesium sulfate, and the solvent was removed therefrom. A solid thus obtained was dissolved in 30 ml (0.25 M) of a sodium bicarbonate solution, and an excess of sodium bromide was added thereto at 0° C. and stirred for 3 hours. The reaction solution was treated with 6 normal hydrochloric acid (pH of about 4), and an extraction process was performed thereon by utilizing dichloromethane. Next, the extract was dried with magnesium sulfate, and the solvent was removed therefrom, thereby preparing Ligand 2.

### Synthesis Example 2-2: Formation of Quantum Dot 2

Quantum dot 2 was prepared in the same manner as in the preparation of Quantum dot 1, except that Ligand 2 was utilized instead of Ligand 1

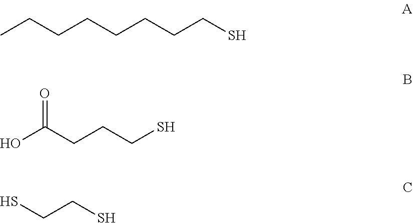

### Comparative Synthesis Example 1: Synthesis of Quantum Dot A

Preparation of Ligand A

1-octanethiol (Ligand A) was purchased from Sigma-Aldrich.

Formation of Quantum Dot A

Quantum dot A was prepared in the same manner as in the preparation of Quantum dot 1, except that 1-octanethiol (Ligand A) was utilized instead of Ligand 1.

### Comparative Synthesis Example 2: Synthesis of Quantum Dot B

Preparation of Ligand B

1-mercaptobutanoate (Ligand B) was purchased from Sigma-Aldrich.

Formation of Quantum Dot B

Quantum dot B was prepared in the same manner as in the preparation of Quantum dot 1, except that 1-mercaptobutanoate (Ligand B) was utilized instead of Ligand 1.

### Comparative Synthesis Example 3: Synthesis of Quantum Dot C

Preparation of Ligand C

1,2-ethanedithiol (Ligand C) was purchased from Sigma-Aldrich.

Formation of Quantum dot C

Quantum dot C was prepared in the same manner as in the preparation of Quantum dot 1, except that 1,2-ethanedithiol (Ligand C) was utilized instead of Ligand 1.

### Evaluation Example 1

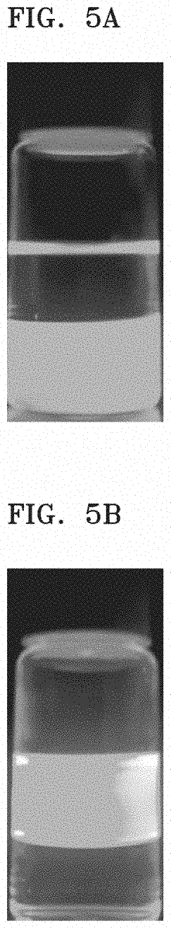

1 mmol of Quantum dot 1 and 1 mmol of Quantum dot A were separately added to 10 ml of a mixed solution containing hexane and water (at a volume ratio 1:1), and photoluminescence was evaluated by emitting light having a wavelength of 365 nm to the reaction solutions. The evaluation results are shown in FIGS. 5A and 5B, respectively.

Referring to FIGS. 5A and 5B, it was confirmed that Quantum dot 1 was dissolved in water so that luminescence was observed in the water layer located at the bottom, whereas Quantum dot A was dissolved in hexane so that luminescence was observed in the hexane layer located above the water layer. Therefore, based on the evaluation results, it was confirmed that, unlike Quantum dot A, Quantum dot 1 of the present disclosure had excellent or suitable solubility in a hydrophilic solvent.

### Synthesis Example 1 of Ink Composition: Synthesis of Ink Composition 1-1

1 mmol of Quantum dot 1 of Synthesis Example 1 was added to 1 mL of water to prepare Ink composition 1-1.

### Synthesis Example 2 of Ink Composition: Synthesis of Ink Composition 1-2

1 mmol of Quantum dot 1 of Synthesis Example 1 was added to 1 mL of glycerol to prepare Ink composition 1-2.

### Synthesis Example 3 of Ink Composition: Synthesis of Ink Composition 1-3

1 mmol of Quantum dot 1 of Synthesis Example 1 was added to 1 mL of ethylene glycol to prepare Ink composition 1-3.

### Evaluation Example 2

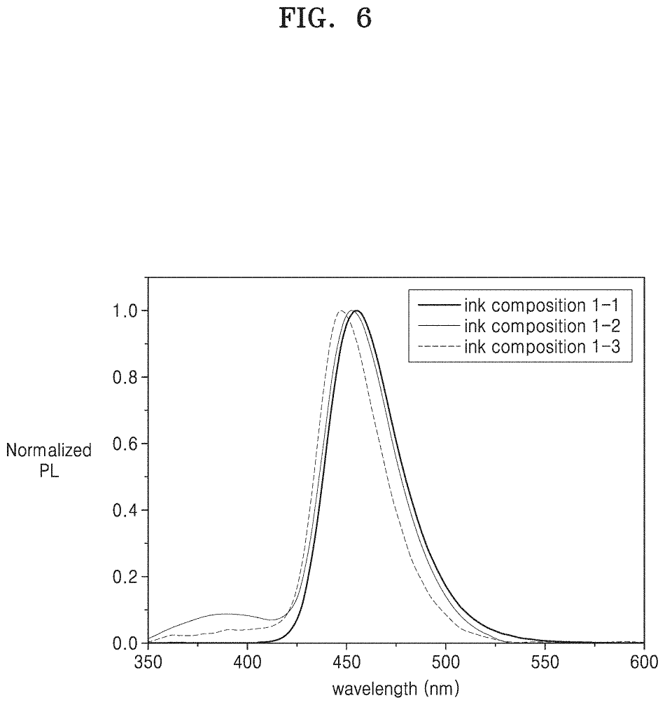

For Ink compositions 1-1 to 1-3, photoluminescence thereof was evaluated in a wavelength range from about 350 nm to about 600 nm under room temperature conditions by utilizing a photoluminescence spectrometer, and the evaluation results are shown in FIG. 6.

Referring to FIG. 6, it was confirmed that all of Ink compositions 1-1 to 1-3 exhibited a maximum emission wavelength in a wavelength range from about 400 nm to about 500 nm. Thus, based on the evaluation results, it was confirmed that Quantum dot 1 of the present disclosure had excellent or suitable solubility in all of water, glycerol, and ethylene glycol.

### Evaluation Example 3

For Quantum dots 1, 2, and A to C, 1 mol of each of the quantum dots was added to 10 mL of each of water, glycerol, ethylene glycol, and hexane, and dissolution (e.g., solubility) thereof was evaluated. The evaluation results are shown in Table 1.

TABLE 1

| | Solubility in | |
|---|---|---|
| | water/glycerol/ethylene | |
| Quantum dot | glycol | Solubility in hexane |
| Quantum dot 1 | ◯ | X |
| Quantum dot 2 | ◯ | X |
| Quantum dot A | X | ◯ |
| Quantum dot B | ◯ | X |
| Quantum dot C | X | ◯ |

Referring to Table 1, it was confirmed that, unlike Quantum dots A and C, Quantum dots 1, 2, and B were dissolved in water, glycerol, and ethylene glycol, which are hydrophilic solvents.

### Example 1

As an anode, an ITO substrate was cut to a size of 50 mm×50 mm×0.5 mm, sonicated with acetone, isopropyl alcohol, and pure water each for 15 minutes, and then cleaned by exposure to ultraviolet rays and ozone for 30 minutes. Then, the ITO substrate was provided to a vacuum deposition apparatus.

Poly(3,4-ethylenedioxythiophene)/poly(4-styrenesulfonate) (PEDOT/PSS) was formed on the ITO substrate to form a hole injection layer having a thickness of 600 Å, and poly[(9,9-dioctylfluorenyl-2,7-diyl)-co-(4,4′-(N-(4-sec-butylphenyl)diphenylamine)] (TFB) was vacuum-deposited on the hole injection layer to form a hole transport layer having a thickness of 400 Å.

Quantum dot 1 was deposited at a concentration of 20 mg/ml on the hole transport layer to form an emission layer having a thickness of 280 Å, and ZnMgO was deposited on the emission layer to form an electron transport layer having a thickness of 280 Å. Al was deposited on the electron transport layer to form a cathode having a thickness of 1,000 Å, thereby completing the manufacture of a light-emitting device.

### Example 2 and Comparative Example 1

Light-emitting devices were manufactured in the same manner as in Example 1, except that, in forming an emission layer, quantum dots shown in Table 2 were respectively utilized instead of Quantum dot 1.

### Evaluation Example 4

To evaluate characteristics of the light-emitting devices of Examples 1 and 2 and Comparative Example 1, the luminescence efficiency of the light-emitting devices at the current density of 10 mA/cm² was measured. The quantum efficiency of each of the light-emitting devices was measured by utilizing a quantum efficiency measurement device, C9920-2-12, of Hamamatsu Photonics Inc. Table 2 shows the evaluation results of the characteristics of the light-emitting devices.

TABLE 2

| | | Luminescence |
|---|---|---|
| | Emission layer | efficiency (%) |
| Example 1 | Quantum dot 1 | 70 |
| Example 2 | Quantum dot 2 | 68 |
| Comparative Example 1 | Quantum dot B | 50 |

Referring to Table 2, it was confirmed that the light-emitting devices of Examples 1 and 2 had better luminescence efficiency than the light-emitting device of Comparative Example 1.

As described above, according to the one or more embodiments, a quantum dot includes a nanoparticle and a ligand, wherein the nanoparticle does not include mercury and cadmium and the ligand includes at least two thiol groups and at least one hydrophilic group. In this regard, the quantum dot not only has excellent solubility in a hydrophilic solvent, for example, an alcohol-based solvent, but also promotes charge transfer to the quantum dot and maintains a narrow (e.g., small) distance between quantum dots. Accordingly, a device, an optical member, and an apparatus, each including the quantum dot may improve the efficiency.

As used herein, the terms “substantially,” “about,” and similar terms are used as terms of approximation and not as terms of degree, and are intended to account for the inherent deviations in measured or calculated values that would be recognized by those of ordinary skill in the art. Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. Further, the use of “may” when describing embodiments of the present disclosure refers to “one or more embodiments of the present disclosure.”

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various suitable changes in form and details may be made therein without departing from the spirit and scope as defined by the following claims, and equivalents thereof.

What is claimed is:

1. A quantum dot comprising:
a nanoparticle; and
at least one ligand on a surface of the nanoparticle,
wherein:
the nanoparticle does not comprise mercury (Hg) and cadmium (Cd); and
the at least one ligand comprises at least two thiol groups and at least one hydrophilic group.

2. The quantum dot of claim 1, wherein
the at least one ligand is represented by Formula 1:
A₁-(L₁)ₙ₁-T₁, and Formula 1
wherein, in Formula 1,
A₁ is a moiety comprising at least two thiol groups,
L₁ is a single bond, *—O—*′, *—S—*′, or *—C(R₁)(R₂)—*′,
n1 is an integer from 1 to 10,
R₁ and R₂ are each independently hydrogen, deuterium, —F, —Cl, —Br, —I, a hydroxyl group, a cyano group, a carboxyl group, a C₁-C₂₀ alkyl group, a C₁-C₂₀ alkoxy group, —NCO, —NCS, —OCN, —SCN, —C(═O)N(Q₁)₂, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
T₁ is a hydrophilic group,
Q₁ to Q₅ are each independently hydrogen, a C₁-C₂₀ alkyl group, a C₁-C₂₀ alkoxy group, a phenyl group, a biphenyl group, a terphenyl group, a naphthyl group, or a pyridinyl group, and
* and *′ each indicate a binding site to a neighboring atom.

3. The quantum dot of claim 1, wherein
the at least one hydrophilic group is selected from a hydroxyl group, a carboxyl group, an amine group, a sulfonyl group, a phosphate group, an ammonium group, a phosphonium group, and combinations thereof.

4. The quantum dot of claim 2, wherein
A₁ is a bidentate thiol group or a tridentate thiol group.

5. The quantum dot of claim 2, wherein
A₁ is an anchoring group bonded to the surface of the nanoparticle.

6. The quantum dot of claim 2, wherein
A₁ is a group represented by one of Formulae A-1 to A-4: 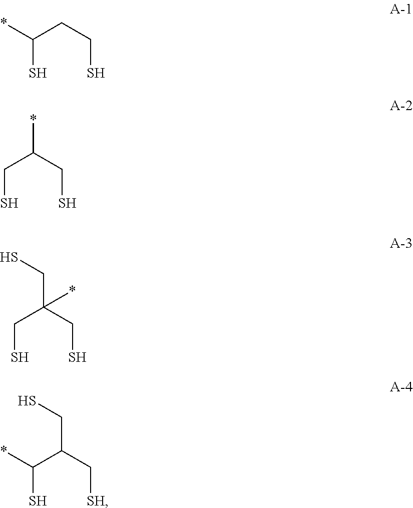
wherein in Formulae A-1 to A-4, * indicates a binding site to a neighboring atom.

7. The quantum dot of claim 2, wherein
n1 is an integer from 1 to 5.

8. The quantum dot of claim 1, wherein
the nanoparticle has a core-shell structure in which a core comprises a first semiconductor material and a shell comprises a second semiconductor material, and
the first semiconductor material and the second semiconductor material do not comprise mercury (Hg) and cadmium (Cd).

9. The quantum dot of claim 8, wherein
the first semiconductor material and the second semiconductor material each independently comprise:
ZnS, ZnSe, ZnTe, ZnO, MgSe, MgS, ZnSeS, ZnSeTe, ZnSTe, MgZnSe, MgZnS, or CdZnSeS;
GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InGaN, InGaP, InNP, InAlP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, InGaZnP, or InAlZnP;
TiO, GaO, GaS, GaSe, Ga₂Se₃, GaTe, InS, InSe, In₂S₃, In₂Se₃, or InTe;
InGaS₃ or InGaSe₃;
AgInS, AgInS₂, CulnS, CuInS₂, CuGaO₂, AgGaO₂, AgAlO₂, or AgInZnS;
SrSe, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, or SnPbSTe;
Si, Ge, SiC, or SiGe; or
any combination thereof.

10. The quantum dot of claim 8, wherein
the first semiconductor material comprises InP, InZnP, InGaP, ZnS, ZnSe, ZnTe, ZnSeS, ZnSeTe, PbSe, PbS, PbTe, AgInZnS, GaN, GaP, GaAs, InGaN, InAs, ZnO, or any combination thereof, and
the second semiconductor material comprises ZnS, ZnSe, ZnTe, ZnSeS, ZnSeTe, ZnO, InP, InS, GaP, GaN, GaO, ZnSeTe, InZnP, InGaP, InGaN, PbS, TiO, SrSe, or any combination thereof.

11. The quantum dot of claim 1, wherein
the at least one ligand is one of Ligands 1 to 3:

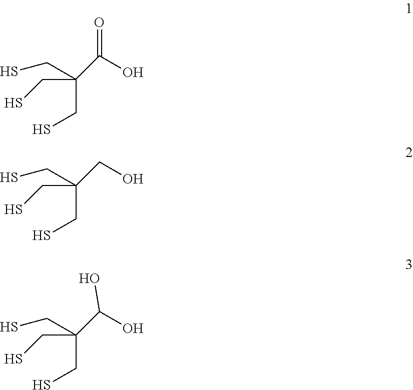

12. An ink composition comprising the quantum dot of claim 1 and a solvent.

13. The ink composition of claim 12, wherein
the solvent comprises an alcohol-based solvent.

14. The ink composition of claim 12, wherein
the solvent comprises aliphatic alcohol, aromatic alcohol, polyhydric alcohol, ethylene glycol monoalkyl ether, or any combination thereof.

15. The ink composition of claim 12, wherein
the solvent comprises methanol, ethanol, phenol, benzenediol, ethylene glycol, glycerol, diethylene glycol, triethylene glycol, ethylene glycol monoethyl ether, ethylene glycol monobutyl ether, or any combination thereof.

16. A light-emitting device comprising:
a first electrode;
a second electrode facing the first electrode; and
an emission layer between the first electrode and the second electrode,
wherein the emission layer comprises the quantum dot of claim 1.

17. An optical member comprising the quantum dot of claim 1.

18. The optical member of claim 17, wherein
the optical member is a color conversion member.

19. An apparatus comprising the quantum dot of claim 1.

20. The apparatus of claim 19, further comprising
a light source,
wherein the quantum dot is arranged on a path of light emitted from the light source.
